(19) United States
(12) Patent Application Publication
(10) Pub. No.: US 2026/0040620 A1
(43) Pub. Date: Feb. 5, 2026

(54) SEMICONDUCTOR DEVICE AND MANUFACTURING METHOD THEREOF

(71) Applicant: Semiconductor Energy Laboratory Co., Ltd., Atsugi-shi, Kanagawa-ken (JP)

(72) Inventors: Junichi KOEZUKA, Tochigi (JP); Masami JINTYOU, Shimotsuga (JP); Yukinori SHIMA, Tatebayashi (JP)

(21) Appl. No.: 19/123,202

(22) PCT Filed: Nov. 10, 2023
(86) PCT No.: PCT/IB2023/061351

§ 371 Date: Apr. 22, 2025

(30) Foreign Application Priority Data
Nov. 17, 2022 (JP) 2022-184425

(51) Int. Cl. H10D 30/67; H10D 30/01; H10K 59/121

(52) U.S. Cl. CPC H10D 30/673; H10D 30/0318; H10D 30/6728; H10K 59/1213

(57) ABSTRACT

A semiconductor device that can be easily miniaturized is provided. A semiconductor device with reduced parasitic capacitance is provided. In the semiconductor device, an insulating layer functioning as a first spacer is provided between a lower electrode that is one of a source electrode and a drain electrode of a transistor and an upper electrode that is the other, and an insulating layer functioning as a second spacer is provided over the upper electrode. The first spacer, the upper electrode, and the second spacer are provided with a first opening portion reaching the lower electrode. Inside the first opening portion, a semiconductor layer where a channel is formed is provided to connect the lower electrode and the upper electrode. Inside the first opening portion, a gate insulating layer and a gate electrode are provided to overlap with the semiconductor layer. An interlayer insulating layer including a second opening portion reaching the gate electrode is provided over the second spacer, the semiconductor layer, the gate insulating layer, and the gate electrode. The gate electrode includes a region in contact with a wiring over the interlayer insulating layer inside the second opening portion.

### TECHNICAL FIELD

One embodiment of the present invention relates to a transistor, a semiconductor device, a memory device, a display device, and an electronic appliance. Another embodiment of the present invention relates to manufacturing methods thereof.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic appliance, a lighting device, an input device, an input/output device, driving methods thereof, and manufacturing methods thereof. A semiconductor device refers to all devices that can function by utilizing semiconductor characteristics.

### BACKGROUND ART

In recent years, semiconductor devices have been developed, and a CPU (Central Processing Unit), a memory, and another LSI (Large Scale Integration) are mainly used in the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU, a memory, or another LSI is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing the feature of the low leakage current. As another example, Patent Document 2 discloses a memory device that can retain stored contents for a long time.

In recent years, demand for an integrated circuit with higher density has risen with reductions in size and weight of electronic appliances. In addition, the productivity of a semiconductor device including an integrated circuit is desired to be improved. For example, Patent Document 3 and Non-Patent Document 1 disclose a technique to obtain an integrated circuit with higher density by making a plurality of memory cells overlap with each other by stacking a first transistor using an oxide semiconductor film and a second transistor using an oxide semiconductor film.

Furthermore, by employing vertical transistors, an integrated circuit with higher density can be obtained. For example, Patent Document 4 discloses a vertical transistor in which a side surface of an oxide semiconductor is covered with a gate electrode with a gate insulating layer therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

As miniaturization of a semiconductor device proceeds, the effect of parasitic capacitance becomes unignorable. For example, as parasitic capacitance increases, the operation speed of the semiconductor device decreases in some cases.

An object of one embodiment of the present invention is to provide a miniaturized semiconductor device. Another object is to provide a semiconductor device with reduced parasitic capacitance. Another object is to provide a semiconductor device that operates at high speed. Another object is to provide a highly reliable semiconductor device. Another object is to provide a semiconductor device that exhibits excellent electrical characteristics.

Another object is to provide a method for manufacturing a miniaturized semiconductor device. Another object is to provide a method for manufacturing a semiconductor device with reduced parasitic capacitance. Another object is to provide a method for manufacturing a semiconductor device that operates at high speed. Another object is to provide a method for manufacturing a highly reliable semiconductor device. Another object is to provide a method for manufacturing a semiconductor device with a high yield. Another object is to provide a method for manufacturing a semiconductor device that exhibits excellent electrical characteristics.

Another object is to provide a semiconductor device, a memory device, a display device, or an electronic appliance. Another object is to provide a method for manufacturing a semiconductor device, a memory device, a display device, or an electronic appliance having a novel structure. An object of one embodiment of the present invention is to at least alleviate at least one of problems in the conventional art.

Note that the description of these objects does not preclude the existence of other objects. Note that one embodiment of the present invention does not need to achieve all of these objects. Note that other objects can be derived from the description of the specification, the drawings, the claims, and the like.

### Means for Solving the Problems

One embodiment of the present invention is a semiconductor device including a transistor, a first insulating layer, a second insulating layer, a third insulating layer, and a wiring; the transistor includes a first conductive layer, a second conductive layer, a third conductive layer, a semiconductor layer, and a fourth insulating layer; the first insulating layer is provided over the first conductive layer; the second conductive layer is provided over the first insulating layer; the second insulating layer is provided over the second conductive layer; the first insulating layer, the second conductive layer, and the second insulating layer include a first opening portion reaching the first conductive layer; the semiconductor layer is positioned inside the first opening portion and includes a region in contact with the first conductive layer and a region in contact with the second conductive layer; the fourth insulating layer is provided between the semiconductor layer and the third conductive layer inside the first opening portion; the third conductive layer is provided to fill the first opening portion; the third insulating layer is provided over the second insulating layer, over the semiconductor layer, over the fourth insulating layer, and over the third conductive layer and includes a second opening portion reaching the third conductive layer; and the wiring includes a region in contact with the third conductive layer inside the second opening portion and includes a region overlapping with the semiconductor layer with the third insulating layer therebetween.

Another embodiment of the present invention is a semiconductor device including a transistor, a first insulating layer, a second insulating layer, a third insulating layer, and a wiring; the transistor includes a first conductive layer, a second conductive layer, a third conductive layer, a semiconductor layer, and a fourth insulating layer; the first insulating layer is provided over the first conductive layer; the second conductive layer is provided over the first insulating layer; the first insulating layer and the second conductive layer include a first opening portion reaching the first conductive layer; the second insulating layer is provided over the second conductive layer; the second insulating layer includes a second opening portion reaching the second conductive layer and including a region overlapping with the first opening portion; the semiconductor layer is positioned inside the first opening portion and inside the second opening portion and includes a region in contact with the first conductive layer and a region in contact with the second conductive layer; the fourth insulating layer is provided between the semiconductor layer and the third conductive layer inside the first opening portion and inside the second opening portion; the third conductive layer is provided to fill the first opening portion and the second opening portion; the third insulating layer is provided over the second insulating layer, over the semiconductor layer, over the fourth insulating layer, and over the third conductive layer and includes a third opening portion reaching the third conductive layer; and the wiring includes a region in contact with the third conductive layer inside the third opening portion and includes a region overlapping with the semiconductor layer with the third insulating layer therebetween.

Alternatively, in the above embodiment, the semiconductor layer may include a region in contact with a top surface of the second conductive layer.

Alternatively, in the above embodiment, a top surface of the second insulating layer, a top surface of the semiconductor layer, a top surface of the fourth insulating layer, and a top surface of the third conductive layer may be level or substantially level with each other.

Alternatively, in the above embodiment, the semiconductor layer may contain a metal oxide. The metal oxide may contain two or three selected from In, an element M, and Zn, and the element M may be one or more kinds selected from Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb.

Another embodiment of the present invention is a method for manufacturing a semiconductor device, including: forming a first insulating layer; forming a first conductive layer over the first insulating layer; forming a second insulating layer over the first conductive layer; forming a first opening portion in the second insulating layer, the first conductive layer, and the first insulating layer; forming a semiconductor layer including a region in contact with the first conductive layer, a third insulating layer over the semiconductor layer, and a second conductive layer over the third insulating layer, inside the first opening portion; forming a fourth insulating layer over the second insulating layer, over the semiconductor layer, over the third insulating layer, and over the second conductive layer; forming a second opening portion in the fourth insulating layer to reach the second conductive layer; and forming a wiring to include a region in contact with the second conductive layer inside the second opening portion and to include a region overlapping with the semiconductor layer with the fourth insulating layer therebetween.

Alternatively, in the above embodiment, the semiconductor layer, the third insulating layer, and the second conductive layer may be formed by: forming a semiconductor film, an insulating film over the semiconductor film, and a conductive film over the insulating film to include a region positioned inside the first opening portion and a region overlapping with the second insulating layer after forming the first opening portion; and performing planarization treatment on the conductive film, the insulating film, and the semiconductor film to expose a top surface of the second insulating layer.

### Effect of the Invention

According to one embodiment of the present invention, a miniaturized semiconductor device can be provided. Alternatively, a semiconductor device with reduced parasitic capacitance can be provided. Alternatively, a semiconductor device that operates at high speed can be provided. Alternatively, a highly reliable semiconductor device can be provided. Alternatively, a semiconductor device that exhibits excellent electrical characteristics can be provided.

Alternatively, a method for manufacturing a miniaturized semiconductor device can be provided. Alternatively, a method for manufacturing a semiconductor device with reduced parasitic capacitance can be provided. Alternatively, a method for manufacturing a semiconductor device that operates at high speed can be provided. Alternatively, a method for manufacturing a highly reliable semiconductor device can be provided. Alternatively, a method for manufacturing a semiconductor device with a high yield can be provided. Alternatively, a method for manufacturing a semiconductor device that exhibits excellent electrical characteristics can be provided.

Alternatively, a semiconductor device, a memory device, a display device, or an electronic appliance having a novel structure can be provided. Alternatively, a method for manufacturing a semiconductor device, a memory device, a display device, or an electronic appliance having a novel structure can be provided. According to one embodiment of the present invention, at least one of problems in the conventional art can be at least alleviated.

Note that the description of these effects does not preclude the existence of other effects. Note that one embodiment of the present invention does not need to have all of these effects. Note that other effects can be derived from the description of the specification, the drawings, the claims, or the like.

### BRIEF DESCRIPTION OF THE DRAWINGS

FIG. 1A and FIG. 1B are perspective views illustrating a structure example of a semiconductor device.

FIG. 2A is a plan view illustrating the structure example of the semiconductor device. FIG. 2B and FIG. 2C are cross-sectional views illustrating the structure example of the semiconductor device.

FIG. 3A and FIG. 3B are cross-sectional views illustrating a structure example of a semiconductor device.

FIG. 4A is a cross-sectional view illustrating the structure example of the semiconductor device. FIG. 4B is a plan view illustrating the structure example of the semiconductor device.

FIG. 5A is a plan view illustrating a structure example of a semiconductor device. FIG. 5B and FIG. 5C are cross-sectional views illustrating the structure example of the semiconductor device.

FIG. 6A is a plan view illustrating a structure example of a semiconductor device. FIG. 6B and FIG. 6C are cross-sectional views illustrating the structure example of the semiconductor device.

FIG. 7A is a plan view illustrating a structure example of a semiconductor device. FIG. 7B and FIG. 7C are cross-sectional views illustrating the structure example of the semiconductor device.

FIG. 8A is a plan view illustrating a structure example of a semiconductor device. FIG. 8B and FIG. 8C are cross-sectional views illustrating the structure example of the semiconductor device.

FIG. 9A is a plan view illustrating a structure example of a semiconductor device. FIG. 9B and FIG. 9C are cross-sectional views illustrating the structure example of the semiconductor device.

FIG. 10A to FIG. 10C are cross-sectional views illustrating a structure example of a semiconductor device.

FIG. 11A to FIG. 11C are plan views illustrating structure examples of semiconductor devices.

FIG. 12A is a plan view illustrating a structure example of a semiconductor device. FIG. 12B and FIG. 12C are cross-sectional views illustrating the structure example of the semiconductor device.

FIG. 13A to FIG. 13D are cross-sectional views illustrating an example of a method for manufacturing a semiconductor device.

FIG. 14A and FIG. 14B are cross-sectional views illustrating the example of the method for manufacturing the semiconductor device.

FIG. 15A and FIG. 15B are cross-sectional views illustrating the example of the method for manufacturing the semiconductor device.

FIG. 16A and FIG. 16B are cross-sectional views illustrating the example of the method for manufacturing the semiconductor device.

FIG. 17A and FIG. 17B are cross-sectional views illustrating an example of a method for manufacturing a semiconductor device.

FIG. 18A and FIG. 18B are cross-sectional views illustrating the example of the method for manufacturing the semiconductor device.

FIG. 19A and FIG. 19B are cross-sectional views illustrating the example of the method for manufacturing the semiconductor device.

FIG. 20 is a circuit diagram illustrating a structure example of a memory device.

FIG. 21A1 and FIG. 21A2 are plan views illustrating a structure example of a memory device.

FIG. 21B and FIG. 21C are cross-sectional views illustrating the structure example of the memory device.

FIG. 22A is a plan view illustrating a structure example of a memory device. FIG. 22B and FIG. 22C are cross-sectional views illustrating a structure example of a memory device.

FIG. 23A is a plan view illustrating a structure example of a memory device. FIG. 23B is a cross-sectional view illustrating the structure example of the memory device.

FIG. 24A is a plan view illustrating a structure example of a memory device. FIG. 24B is a cross-sectional view illustrating the structure example of the memory device.

FIG. 25A is a plan view illustrating a structure example of a memory device. FIG. 25B is a cross-sectional view illustrating the structure example of the memory device.

FIG. 26 is a cross-sectional view illustrating a structure example of a memory device.

FIG. 27 is a block diagram illustrating a structure example of a memory device.

FIG. 28A is a perspective view illustrating a structure example of a memory device. FIG. 28B is a perspective view and a circuit diagram illustrating the structure example of the memory device.

FIG. 29A is a circuit diagram illustrating the structure example of the memory device. FIG. 29B is a block diagram illustrating the structure example of the memory device. FIG. 29C is a circuit diagram illustrating the structure example of the memory device. FIG. 29D is a block diagram illustrating the structure example of the memory device.

FIG. 30 is a block diagram illustrating the structure example of the memory device.

FIG. 31A and FIG. 31B are perspective views illustrating a structure example of a display device.

FIG. 32 is a cross-sectional view illustrating the structure example of the display device.

FIG. 33 is a cross-sectional view illustrating a structure example of a display device.

FIG. 34 is a cross-sectional view illustrating a structure example of a display device.

FIG. 35A is a plan view illustrating a structure example of a display device. FIG. 35B and FIG. 35C are cross-sectional views illustrating the structure example of the display device.

FIG. 36A and FIG. 36B are cross-sectional views illustrating structure examples of display devices.

FIG. 37A to FIG. 37D are diagrams illustrating examples of electronic appliances.

FIG. 38A to FIG. 38F are diagrams illustrating examples of electronic appliances.

FIG. 39A to FIG. 39G are diagrams illustrating examples of electronic appliances.

FIG. 40A and FIG. 40B are diagrams illustrating examples of electronic components.

FIG. 41A to FIG. 41C are diagrams illustrating an example of a large computer.

FIG. 42A is a diagram illustrating an example of a device for space. FIG. 42B is a diagram illustrating an example of a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of the embodiments below.

Note that in the structures of the invention described below, the same reference numeral is used in common for the same portions or portions having similar functions in different drawings, and repeated description thereof is omitted. The same hatching pattern is applied to portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification and the like are used to avoid confusion among components and do not limit the number.

A transistor is a kind of semiconductor element and can achieve a function of amplifying a current or a voltage, switching operation for controlling conduction or non-conduction, or the like. An IGFET (Insulated Gate Field Effect Transistor) and a thin film transistor (TFT) are in the category of a transistor in this specification.

Furthermore, functions of a “source” and a “drain” are sometimes interchanged with each other when a transistor of different polarity is used or when the direction of a current is changed in a circuit operation, for example. Thus, the terms “source” and “drain” can be used interchangeably in this specification.

In this specification and the like, the expression “electrically connected” includes the case where components are connected through an “object having any electric function”. Here, there is no particular limitation on the “object having any electric function” as long as electric signals can be transmitted and received between components that are connected through the object. Examples of the “object having any electric function” include a switch such as a transistor, a resistor, a coil, a capacitor, and other elements with a variety of functions as well as an electrode and a wiring.

Note that in this specification and the like, the top-view shape of a component means the shape of the outline of the component in a plan view. A plan view means that the component is observed from a direction normal to a surface where the component is formed or a surface of a support (e.g., a substrate) where the component is formed.

In this specification and the like, the expression “having substantially the same top-view shape” means that the outlines of stacked layers at least partly overlap with each other. For example, the case of processing the upper layer and the lower layer with the use of the same mask pattern or mask patterns that are partly the same is included. However, in some cases, the outlines do not exactly overlap with each other and the upper layer is positioned inward from the lower layer or the upper layer is positioned outward from the lower layer; such a case is also represented by the expression “having substantially the same top-view shape”.

Note that the expressions indicating directions such as “over” and “under” are hereinafter basically used to correspond to the directions in drawings. However, in some cases, the term “over” or “under” in the specification indicates a direction that does not correspond to the direction in the drawings, for the purpose of easy description or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In this specification and the like, the term “film” and the term “layer” can be interchanged with each other in some cases. For example, in some cases, the term “conductive layer” or “insulating layer” can be interchanged with the term “conductive film” or “insulating film.”

### Embodiment 1

In this embodiment, a structure example of a semiconductor device of one embodiment of the present invention and an example of a manufacturing method thereof will be described.

In this specification and the like, a memory device and a display device are each an embodiment of a semiconductor device. In this specification and the like, all devices including circuits including semiconductor elements, all devices that can function by utilizing semiconductor characteristics, and all devices containing semiconductor materials may be referred to as semiconductor devices. For example, an arithmetic device and an image capturing device can each be one embodiment of a semiconductor device.

In a transistor included in the semiconductor device of one embodiment of the present invention (also referred to as a transistor of one embodiment of the present invention), a source electrode and a drain electrode are positioned at different heights, and a current flows in the height direction in a semiconductor layer. In other words, the channel length direction can be regarded as having a component of the height direction (the vertical direction); accordingly, the transistor of one embodiment of the present invention can also be referred to as a vertical transistor, a vertical-channel transistor, or the like.

Specifically, an insulating layer functioning as a first spacer is provided between a lower electrode that is one of the source electrode and the drain electrode of the transistor and an upper electrode that is the other, and an insulating layer functioning as a second spacer is provided over the upper electrode. Note that in the following description, an insulating layer functioning as a spacer is simply referred to as a spacer in some cases, and the spacer may be read as an insulating layer.

The first spacer, the upper electrode, and the second spacer are provided with a first opening portion reaching the lower electrode. Inside the first opening portion, a semiconductor layer where a channel is formed is provided to connect the lower electrode and the upper electrode. Inside the first opening portion, a gate insulating layer and a gate electrode are provided to overlap with the semiconductor layer. Since the source electrode, the semiconductor layer, and the drain electrode can be provided to overlap with each other, the area occupied by the transistor can be significantly smaller than that of what is called a planar transistor in which a semiconductor layer is positioned over a flat plane.

The second spacer, the semiconductor layer, the gate insulating layer, and the gate electrode are planarized, whereby the top surfaces thereof can be level or substantially level with each other. An interlayer insulating layer is provided over the second spacer, the semiconductor layer, the gate insulating layer, and the gate electrode. The interlayer insulating layer is provided with a second opening portion reaching the gate electrode. The gate electrode includes a region in contact with a wiring provided over the interlayer insulating layer inside the second opening portion.

Note that in this specification and the like, the expression “level or substantially level” indicates a structure having the same level from a reference surface (e.g., a flat surface such as a substrate surface) in a cross-sectional view. For example, in a manufacturing process of a memory device, planarization treatment such as CMP (Chemical Mechanical Polishing) treatment is performed, whereby the surface(s) of a single layer or a plurality of layers are exposed in some cases. In that case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed, for example. This case is also regarded as being “level or substantially level” in this specification and the like. For example, the expression “level or substantially level” also includes the case where two layers (here, a first layer and a second layer) have different levels with respect to a reference surface and the difference in the top-surface level between the first and second layers is less than or equal to 20 nm.

Since the channel length of the transistor here can be precisely controlled by the thickness of the insulating layer functioning as the first spacer, a variation in the channel length can be much smaller than that among planar transistors. Furthermore, by reducing the thickness of the insulating layer, a transistor with an extremely short channel length can be manufactured. For example, it is possible to manufacture a transistor with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm. Thus, it is possible to obtain a transistor with an extremely short channel length that could not be obtained with the use of a light-exposure apparatus for mass production. Moreover, it is also possible to obtain a transistor with a channel length shorter than 10 nm without using an extremely expensive light-exposure apparatus used in the latest LSI technology.

The transistor of one embodiment of the present invention can have an extremely short channel length, occupy a small area, allow a large amount of current to flow therethrough, have small parasitic capacitance, and operate at high speed.

More specific examples will be described below with reference to drawings.

### Structure Example

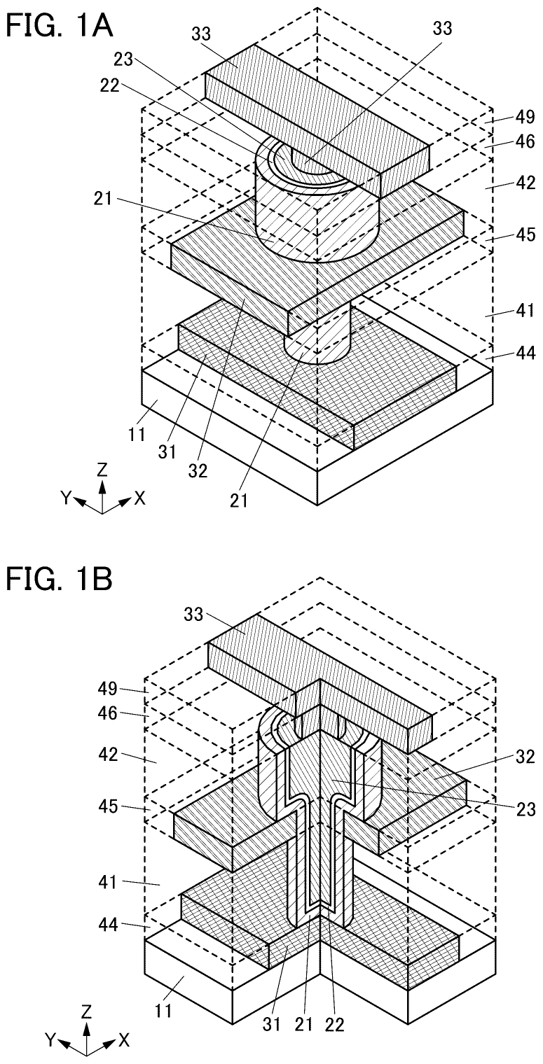

FIG. 1A and FIG. 1B are schematic perspective views of the semiconductor device of one embodiment of the present invention. FIG. 1B is a perspective view of FIG. 1A part of which is cut out. In FIG. 1A and FIG. 1B, only the outlines of some components (e.g., interlayer insulating layers) are indicated by dashed lines.

In FIG. 1A and FIG. 1B, the X direction, the Y direction, and the Z direction are indicated by arrows. Although the same reference signs X, Y, and Z are used in FIG. 1A and FIG. 1B, the directions in these drawings are not necessarily the same.

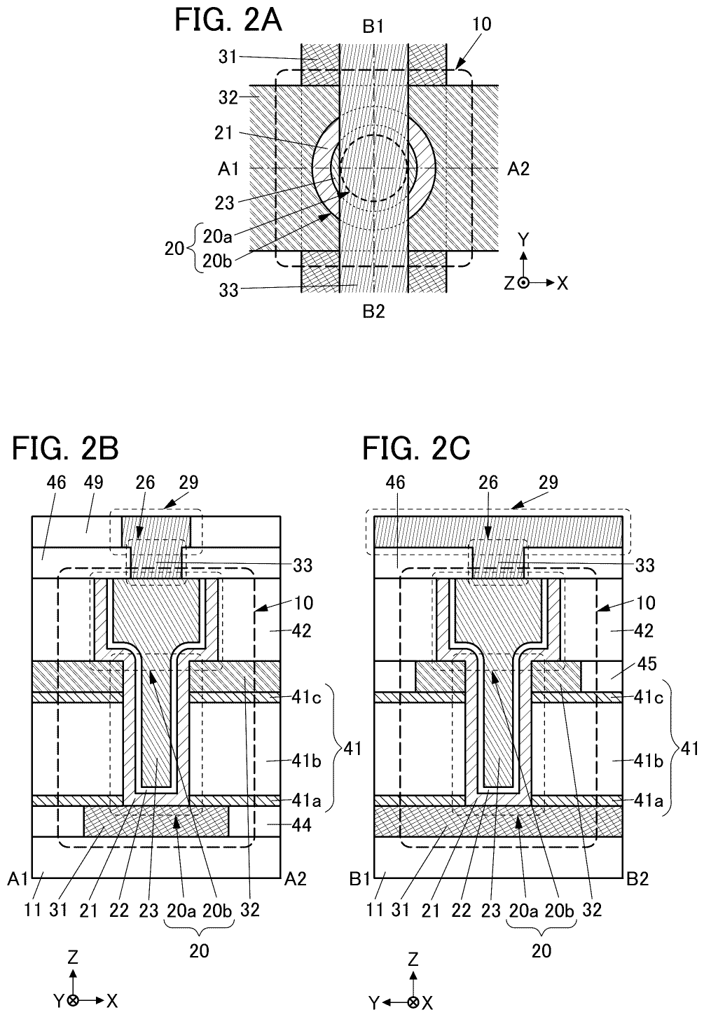

FIG. 2A illustrates a planar structure example of the semiconductor device of one embodiment of the present invention, and FIG. 2B and FIG. 2C respectively illustrate cross-sectional structure examples along the cutting line A1-A2 and the cutting line B1-B2 in FIG. 2A. Note that some components (e.g., insulating layers) are omitted in FIG. 2A. In the following drawings illustrating planar structure examples, some components are omitted as in FIG. 2A.

The semiconductor device of one embodiment of the present invention includes a transistor 10, an insulating layer 11, an insulating layer 41, an insulating layer 42, an insulating layer 44, an insulating layer 45, an insulating layer 46, an insulating layer 49, and a conductive layer 33. The transistor 10 is provided over the insulating layer 11 provided over a substrate (not illustrated). The insulating layer 11 functions as an interlayer insulating layer.

The transistor 10 includes a conductive layer 31 functioning as one of a source electrode and a drain electrode, a conductive layer 32 functioning as the other of the source electrode and the drain electrode, a semiconductor layer 21, an insulating layer 22 functioning as a gate insulating layer, and a conductive layer 23 functioning as a gate electrode. The conductive layer 31 and the conductive layer 32 function also as wirings.

The conductive layer 31 and the insulating layer 44 are provided over the insulating layer 11. The insulating layer 41 is provided over the conductive layer 31 and the insulating layer 44. The conductive layer 32 and the insulating layer 45 are provided over the insulating layer 41. The insulating layer 41 and the conductive layer 32 include an opening portion 20a reaching the conductive layer 31.

The insulating layer 42 is provided over the conductive layer 32 and the insulating layer 45. The insulating layer 42 includes an opening portion 20b reaching the conductive layer 32 and including a region overlapping with the opening portion 20a. Here, the diameter of the opening portion 20b can be larger than the diameter of the opening portion 20a. In that case, a structure can be obtained in which the whole opening portion 20a overlaps with the opening portion 20b. Since the opening portion 20b includes the region overlapping with the opening portion 20a, the opening portion 20a and the opening portion 20b can be regarded as one opening portion 20.

The insulating layer 41 functions as a first spacer, and the insulating layer 42 functions as a second spacer. Note that the insulating layer 42 may function as a first spacer, and the insulating layer 41 may function as a second spacer. The insulating layer 41 and the insulating layer 42 can function as interlayer insulating layers.

The semiconductor layer 21 is positioned inside the opening portion 20. The semiconductor layer 21 is provided along the sidewall of the opening portion 20. The semiconductor layer 21 includes a region in contact with the conductive layer 31 inside the opening portion 20a. In addition, the semiconductor layer 21 includes one or both of a region in contact with the side surface of the conductive layer 32 inside the opening portion 20a and a region in contact with the top surface of the conductive layer 32 inside the opening portion 20b. Furthermore, the semiconductor layer 21 may include a region in contact with the side surface of the insulating layer 41 inside the opening portion 20a and may include a region in contact with the side surface of the insulating layer 42 inside the opening portion 20b.

The opening portion 20b may reach not only the conductive layer 32 but also the insulating layer 45. In that case, an insulating material with which etching rate selectivity with respect to the insulating layer 42 can be increased is preferably used for the insulating layer 45. Specifically, an insulating film that differs in composition or density from the insulating layer 42 is preferably used for the insulating layer 45. This can inhibit unintentional processing of the insulating layer 45 at the time of processing the insulating layer 42. An insulating layer functioning as an etching stopper at the time of forming the opening portion 20b in the insulating layer 42 may be provided between the insulating layer 45 and the insulating layer 42. In that case, insulating films having the same composition and density can be used for the insulating layer 45 and the insulating layer 42, so that the range of choices of materials for the insulating layer 45 and the insulating layer 42 can be expanded. Note that the insulating layer functioning as an etching stopper may be included in the insulating layer 45, for example. In that case, the uppermost portion of the insulating layer 45 can be the insulating layer functioning as an etching stopper.

The insulating layer 22 is positioned inside the opening portion 20 and provided along the shape of the semiconductor layer 21. The insulating layer 22 can include a region in contact with the semiconductor layer 21 inside the opening portion 20.

The conductive layer 23 is provided over the insulating layer 22 to fill the opening portion 20. Thus, the insulating layer 22 is provided between the semiconductor layer 21 and the conductive layer 23 inside the opening portion 20.

The top surfaces of the insulating layer 42, the semiconductor layer 21, the insulating layer 22, and the conductive layer 23 can be level or substantially level with each other by being planarized. Specifically, the top surface of the insulating layer 42, the uppermost surface of the semiconductor layer 21, the uppermost surface of the insulating layer 22, and the top surface of the conductive layer 23 can be level or substantially level with each other.

The insulating layer 46 is provided over the insulating layer 42, the semiconductor layer 21, the insulating layer 22, and the conductive layer 23, and the insulating layer 49 is provided over the insulating layer 46. The insulating layer 46 and the insulating layer 49 function as interlayer insulating layers.

The insulating layer 46 includes an opening portion 26 reaching the conductive layer 23. The insulating layer 49 includes an opening portion 29 reaching the insulating layer 46 and including a region overlapping with the opening portion 26. Since the opening portion 29 here includes the region overlapping with the opening portion 26, the opening portion 26 and the opening portion 29 may be regarded as one opening portion.

The opening portion 26 can be formed by processing the insulating layer 46 by an etching method, for example. The opening portion 29 can be formed by processing the insulating layer 49 by an etching method, for example. In that case, an insulating material with which etching rate selectivity with respect to the insulating layer 46 can be increased can be used for the insulating layer 49. This can prevent the top surface of the semiconductor layer 21, for example, from being exposed and in contact with the conductive layer 33 by unintentional processing of the insulating layer 46 at the time of processing the insulating layer 49. Accordingly, a highly reliable semiconductor device can be obtained.

For the insulating layer 49, an insulating film that differs in composition or density from at least the insulating layer 46 is used. Note that the insulating layer 46 and the insulating layer 49 may contain the same constituent element.

Here, an insulating layer functioning as an etching stopper at the time of forming the opening portion 29 in the insulating layer 49 may be provided between the insulating layer 46 and the insulating layer 49. In that case, insulating films having the same composition and density can be used for the insulating layer 46 and the insulating layer 49, so that the range of choices of materials for the insulating layer 46 and the insulating layer 49 can be expanded. Note that the insulating layer functioning as an etching stopper may be included in the insulating layer 46, for example. In that case, the uppermost portion of the insulating layer 46 can be the insulating layer functioning as an etching stopper.

The conductive layer 33 functions as a wiring, specifically, a lead wiring of the gate electrode (also referred to as a gate wiring) of the transistor 10. The conductive layer 33 is provided to fill the opening portion 26 and the opening portion 29. The conductive layer 33 can include a region in contact with the conductive layer 23 inside the opening portion 26. Here, when the top surface of the conductive layer 23 has a large area, the opening portion 26 can be prevented from reaching the semiconductor layer 21, and the conductive layer 33 can be prevented from being in contact with the semiconductor layer 21, for example. Specifically, when the diameter of the opening portion 20b is larger than the diameter of the opening portion 20a, the area of the top surface of the conductive layer 23 can be increased while the area occupied by the transistor 10 can be inhibited from being increased by an increase in the width of the conductive layer 32 (the length in the Y direction in FIG. 2A in a region not including the opening portion 20a), for example. Accordingly, the transistor included in the semiconductor device can be miniaturized, and the semiconductor device can have high reliability.

The conductive layer 33 includes a region positioned over the insulating layer 46. In this region, the conductive layer 33 includes a region overlapping with the insulating layer 42 with the insulating layer 46 therebetween, a region overlapping with the semiconductor layer 21 with the insulating layer 46 therebetween, a region overlapping with the insulating layer 22 with the insulating layer 46 therebetween, and a region overlapping with the conductive layer 23 with the insulating layer 46 therebetween. Specifically, the conductive layer 33 includes a region overlapping with the top surface of the insulating layer 42 with the insulating layer 46 therebetween, a region overlapping with the uppermost surface of the semiconductor layer 21 with the insulating layer 46 therebetween, a region overlapping with the uppermost surface of the insulating layer 22 with the insulating layer 46 therebetween, and a region overlapping with the top surface of the conductive layer 23 with the insulating layer 46 therebetween. The top surface of the conductive layer 33 can be level or substantially level with the top surface of the insulating layer 49.

Here, the conductive layer 31 is embedded in the insulating layer 44, and the conductive layer 32 is embedded in the insulating layer 45. Furthermore, the top surfaces thereof are planarized, whereby the top surfaces of the conductive and insulating layers are substantially level with each other. Such a structure is preferable because the effect of a step can be eliminated. The insulating layer 44 and the insulating layer 45 function as interlayer insulating layers. For insulating layers functioning as interlayer insulating layers, such as the insulating layer 11, the insulating layer 42, the insulating layer 44, the insulating layer 45, the insulating layer 46, and the insulating layer 49, a low-permittivity inorganic insulating material such as silicon oxide or silicon oxynitride is preferably used, for example. Note that materials which can be used for the insulating layer 41 will be described later.

In this specification and the like, oxynitride refers to a material in which the oxygen content is higher than the nitrogen content. Nitride oxide refers to a material in which the nitrogen content is higher than the oxygen content.

In the case where the insulating layer 46 and the insulating layer 49 here differ in composition from each other as described above, an insulating material containing oxygen can be used for the insulating layer 46, and an insulating material containing nitrogen can be used for the insulating layer 49, for example. Silicon oxide can be used for the insulating layer 46, and silicon nitride can be used for the insulating layer 49, for example. Note that an insulating material containing nitrogen may be used for the insulating layer 46, and an insulating material containing oxygen may be used for the insulating layer 49, for example.

In the transistor 10 having the above structure, the source electrode and the drain electrode are positioned at different heights, so that current flows in the semiconductor in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, or the like. Since the source electrode, the semiconductor, and the drain electrode can be provided to overlap with each other in the transistor 10, the area occupied by the transistor 10 can be significantly smaller than that of what is called a planar transistor (also referred to as a lateral transistor, LFET (Lateral FET), or the like) in which a semiconductor is positioned over a flat surface.

Since the channel length of the transistor 10 can be precisely controlled by the thickness of the insulating layer 41, a variation in the channel length among a plurality of the transistors 10 can be much smaller than that among planar transistors. Furthermore, by reducing the thickness of the insulating layer 41, a transistor with an extremely short channel length can be manufactured. For example, it is possible to manufacture a transistor with a channel length of less than or equal to 50 nm, less than or equal to 30 nm, or less than or equal to 20 nm and greater than or equal to 5 nm, greater than or equal to 7 nm, or greater than or equal to 10 nm. Thus, even with a conventional light-exposure apparatus for mass production, a transistor with a channel length of less than 10 nm can be obtained without using an extremely expensive light-exposure apparatus used in the latest LSI technology.

A variety of semiconductor materials can be used for the semiconductor layer 21; in particular, an oxide semiconductor containing a metal oxide is preferably used. The use of an oxide semiconductor formed under an appropriate condition allows a transistor having both a high on-state current and an extremely low off-state current to be obtained at a low cost. Described below are preferable structure examples of the case where an oxide semiconductor is used for the semiconductor layer 21 unless otherwise specified.

A structure can be employed in which the top surfaces of the conductive layer 31 and the conductive layer 32 are in contact with the semiconductor layer 21. Hence, in the case where an oxide semiconductor is used for the semiconductor layer 21, the exposed surfaces of the conductive layer 31 and the conductive layer 32 and vicinities thereof might be oxidized by, for example, the effect of heat applied in a deposition step of a semiconductor film to be the semiconductor layer 21 or a later step, so that insulating oxide films might be formed between the conductive layers 31 and 32 and the semiconductor layer 21, increasing the contact resistance. Thus, an oxide conductor containing a conductive oxide is preferably used at least for the uppermost portions of the conductive layer 31 and the conductive layer 32. This can prevent an increase in the contact resistance due to the oxidation of the surfaces of the conductive layer 31 and the conductive layer 32.

The conductive layer 31 can be used as one of a source wiring and a drain wiring. The conductive layer 32 can be used as the other of the source wiring and the drain wiring. In the case where one or both of the conductive layer 31 and the conductive layer 32 are used as a wiring in this manner, they preferably have a low electric resistance. Thus, a material having a higher conductivity than an oxide conductor, such as a metal, an alloy, or a nitride thereof, is preferably used. It is particularly preferable that one or both of the conductive layer 31 and the conductive layer 32 have a stacked-layer structure including a layer of the material having high conductivity, where the above-described oxide conductor is used at least for the uppermost portion(s).

Here, the transistor 10 is provided at the intersection of the conductive layer 33 functioning as the gate wiring and the conductive layer 32 functioning as the source wiring or the drain wiring. Thus, parasitic capacitance is generated in a region where the conductive layer 33 and the conductive layer 32 overlap with each other at the intersection thereof. However, since the insulating layer 42 and the insulating layer 46 are provided between the conductive layer 33 and the conductive layer 32 in one embodiment of the present invention, the parasitic capacitance is significantly reduced as compared with the case where neither the insulating layer 42 nor the insulating layer 46 is provided (e.g., the case where there is a region where the conductive layer 33 and the conductive layer 32 overlap with each other with only the insulating layer 22 therebetween). Thus, a semiconductor device that operates at high speed can be obtained.

When the thickness of the insulating layer 42 and the thickness of the insulating layer 46 are increased, the parasitic capacitance between the conductive layer 33 and the conductive layer 32 can be favorably reduced. For example, the sum of the thickness of the insulating layer 42 and the thickness of the insulating layer 46 can be larger than the thickness of the insulating layer 22. The sum of the thicknesses of the insulating layer 42 and the insulating layer 46 is preferably larger than at least one of the thickness of the insulating layer 44, the thickness of the insulating layer 45, and the thickness of the insulating layer 49. The insulating layer 42 and the insulating layer 46 are preferably thicker so that the parasitic capacitance between the conductive layer 33 and the conductive layer 32 can be further reduced, but the thicknesses are set in consideration of productivity. The sum of the thickness of the insulating layer 42 and the thickness of the insulating layer 46 can be less than or equal to twice or less than or equal to three times the thickness of the insulating layer 41, for example.

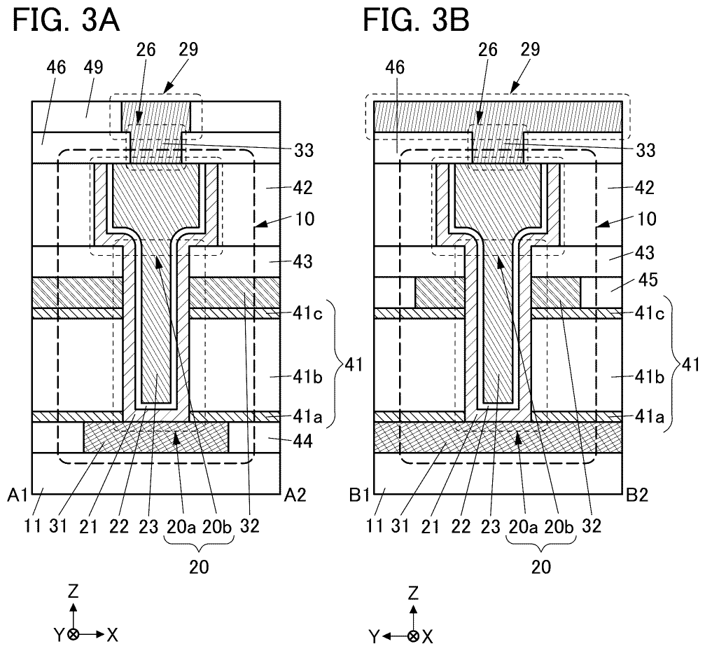

FIG. 3A and FIG. 3B are cross-sectional views illustrating an example in which an insulating layer 43 is provided between the conductive layer 32 and the insulating layer 42 included in the semiconductor device illustrated in FIG. 2B and FIG. 2C. FIG. 2A can be referred to for the planar structure of the semiconductor device illustrated in FIG. 3A and FIG. 3B.

In the semiconductor device illustrated in FIG. 3A and FIG. 3B, the insulating layer 43 includes the opening portion 20a. The insulating layer 42 includes the opening portion 20b reaching the insulating layer 43 and including a region overlapping with the opening portion 20a.

In the semiconductor device illustrated in FIG. 3A and FIG. 3B, the semiconductor layer 21 includes the region in contact with the side surface of the conductive layer 32 inside the opening portion 20a. In addition, the semiconductor layer 21 may include a region in contact with the side surface of the insulating layer 43 inside the opening portion 20a and may include a region in contact with the top surface of the insulating layer 43 inside the opening portion 20b.

In the semiconductor device illustrated in FIG. 3A and FIG. 3B, the insulating layer 43 is provided in addition to the semiconductor layer 21 and the insulating layer 22 between the conductive layer 32 and the conductive layer 23 in a region where the top surface of the conductive layer 32 and the conductive layer 23 overlap with each other. Thus, parasitic capacitance in the region where the top surface of the conductive layer 32 and the conductive layer 23 overlap with each other can be smaller than that in the semiconductor device illustrated in FIG. 2B and FIG. 2C. Meanwhile, in the semiconductor device illustrated in FIG. 2B and FIG. 2C, the semiconductor layer 21 can include a region in contact with not only the side surface but also the top surface of the conductive layer 32. Thus, the conductive layer 32 and the semiconductor layer 21 can be in contact with each other more favorably than in the semiconductor device illustrated in FIG. 3A and FIG. 3B.

The opening portion 20a included in the insulating layer 43 can be formed by processing the insulating layer 43 by an etching method, for example. The opening portion 20b included in the insulating layer 42 can be formed by processing the insulating layer 42 by an etching method, for example. In that case, an insulating material with which etching rate selectivity with respect to the insulating layer 42 can be increased can be used for the insulating layer 43. For the insulating layer 43, an insulating film that differs in composition or density from at least the insulating layer 42 is used. Note that the insulating layer 42 and the insulating layer 43 may contain the same constituent element. For example, a material similar to the material that can be used for the insulating layer 49 can be used for the insulating layer 42, and a material similar to the material that can be used for the insulating layer 46 can be used for the insulating layer 43. Note that a material similar to the material that can be used for the insulating layer 46 may be used for the insulating layer 42, and a material similar to the material that can be used for the insulating layer 49 may be used for the insulating layer 43.

Here, an insulating layer functioning as an etching stopper at the time of forming the opening portion 20b in the insulating layer 42 may be provided between the insulating layer 43 and the insulating layer 42. In that case, insulating films having the same composition and density can be used for the insulating layer 43 and the insulating layer 42, so that the range of choices of materials for the insulating layer 43 and the insulating layer 42 can be expanded. Note that the insulating layer functioning as an etching stopper may be included in the insulating layer 43, for example. In that case, the uppermost portion of the insulating layer 43 can be the insulating layer functioning as an etching stopper.

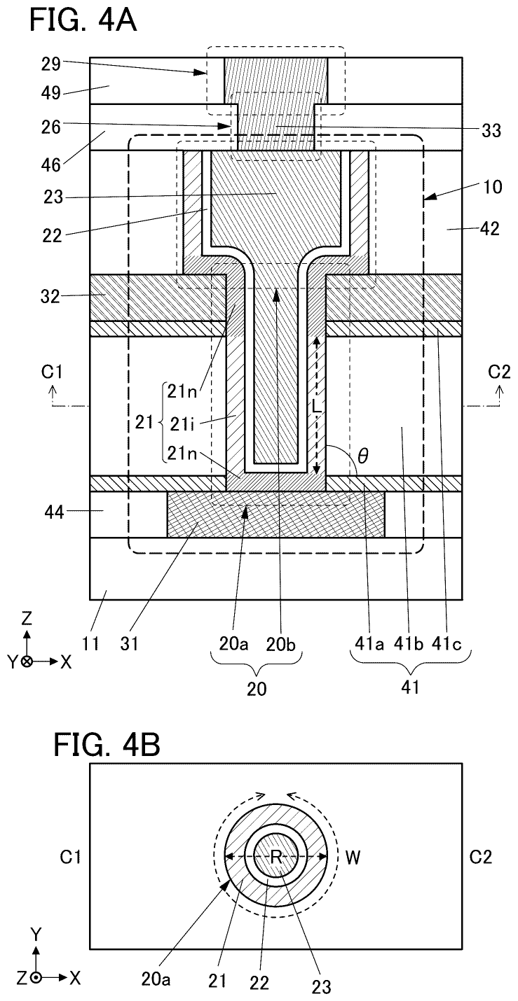

FIG. 2B, FIG. 2C, FIG. 3A, and FIG. 3B illustrate the case where a stacked-layer film of an insulating layer 41a, an insulating layer 41b, and an insulating layer 41c is used for the insulating layer 41. FIG. 4A illustrates an enlarged view of FIG. 2B.

The semiconductor layer 21 can be provided to include a region in contact with the side surface of the insulating layer 41b in the opening portion 20a. An oxide insulating film is preferably used for the insulating layer 41b. In particular, an oxide insulating film from which oxygen is released by heating is preferably used. Moreover, a structure is preferable in which the insulating layer 41b is interposed between the insulating layer 41a and the insulating layer 41c having a barrier property against oxygen. This enables oxygen contained in the insulating layer 41b to be enclosed in a region surrounded by the insulating layer 41a, the insulating layer 41c, and the semiconductor layer 21 and inhibits a reduction in oxygen caused by release from the insulating layer 41b in the process, so that oxygen can be supplied to the semiconductor layer 21 more efficiently.

A region of the semiconductor layer 21 that is in contact with the insulating layer 41b can be regarded as a region where oxygen vacancies are reduced, i.e., an i-type region. Meanwhile, a region of the semiconductor layer 21 that is not in contact with the insulating layer 41b is preferably an n-type region including a large amount of carriers. That is, the region of the semiconductor layer 21 that is in contact with the insulating layer 41b can be a channel formation region, and an outer region thereof can be a low-resistance region (also referred to as a source region or a drain region). In FIG. 4A, different hatching patterns are applied to a channel formation region 21i and low-resistance regions 21n of the semiconductor layer 21.

In that case, a channel length L of the transistor 10 can be defined as, as illustrated in FIG. 4A, the length of a region of the semiconductor layer 21 that is in contact with the insulating layer 41b on the shortest path connecting a region in contact with the conductive layer 31 and a region in contact with the conductive layer 32. When the sidewall of the opening portion 20a in the insulating layer 41b has an angle (θ) of 90°, the channel length L is equal to the thickness of the insulating layer 41b. The channel length L can be increased with an increase in θ.

Meanwhile, a channel width W of the transistor 10 depends on the shape of the opening portion 20a. FIG. 4B is a plan view seen in the Z direction of a cross section along the cutting line C1-C2 positioned at a height where the insulating layer 41b is provided in FIG. 4A. Here, the case where the opening portion 20a has a cylindrical shape is illustrated. When the outline of the opening portion 20a is a circle with a diameter R, the channel width W can be regarded as the circumference of the opening portion 20a (i.e., π×R). Here, the circumference of the opening portion 20a varies with the height in the case where the angle θ of the sidewall of the opening portion 20a in the insulating layer 41b shifts from 90°. In that case, the circumference at a height where the opening portion 20a has the minimum diameter may be regarded as the channel width W, or the circumference at a height of the upper end of the opening portion 20a may be regarded as the channel width W. Note that in this specification and the like, a circular shape is not limited to a perfect circular shape.

Since the semiconductor layer 21 and the insulating layer 22 are formed along the side surface of the insulating layer 41b in the opening portion 20a, the thicknesses thereof in this region are sometimes reduced by some deposition methods. For example, when a deposition method such as a sputtering method or a plasma chemical vapor deposition (PECVD: Plasma Enhanced Chemical Vapor Deposition) method is used, a film deposited on a surface inclined or perpendicular to the substrate surface tends to be thinner than a film deposited on a surface parallel to the substrate surface. By contrast, a deposition method such as an atomic layer deposition (ALD) method or a thermal CVD (TCVD) method allows a film with a uniform thickness to be deposited on a surface with any angle. The semiconductor layer 21 and the insulating layer 22 are preferably formed by an ALD method in the case where the side surface of the insulating layer 41b in the opening portion 20a has an angle θ of greater than or equal to 75°, greater than or equal to 80°, or greater than or equal to 85°, for example.

### [Components]

### <Substrate>

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor layer or a semiconductor layer, a semiconductor substrate provided with a conductive layer or an insulating layer, and a conductor substrate provided with a semiconductor layer or an insulating layer. Alternatively, these substrates provided with elements may be used. Examples of the element provided over the substrate include a capacitor, a resistor, a switch, a light-emitting element (also referred to as a light-emitting device), and a memory element (also referred to as a memory device).

### <Semiconductor Layer>

The semiconductor layer 21 preferably contains a metal oxide (an oxide semiconductor).

Examples of the metal oxide that can be used for the semiconductor layer 21 include In oxide, Ga oxide, and Zn oxide. The metal oxide preferably contains at least In or Zn. The metal oxide preferably contains two or three selected from In, an element M, and Zn. Note that the element M is a metal element or metalloid element that has a high bonding energy with oxygen, such as a metal element or metalloid element whose bonding energy with oxygen is higher than that of indium, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M contained in the metal oxide is preferably one or more kinds of the above elements, particularly preferably one or more kinds selected from Al, Ga, Y, and Sn, and further preferably gallium. Note that a metal oxide containing indium, M, and zinc is hereinafter referred to as In-M-Zn oxide in some cases. In this specification and the like, a metal element and a metalloid element may be collectively referred to as a “metal element”, and a “metal element” in this specification and the like may refer to a metalloid element.

In the case where the metal oxide is an In-M-Zn oxide, the atomic ratio of In is preferably higher than or equal to the atomic ratio of M in the In-M-Zn oxide. Examples of the atomic ratio of the metal elements of such an In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood thereof. Note that a composition in the neighborhood includes the range of ±30% of an intended atomic ratio. By increasing the atomic ratio of indium in the metal oxide, the on-state current, field-effect mobility, or the like of the transistor can be improved.

The atomic ratio of In may be less than that of M in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood thereof. By increasing the atomic ratio of M in the metal oxide, generation of oxygen vacancies can be inhibited.

For the semiconductor layer 21, for example, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, In—Ga—Al—Zn oxide, or the like can be used. Alternatively, Ga—Zn oxide may be used.

Note that the metal oxide may contain, instead of indium or in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. A transistor containing the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used to form the metal oxide. Note that in the case where the metal oxide is formed by a sputtering method, the composition of the deposited metal oxide may be different from the composition of a target. In particular, the content percentage of zinc in the deposited metal oxide may be reduced to approximately 50% of that of the target.

In this specification and the like, the content percentage of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by A_{X}, A_{Y}, and A_{Z}, the content percentage of the metal element X can be represented by A_{X}/(A_{X}+A_{Y}+A_{Z}). Moreover, in the case where the atomic ratio of the metal element X to the metal element Y to the metal element Z contained in the metal oxide is represented by Bₓ:B_{Y}:B_{Z}, the content percentage of the metal element X can be represented by Bₓ/(Bₓ+B_{Y}+B_{Z}).

For example, in the case of the metal oxide containing In, a higher content percentage of In enables the transistor to have a higher on-state current.

With use of a metal oxide that does not contain Ga or has a low Ga content percentage for the semiconductor layer 21, the transistor can be highly reliable against positive bias application. That is, the amount of change in the threshold voltage of the transistor in the PBTS (Positive Bias Temperature Stress) test can be small. Meanwhile, with use of a metal oxide that contains Ga, the Ga content percentage is preferably lower than the In content percentage. Thus, the transistor with high mobility and high reliability can be obtained.

Meanwhile, the high content percentage of Ga enables the transistor to be highly reliable against light. That is, the amount of change in the threshold voltage of the transistor in the NBTIS (Negative Bias Temperature Illumination Stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high zinc content percentage has high crystallinity, whereby diffusion of impurities in the metal oxide can be inhibited. Consequently, a change in electrical characteristics of the transistor can be inhibited, and the reliability of the transistor can be improved.

The semiconductor layer 21 may have a stacked-layer structure of two or more metal oxide layers. The two or more metal oxide layers included in the semiconductor layer 21 may have the same or substantially the same composition. Employing a stacked-layer structure of metal oxide layers having the same composition can reduce the manufacturing cost because the metal oxide layers can be formed using the same sputtering target, for example. Note that a stacked-layer structure including two or more oxide semiconductor layers having different compositions may be employed. The use of an ALD method enables formation of a metal oxide layer with a composition that continuously changes in the thickness direction. This not only expands the range of choices for design as compared with the case of using a film with a predetermined composition but also prevents generation of an interface state between two layers with different compositions, for example; thus, the electrical characteristics and reliability can be improved.

In the case where the semiconductor layer 21 has a two-layer structure, the second layer, i.e., the layer closer to the gate electrode, preferably uses a material with higher mobility (higher conductivity) than the first layer. This enables the transistor to be normally off and have a high on-state current. Consequently, both low power consumption and high performance can be achieved. Alternatively, the first layer, i.e., the layer in contact with the source electrode and the drain electrode, may use a material having higher mobility than the second layer. In that case, contact resistance between the semiconductor layer 21 and the source electrode or the drain electrode can be reduced and the parasitic resistance can be reduced accordingly, so that the transistor can have a high on-state current.

In the case where the semiconductor layer 21 has a three-layer structure, the second layer preferably uses a material having higher mobility than the first and third layers. This enables the transistor to have a high on-state current and high reliability.

The above-described differences in mobility and conductivity can be rephrased as a difference in the indium content percentage, for example. In addition, the mobility and the conductivity are affected by whether or not an element that contributes to an improvement in conductivity is contained in addition to indium, by the content of the element, or the like. Examples of high-mobility materials include a material of In:Ga:Zn=4:3:2 [atomic ratio] or in the neighborhood thereof, a material of In:Zn=1:1 [atomic ratio] or in the neighborhood thereof, a material of In:Zn=4:1 or in the neighborhood thereof, and a material of In:Sn:Zn=40:X:10 [atomic ratio] (X is greater than or equal to 0.1 and less than or equal to 5, typically X=1) or in the neighborhood thereof. Examples of materials having lower mobility or conductivity than the above-described materials include a material of In:Ga:Zn=1:3:2 [atomic ratio] or in the neighborhood thereof, a material of In:Ga:Zn=1:3:4 [atomic ratio] or in the neighborhood thereof, a material of In:Ga:Zn=2:2:1 [atomic ratio] or in the neighborhood thereof, a material of In:Ga:Zn=1:1:1 [atomic ratio] or in the neighborhood thereof, and a material of In:Ga:Zn=1:1:2 [atomic ratio] or in the neighborhood thereof.

It is preferable to use a metal oxide layer having crystallinity as the semiconductor layer 21. For example, a metal oxide layer having a CAAC (c-axis aligned crystal) structure, a polycrystalline structure, a nano-crystal (nc) structure, or the like can be used. With the use of the metal oxide layer having crystallinity as the semiconductor layer 21, the density of defect states in the semiconductor layer 21 can be reduced, which enables the semiconductor device to have high reliability.

The higher the crystallinity of the metal oxide layer used as the semiconductor layer 21 is, the lower the density of defect states in the semiconductor layer 21 can be. By contrast, the use of a metal oxide layer having low crystallinity enables a transistor to allow a large amount of current to flow therethrough.

A transistor using an oxide semiconductor (hereinafter referred to as an OS transistor) has a much higher field-effect mobility than a transistor using amorphous silicon. In addition, the OS transistor has an extremely low leakage current between a source and a drain in an off state (hereinafter also referred to as off-state current), and charge accumulated in a capacitor that is connected in series with the transistor can be held for a long period. Furthermore, power consumption of the semiconductor device can be reduced when the OS transistor is used.

The semiconductor device of one embodiment of the present invention can be used for a display device, for example. To increase the emission luminance of a light-emitting device included in a pixel circuit in the display device, it is necessary to increase the amount of a current flowing through the light-emitting device. For this, it is necessary to increase the source-drain voltage of a driving transistor included in the pixel circuit. Since the OS transistor has a higher breakdown voltage between the source and the drain than a transistor using silicon (hereinafter referred to as a Si transistor), a high voltage can be applied between the source and the drain of the OS transistor. Accordingly, when the OS transistor is used as the driving transistor included in the pixel circuit, the amount of a current flowing through the light-emitting device can be increased, so that the emission luminance of the light-emitting device can be increased.

In the case where transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of a current flowing through the light-emitting device can be precisely controlled. Accordingly, the number of gray levels in the pixel circuit can be increased. Moreover, current can be made to flow stably even when the electrical characteristics (e.g., resistance) of the light-emitting device change or the electrical characteristics of the light-emitting device vary.

As described above, with the use of an OS transistor as the driving transistor included in the pixel circuit, it is possible to achieve “inhibition of black-level degradation,” “increase in emission luminance,” “increase in gray level,” “inhibition of the effect of variation in characteristics among light-emitting devices,” and the like.

A change in electrical characteristics of an OS transistor due to exposure to radiation is small, i.e., an OS transistor has high tolerance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a neutron beam, a proton beam, and a neutron beam).

Note that the semiconductor material that can be used for the semiconductor layer 21 is not limited to the oxide semiconductor. For example, a semiconductor of a single element or a compound semiconductor can be used. Examples of the semiconductor of a single element include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. Note that these semiconductor materials may contain an impurity as a dopant.

Alternatively, the semiconductor layer 21 may contain a layered substance that functions as a semiconductor. The layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be obtained.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used, in which case deterioration of the transistor characteristics can be inhibited.

### <Gate Insulating Layer>

The insulating layer 22 functions as the gate insulating layer of the transistor. In the case where the semiconductor layer 21 is formed using an oxide semiconductor, an oxide insulating film is preferably used as at least a film of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, for the insulating layer 22, a nitride insulating film of silicon nitride, silicon nitride oxide, aluminum nitride, or aluminum nitride oxide can also be used. The insulating layer 22 may have a stacked-layer structure, e.g., a stacked-layer structure including at least one oxide insulating film and at least one nitride insulating film.

### <Conductive Layer>

For the conductive layer 31 and the conductive layer 32, it is preferable to use tantalum nitride, titanium nitride, a nitride containing titanium and aluminum, a nitride containing tantalum and aluminum, ruthenium, ruthenium oxide, ruthenium nitride, an oxide containing strontium and ruthenium, an oxide containing lanthanum and nickel, or the like, for example. These materials are preferable because they are conductive materials that are less likely to be oxidized or materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn oxide, In—Sn—Si oxide, or Ga—Zn oxide for the conductive layer 31 and the conductive layer 32. A conductive oxide containing indium is particularly preferable because of its high conductivity.

The conductive layer 23 functions as the gate electrode, and a variety of conductive materials can be used. For the conductive layer 23, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like, or an alloy containing any of the above metal elements as its component, for example. A nitride or an oxide of any of the above metals or the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

For the conductive layer 23, the nitride or the oxide that can be used for the conductive layer 31 and the conductive layer 32 may be used.

The conductive layer 31 and the conductive layer 32 function also as wirings; thus, stacked low-resistance conductive materials can be used. The resistance of the conductive layer 33 is preferably as low as possible. For the conductive layer 31, the conductive layer 32, and the conductive layer 33, a conductive material similar to that for the conductive layer 23 can be used.

### <Insulating Layer>

The insulating layer 41 (or the insulating layer 41b) includes a region that is in contact with the semiconductor layer 21. In the case where the semiconductor layer 21 uses an oxide semiconductor, an oxide is preferably used for at least the region of the insulating layer 41 that is in contact with the semiconductor layer 21 in order to improve the properties of the interface between the semiconductor layer 21 and the insulating layer 41. For example, silicon oxide or silicon oxynitride can be suitably used.

A film from which oxygen is released by heating is further preferably used for the insulating layer 41. Accordingly, oxygen can be supplied to the semiconductor layer 21 owing to heat applied during the manufacturing process of the transistor 10; thus, the amount of oxygen vacancies in the semiconductor layer 21 can be reduced, and reliability can be improved. Examples of a method for supplying oxygen to the insulating layer 41 include heat treatment in an oxygen atmosphere and plasma treatment in an oxygen atmosphere. Alternatively, an oxide film may be deposited over the top surface of the insulating layer 41 by a sputtering method in an oxygen atmosphere to supply oxygen. After that, the oxide film may be removed.

The insulating layer 41 is preferably formed by a deposition method such as a sputtering method or a plasma CVD method. In particular, by a sputtering method as a deposition method using a deposition gas not containing a hydrogen gas, a film having an extremely low hydrogen content can be deposited. Consequently, supply of hydrogen to the semiconductor layer 21 can be inhibited, and the electrical characteristics of the transistor 10 can be stabilized.

For the insulating layer 41a and the insulating layer 41c, films in which oxygen is less likely to diffuse are preferably used. Accordingly, it is possible to prevent oxygen contained in the insulating layer 41b from being transmitted to the insulating layer 11 side through the insulating layer 41a and being transmitted to the insulating layer 22 side through the insulating layer 41c by heating. In other words, when the insulating layer 41b is interposed between the insulating layer 41a therebelow and the insulating layer 41c thereabove in which oxygen is less likely to diffuse, oxygen can be enclosed in the insulating layer 41b. Accordingly, oxygen can be effectively supplied to the semiconductor layer 21.

For the insulating layer 41a and the insulating layer 41c, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide are particularly suitable for the insulating layer 41a and the insulating layer 41c because they release fewer impurities (e.g., water and hydrogen) and are less likely to transmit oxygen and hydrogen.

### MODIFICATION EXAMPLES

Structure examples partly different from the above structure examples will be described below. Note that the description of examples similar to those described above will be omitted as appropriate. Although modification examples of FIG. 2A to FIG. 2C are mainly described here, the modification examples can also be applied to the structure example illustrated in FIG. 3A and FIG. 3B as appropriate.

### Modification Example 1

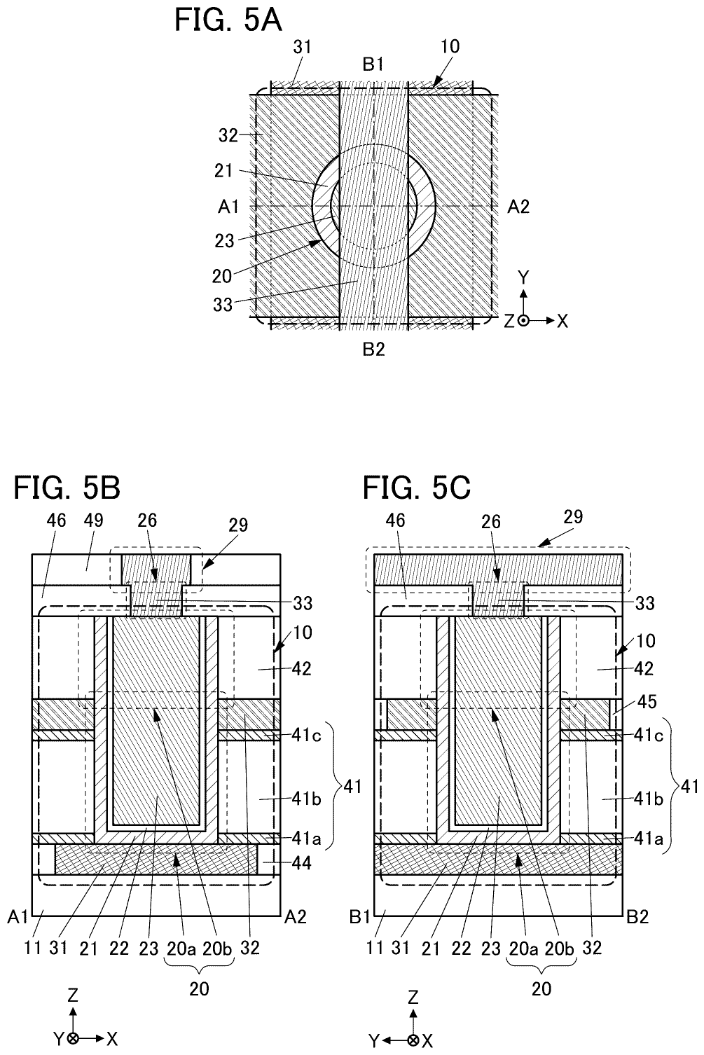

FIG. 5A, FIG. 5B, and FIG. 5C illustrate an example in which the sidewall of the opening portion 20a and the sidewall of the opening portion 20b are provided as one plane (in other words, aligned with each other). In the semiconductor device illustrated in FIG. 5A to FIG. 5C, the opening portion 20a and the opening portion 20b can be formed in the same step; thus, the manufacturing process can be simplified as compared with that of the semiconductor device illustrated in FIG. 2A to FIG. 2C. Meanwhile, in the semiconductor device illustrated in FIG. 2A to FIG. 2C, the area occupied by the transistor 10 can be decreased, for example. Thus, the transistor included in the semiconductor device can be miniaturized as compared with the transistor included in the semiconductor device illustrated in FIG. 5A to FIG. 5C, while the semiconductor device can be highly reliable. In the semiconductor device illustrated in FIG. 2A to FIG. 2C, the semiconductor layer 21 can include a region in contact with not only the side surface but also the top surface of the conductive layer 32. This enables the conductive layer 32 and the semiconductor layer 21 to be in favorable contact with each other and thus enables the semiconductor device to have high reliability.

### Modification Example 2

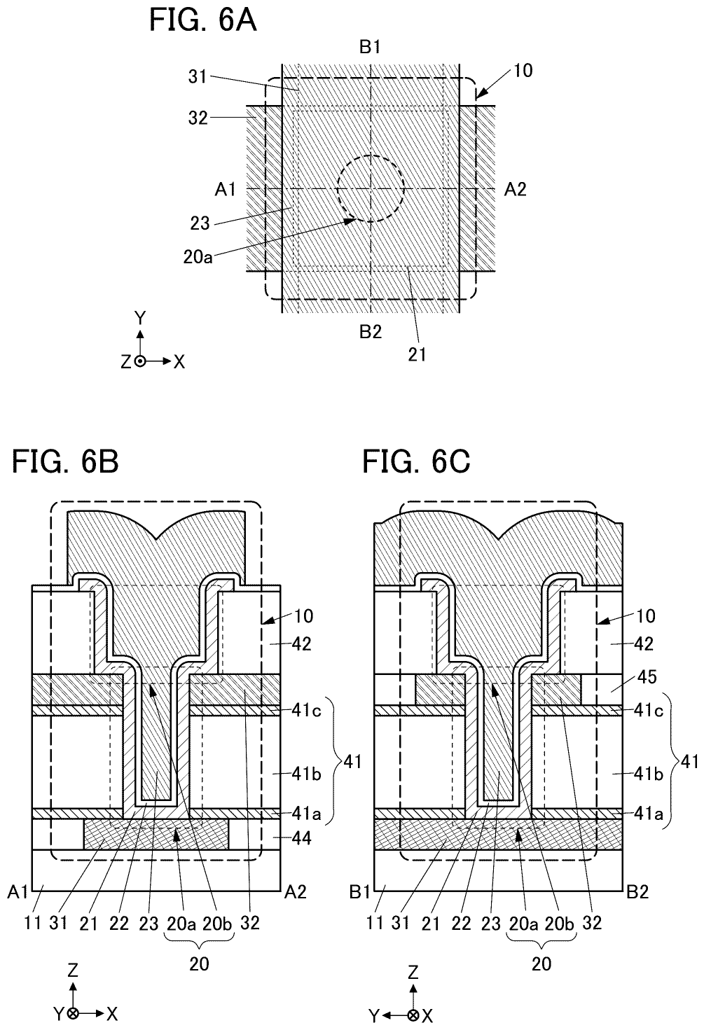

FIG. 6A, FIG. 6B, and FIG. 6C illustrate an example in which the semiconductor layer 21, the insulating layer 22, and the conductive layer 23 include a region positioned outside the opening portion 20. In the example illustrated in FIG. 6A to FIG. 6C, the semiconductor layer 21, the insulating layer 22, and the conductive layer 23 include a region positioned over the insulating layer 42. FIG. 6B and FIG. 6C illustrate an example in which the insulating layer 22 is provided to cover the side surface of the semiconductor layer 21 outside the opening portion 20. Furthermore, FIG. 6A to FIG. 6C illustrate an example in which the side surface of the conductive layer 23 outside the opening portion 20 is positioned outward (on the side opposite to the opening 20) from the side surface of the semiconductor layer 21 outside the opening portion 20. Note that the side surface of the conductive layer 23 outside the opening portion 20 may be positioned inward (on the opening portion 20 side) from the side surface of the semiconductor layer 21 outside the opening portion 20. Although FIG. 6A to FIG. 6C illustrate an example in which the insulating layer 22 is not patterned, the insulating layer 22 may be patterned. For example, the insulating layer 22 and the conductive layer 23 may be formed to have the same pattern. In that case, the side surface of the insulating layer 22 outside the opening portion 20 and the side surface of the conductive layer 23 outside the opening portion 20 can be aligned with each other. Here, in the semiconductor device illustrated in FIG. 6A to FIG. 6C, the conductive layer 23 functioning as the gate electrode can be led without providing the insulating layer 46, the insulating layer 49, and the conductive layer 33. When a planarized insulating layer (also referred to as a planarization layer) is provided to cover the conductive layer 23, a step formed by the conductive layer 23 can be reduced.

### Modification Example 3

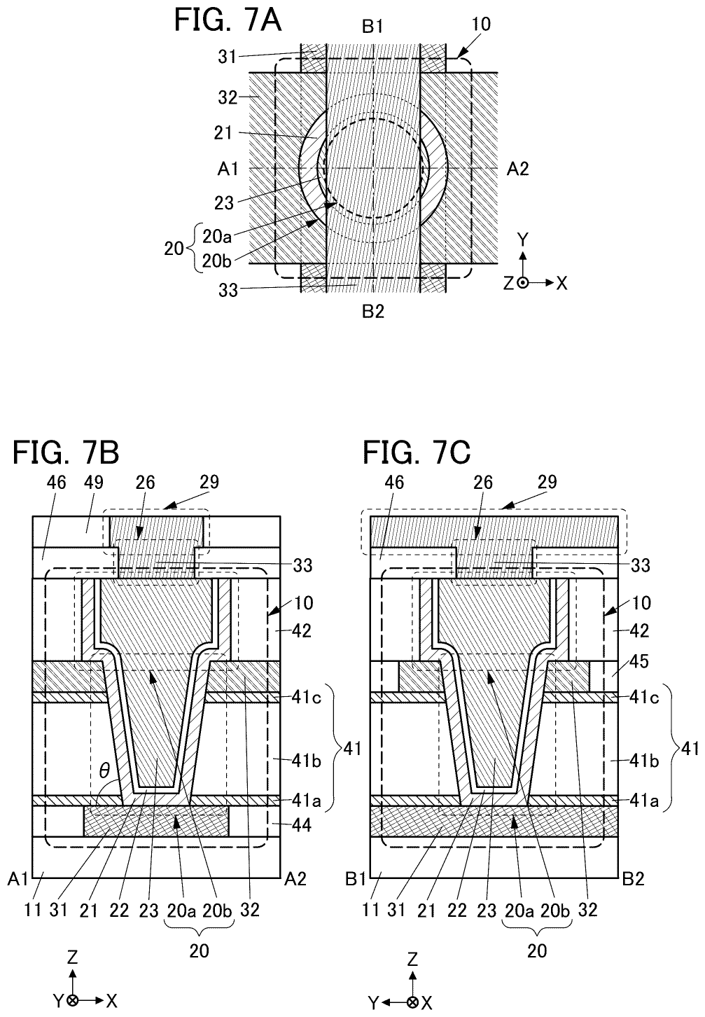

FIG. 7A, FIG. 7B, and FIG. 7C illustrate an example in which the sidewall of the opening portion 20a has a tapered shape. In the transistor 10 illustrated in FIG. 7A to FIG. 7C, the diameter (opening diameter) of the upper end of the opening portion 20a is larger than the diameter (opening diameter) of the lower end thereof.

In this specification and the like, the tapered shape refers to a shape such that at least part of a side surface of a component is inclined to a substrate surface or a formation surface. For example, the tapered shape preferably includes a region where the angle formed between the inclined side surface and the substrate surface or the formation surface (the angle is also referred to as a taper angle) is less than 90°. Note that the side surface of the component, the substrate surface, and the formation surface are not necessarily completely flat and may be substantially flat with a slight curvature or substantially flat with slight unevenness.

The tapered shape of the sidewall of the opening portion 20a improves the coverage with the semiconductor layer 21, for example, so that generation of defects such a low-density region in the film can be inhibited even when a deposition method such as a sputtering method is used. The angle θ can be, for example, greater than or equal to 45° and less than or equal to 90°, greater than or equal to 60° and less than 90°, or greater than or equal to 70° and less than 90°. Note that the angle θ may be greater than 90° in the case where a deposition method achieving an extremely high coverage, such as an ALD method, is used.

In the case where the sidewall of the opening portion 20a has a tapered shape, the diameter of the opening portion 20a, which corresponds to the channel width of the transistor 10, increases from the conductive layer 31 side toward the insulating layer 42 side. The amount of current flowing through the transistor 10 at this time is limited by a region with the minimum diameter. Hence, the channel width of the transistor 10 can be regarded as the perimeter of the region with the minimum diameter. Thus, when the sidewall of the opening portion 20a has a tapered shape, the transistor 10 with a channel width smaller than the diameter of the upper end of the opening portion 20a can be manufactured.

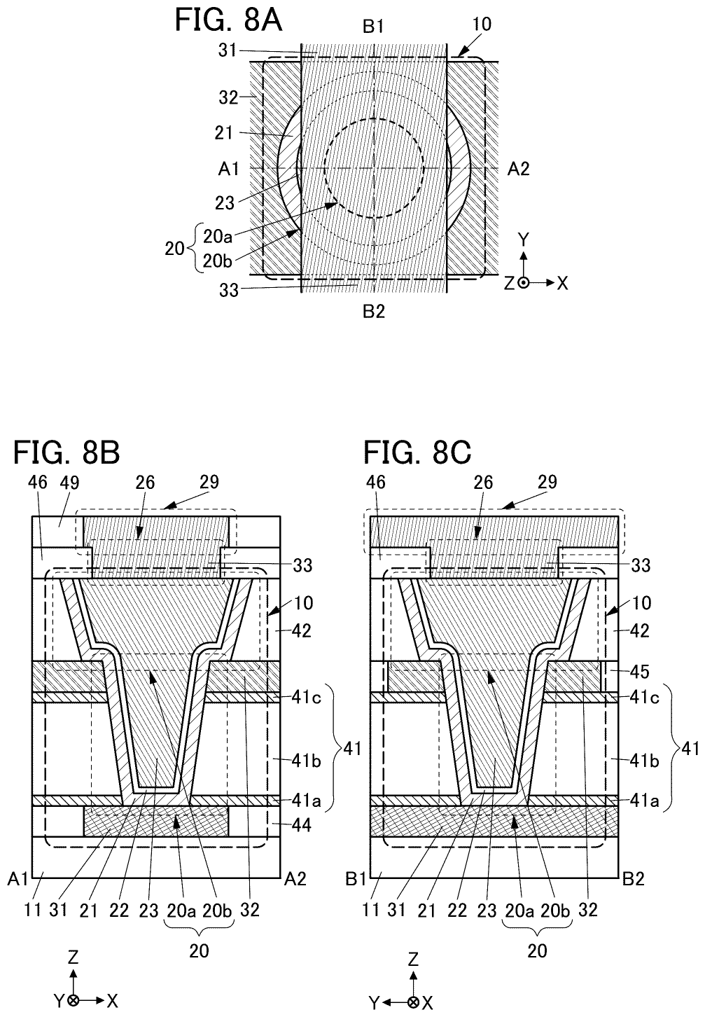

FIG. 8A to FIG. 8C illustrate an example in which not only the sidewall of the opening portion 20a but also the sidewall of the opening portion 20b has a tapered shape. In the transistor 10 illustrated in FIG. 8A to FIG. 8C, the diameter (opening diameter) of the upper end of not only the opening portion 20a but also the opening portion 20b is larger than the diameter (opening diameter) of the lower end thereof.

As illustrated in FIG. 8B and FIG. 8C, the diameter of the upper end of the opening portion 20b is preferably larger than the diameter of the lower end thereof, in which case the contact area between the conductive layer 23 and the conductive layer 33 can be increased.

### Modification Example 4

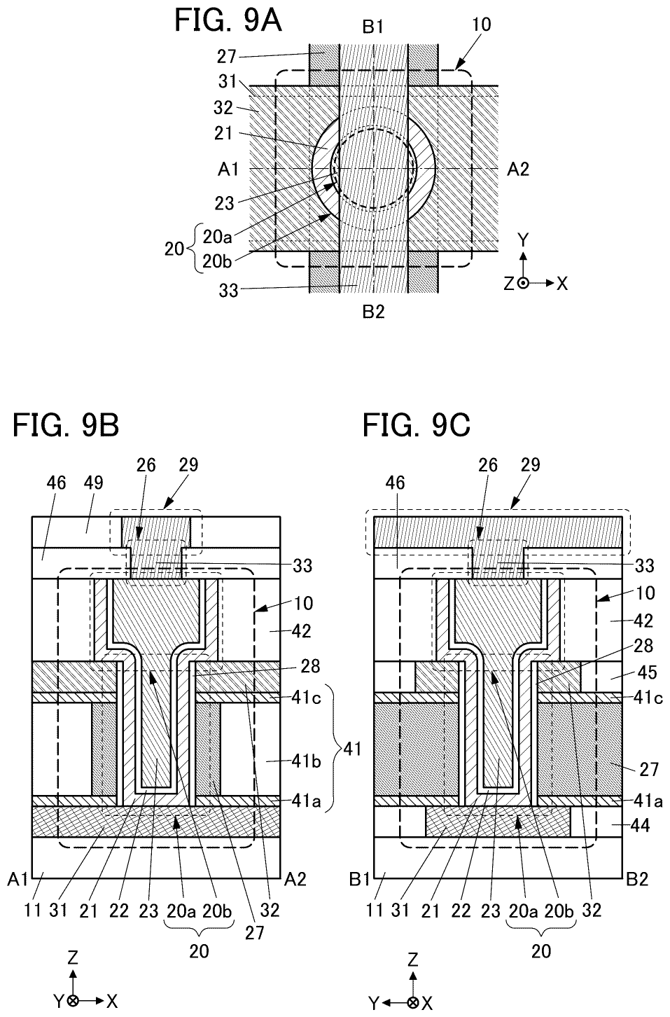

FIG. 9A, FIG. 9B, and FIG. 9C illustrate an example in which the transistor 10 includes a conductive layer 27 and an insulating layer 28.

The conductive layer 27 functions as a second gate electrode (or a back gate electrode). The insulating layer 28 is positioned between the conductive layer 27 and the semiconductor layer 21 and functions as a second gate insulating layer (or a back gate insulating layer). A fixed potential or a given signal can be supplied to the conductive layer 27. When the conductive layer 27 is provided and a fixed potential is supplied to the conductive layer 27, the potential of the back channel side of the semiconductor layer 21 can be fixed, so that variation in electrical characteristics can be reduced. The conductive layer 27 may be electrically connected to any one of the conductive layer 31, the conductive layer 32, and the conductive layer 33.

The conductive layer 27 is embedded in the insulating layer 41b. Thus, the conductive layer 27 is provided between the insulating layer 41a and the insulating layer 41c. The insulating layer 28 is provided along the side surfaces of the insulating layer 41a, the conductive layer 27, the insulating layer 41c, and the conductive layer 32. For example, the insulating layer 28 can be formed in the following manner: an opening portion is formed in the conductive layer 32, the insulating layer 41c, the conductive layer 27, and the insulating layer 41a, an insulating film covering the opening portion is deposited by a deposition method with high coverage, and then anisotropic etching is performed. Here, the semiconductor layer 21 includes a region in contact with the top surface of the conductive layer 32; thus, the semiconductor layer 21 and the conductive layer 32 can be electrically connected to each other.

FIG. 9A to FIG. 9C illustrate an example in which the conductive layer 31 and the conductive layer 32 extend in the X direction and the conductive layer 27 and the conductive layer 33 extend in the Y direction. In the case where the conductive layer 31 and the conductive layer 27 extend in different directions, parasitic capacitance between the conductive layer 31 and the conductive layer 27 can be reduced as compared with the case where the conductive layer 31 and the conductive layer 27 extend in the same direction. In the case where the conductive layer 27 and the conductive layer 32 extend in different directions, parasitic capacitance between the conductive layer 27 and the conductive layer 32 can be reduced as compared with the case where the conductive layer 27 and the conductive layer 32 extend in the same direction. Note that the conductive layer 31 and the conductive layer 27 may extend in the same direction, or the conductive layer 27 and the conductive layer 32 may extend in the same direction. Here, when the thickness of the insulating layer 41a is increased, the parasitic capacitance between the conductive layer 31 and the conductive layer 27 can be reduced, and when the thickness of the insulating layer 41c is increased, the parasitic capacitance between the conductive layer 27 and the conductive layer 32 can be reduced.

### Modification Example 5

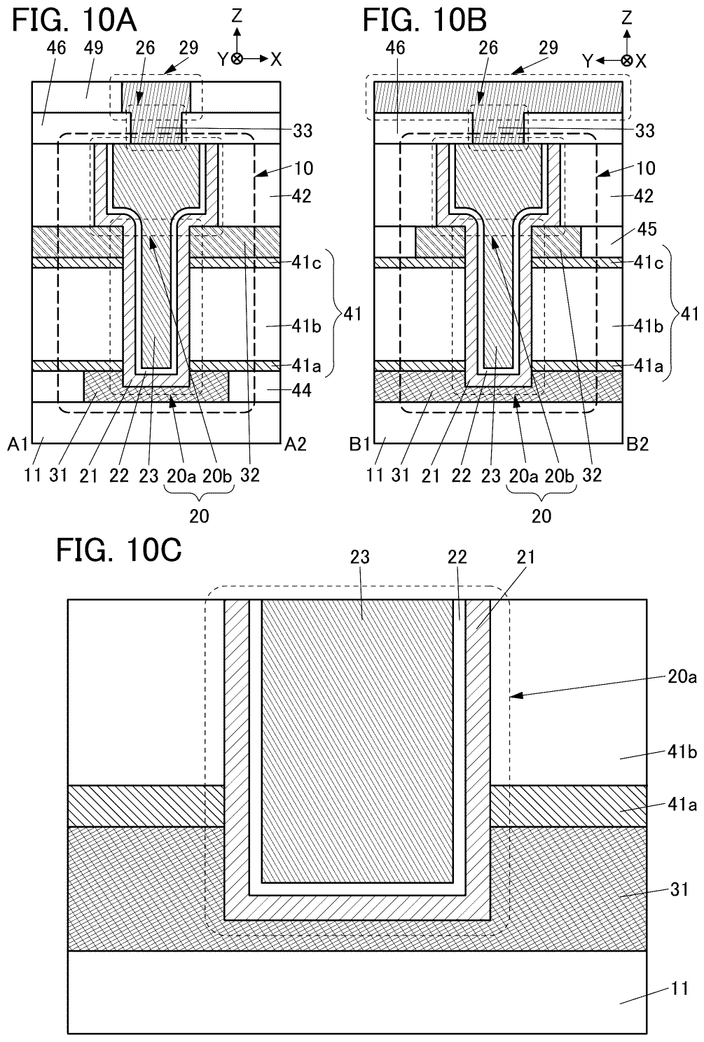

FIG. 10A and FIG. 10B illustrate an example in which a depressed portion is provided in the conductive layer 31 illustrated in FIG. 2B and FIG. 2C. Note that FIG. 2A can be referred to for the plan view. FIG. 10C is an enlarged view of the conductive layer 31 and its peripheral region illustrated in FIG. 10A and FIG. 10B.

In the transistor 10 illustrated in FIG. 10A and FIG. 10B, the semiconductor layer 21, the insulating layer 22, and the conductive layer 23 are provided along the depressed portion in the conductive layer 31. In that case, the level of the bottom surface of the conductive layer 23 is preferably lower than the level of the uppermost surface of the conductive layer 31, as illustrated in FIG. 10C.

In the transistor 10 illustrated in FIG. 10A and FIG. 10B, a region of the semiconductor layer 21 that is in contact with the conductive layer 31 has a lower resistance than the channel formation region. Thus, the bottom surface of the conductive layer 23 being at a lower position than the uppermost surface of the conductive layer 31 as illustrated in FIG. 10C enables a gate electric field to be uniformly applied to the whole channel formation region of the semiconductor layer 21, thereby preventing formation of a high-resistance region (offset region) due to poor application of a gate electric field to the semiconductor layer 21. As a result, the on-state current of the transistor can be increased. To achieve such a structure, for example, the thickness of the conductive layer 31 is made larger than the sum of the thickness of the semiconductor layer 21 and the thickness of the insulating layer 22.

### Modification Example 6

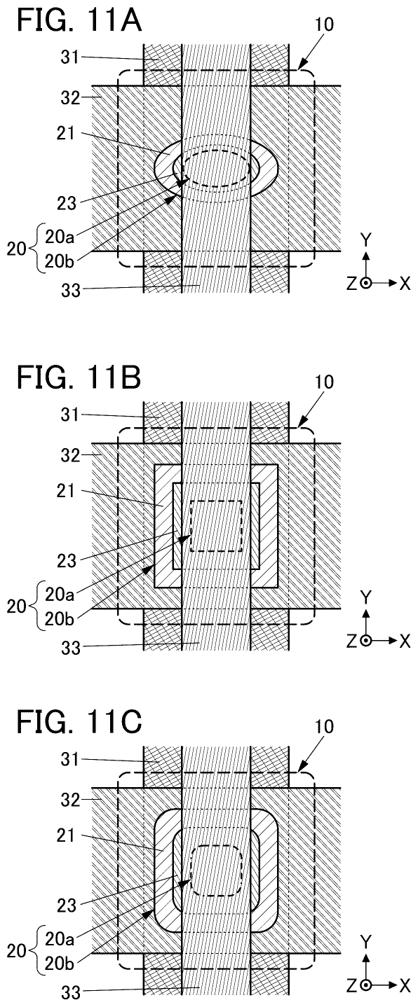

FIG. 11A illustrates an example in which the opening portion 20a and the opening portion 20b illustrated in FIG. 2A have an elliptical shape in a plan view. Although FIG. 11A illustrates an example in which the major axis of the ellipse is parallel to the X direction, the major axis of the ellipse may be parallel to the Y direction or may be parallel to neither the X direction nor the Y direction.

FIG. 11B illustrates an example in which the opening portion 20a and the opening portion 20b illustrated in FIG. 2A have a quadrangular shape in a plan view. Although the opening portion 20a and the opening portion 20b have a square shape in the plan view in FIG. 11B, the opening portion 20a and the opening portion 20b are not limited to this shape in the plan view, and may have the shape of a rectangle, a rhombus, or a parallelogram, for example. Furthermore, the opening portion 20a and the opening portion 20b may have the shape of, for example, a triangle, a polygon with five or more sides, or a star in the plan view.

FIG. 11C illustrates an example in which the corners of the opening portion 20a and the opening portion 20b illustrated in FIG. 11B are rounded. That is, FIG. 11C illustrates an example in which the opening portion 20a and the opening portion 20b have the shape of a quadrangle with rounded corners in a plan view. Although the opening portion 20a and the opening portion 20b in the plan view in FIG. 11C have the shape of a square with rounded corners, the opening portion 20a and the opening portion 20b are not limited to this shape in the plan view, and may have the shape of, for example, a rectangle with rounded corners, a rhombus with rounded corners, a parallelogram with rounded corners, a triangle with rounded corners, a polygon with five or more sides and rounded corners, or a star with rounded corners.

Although FIG. 2A, FIG. 11A to FIG. 11C, and the like illustrate examples in which the shape of the opening portion 20b in the plan view is similar to the shape of the opening portion 20a in the plan view, the shape of the opening portion 20a in the plan view and the shape of the opening portion 20b in the plan view may be of different types. For example, the opening portion 20a may have the shape of a circle or an ellipse in the plan view, and the opening portion 20b may have the shape of a quadrangle or a quadrangle with rounded corners in the plan view. The opening portion 20a may have the shape of a quadrangle in the plan view, and the opening portion 20b may have the shape of a quadrangle with rounded corners, a circle, or an ellipse in the plan view.

### Modification Example 7

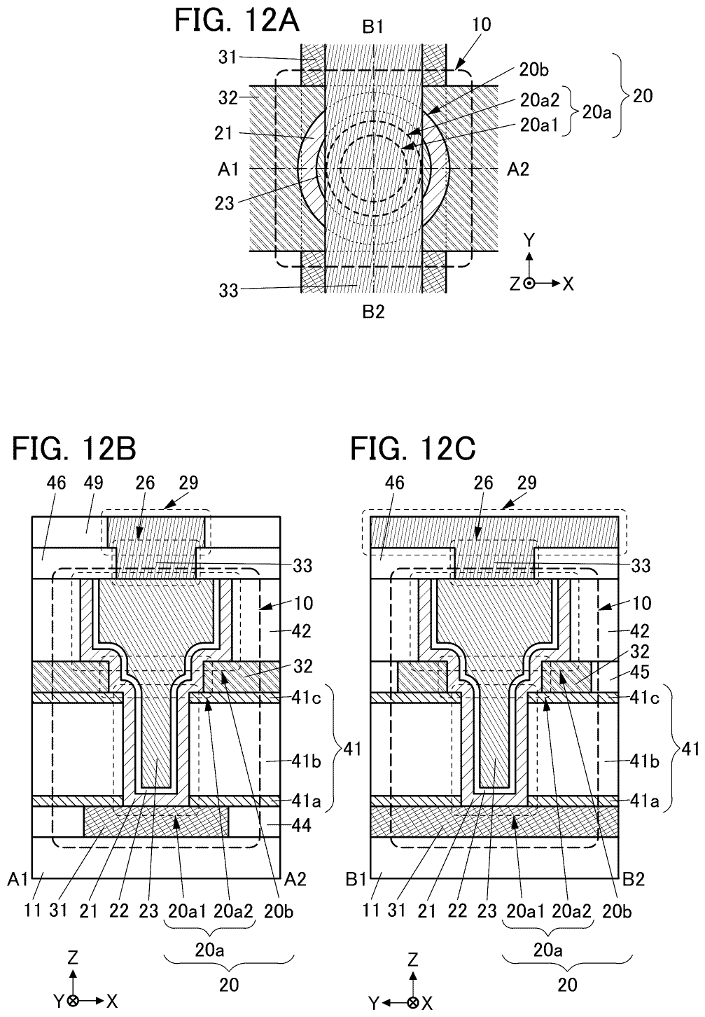

FIG. 12A, FIG. 12B, and FIG. 12C illustrate an example in which the shape of the opening portion 20a provided in the insulating layer 41 in the plan view is not identical with the shape of the opening portion 20a provided in the conductive layer 32 in the plan view. Here, in FIG. 12A to FIG. 12C, the opening portion 20a provided in the insulating layer 41 is denoted as an opening portion 20a1, and the opening portion 20a provided in the conductive layer 32 is denoted as an opening portion 20a2. In the example illustrated in FIG. 12A to FIG. 12C, the shape of the opening portion 20a2 in the plan view is a circle having a larger radius than the opening portion 20a1. Note that one or both of the shape of the opening portion 20a1 in the plan view and the shape of the opening portion 20a2 in the plan view are not necessarily circular. For example, one or both of the shape of the opening portion 20a1 in the plan view and the shape of the opening portion 20a2 in the plan view can have the above-described possible shape of the opening portion 20a, such as an ellipse, a quadrangle, or a quadrangle with rounded corners.

Although FIG. 12A to FIG. 12C illustrate an example in which the area of the opening portion 20a2 in the plan view is larger than the area of the opening portion 20a1 in the plan view, the area of the opening portion 20a2 in the plan view may be smaller than the area of the opening portion 20a1 in the plan view. In that case, the conductive layer 32 includes a region that protrudes beyond the sidewall of the opening portion 20a1.

For example, in the case where the opening portion 20a1 and the opening portion 20a2 are formed in different steps, the shape of the opening portion 20a1 in the plan view may be different from the shape of the opening portion 20a2 in the plan view. In the case where the opening portion 20a1 and the opening portion 20a2 are formed in the same step but the etching rate of the conductive layer 32 in the X direction and the Y direction is different from the etching rate of the insulating layer 41 in the X direction and the Y direction, for example, the shape of the opening portion 20a1 in the plan view is sometimes different from the shape of the opening portion 20a2 in the plan view. For example, in the case where the opening portion 20a1 and the opening portion 20a2 are formed in the same step but the etching rate of the conductive layer 32 in the X direction and the Y direction is higher than the etching rate of the insulating layer 41 in the X direction and the Y direction, the area of the opening portion 20a2 in the plan view is sometimes larger than the area of the opening portion 20a1 in the plan view.

The above is the description of the modification examples. The above-described structures can be employed in appropriate combination.

### Manufacturing Method Example 1

Next, a method for manufacturing the semiconductor device of one embodiment of the present invention is described. Here, an example of a method for manufacturing the transistor 10 illustrated in FIG. 2B and FIG. 2C is described.

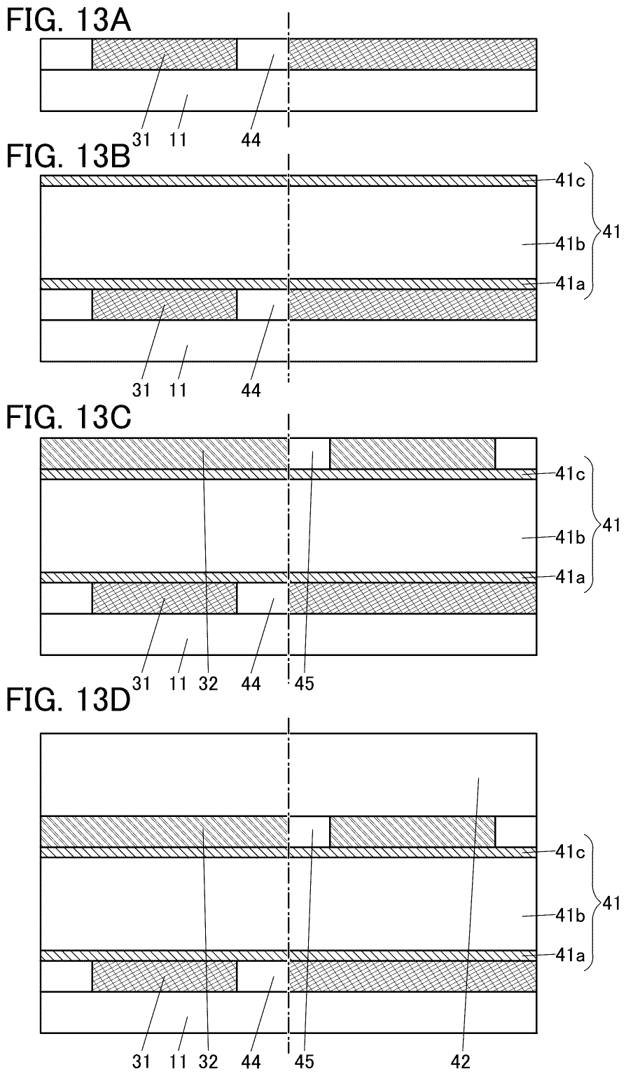

FIG. 13A to FIG. 16B are cross-sectional views of steps in the manufacturing method of the semiconductor device described below as an example. In each drawing, a cross section corresponding to FIG. 2B is shown on the left side, and a cross section corresponding to FIG. 2C is shown on the right side.

Hereinafter, an insulating material for forming an insulating layer, a conductive material for forming a conductive layer, and a semiconductor material for forming a semiconductor layer can be deposited by a sputtering method, a CVD method, an MBE (Molecular Beam Epitaxy) method, a PLD (Pulsed Laser Deposition) method, an ALD method, or the like as appropriate.

Note that examples of the sputtering method include an RF (Radio Frequency) sputtering method in which a high-frequency power source is used as a sputtering power source, a DC (Direct Current) sputtering method in which a DC power source is used, and a pulsed DC sputtering method in which voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD method using plasma, a thermal CVD method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method does not use plasma and thus enables less plasma damage to an object to be processed. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, or the like can be used.

Unlike the sputtering method, the CVD method and the ALD method are deposition methods that enable favorable step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, e.g., the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors. Furthermore, a film whose composition is continuously changed can be deposited as in the CVD method.

First, a substrate (not illustrated) is prepared, and the insulating layer 11 is formed over the substrate (FIG. 13A). As the insulating layer 11, an inorganic insulating film such as a silicon oxide film or a silicon oxynitride film can be used. The insulating layer 11 can be formed by a sputtering method, a CVD method, an MBE method, a PLD method, an ALD method, or the like. In the case where the formation surface of the insulating layer 11 is not flat, planarization treatment is preferably performed after the deposition of the insulating layer 11 so that the insulating layer 11 has a flat top surface.

Subsequently, a conductive film to be the conductive layer 31 is formed over the insulating layer 11. After that, a resist mask is formed over the conductive film by, for example, a photolithography method, a region of the conductive film that is not covered with the resist mask is removed by etching, and then, the resist mask is removed. Thus, the conductive layer 31 can be formed. Next, an insulating film to be the insulating layer 44 is deposited and a region thereof that overlaps with the conductive layer 31 is removed, whereby the insulating layer 44 and the conductive layer 31 embedded in the insulating layer 44 can be formed (FIG. 13A). The insulating film to be the insulating layer 44 is preferably processed by a CMP method; for example, the insulating layer 44 illustrated in FIG. 13A can be formed by processing the insulating film until the top surface of the conductive layer 31 is exposed.

Note that the insulating layer 44 and the conductive layer 31 may be formed in the following manner: after an insulating film to be the insulating layer 44 is formed first, an opening portion is formed in the insulating film, a conductive film is formed to fill the opening portion, and polishing treatment (planarization treatment) using a CMP method is performed until the top surface of the insulating film is exposed.

The top surface of the insulating layer 41 to be formed next can be made flat by performing planarization treatment such that the top surfaces of the insulating layer 44 and the conductive layer 31 are level with each other. Note that the insulating layer 44 is not necessarily provided and the insulating layer 41 may be provided to cover the conductive layer 31; in that case, the top surface of the insulating layer 41 is preferably subjected to planarization treatment by a CMP method so as to be a flat surface.

Next, the insulating layer 41a, the insulating layer 41b, and the insulating layer 41c (hereinafter collectively referred to as the insulating layer 41 in some cases) are formed over the conductive layer 31 and the insulating layer 44 (FIG. 13B). The insulating layer 41a, the insulating layer 41b, and the insulating layer 41c are formed by a sputtering method, a CVD method, an MBE method, a PLD method, an ALD method, or the like as appropriate.

Here, the thickness of the insulating layer 41 affects the channel length of the transistor; thus, it is important to prevent a variation in the thickness of the insulating layer 41.

When the insulating layer 41b is deposited by a sputtering method in an oxygen-containing atmosphere, the insulating layer 41b containing a large amount of oxygen therein can be formed. By using a sputtering method that does not need to use a molecule containing hydrogen as a deposition gas, the hydrogen concentration in the insulating layer 41b can be reduced. When the insulating layer 41b is deposited in this manner, oxygen can be supplied from the insulating layer 41b to the channel formation region of the semiconductor layer 21, so that oxygen vacancies can be reduced.

Next, the conductive layer 32 and the insulating layer 45 are formed over the insulating layer 41 (FIG. 13C). The conductive layer 32 and the insulating layer 45 can be formed by methods similar to those for the conductive layer 31 and the insulating layer 44.

Next, the insulating layer 42 is formed over the conductive layer 32 and the insulating layer 45 (FIG. 13D). The insulating layer 42 can be formed by a method similar to that for the insulating layer 41b, for example.

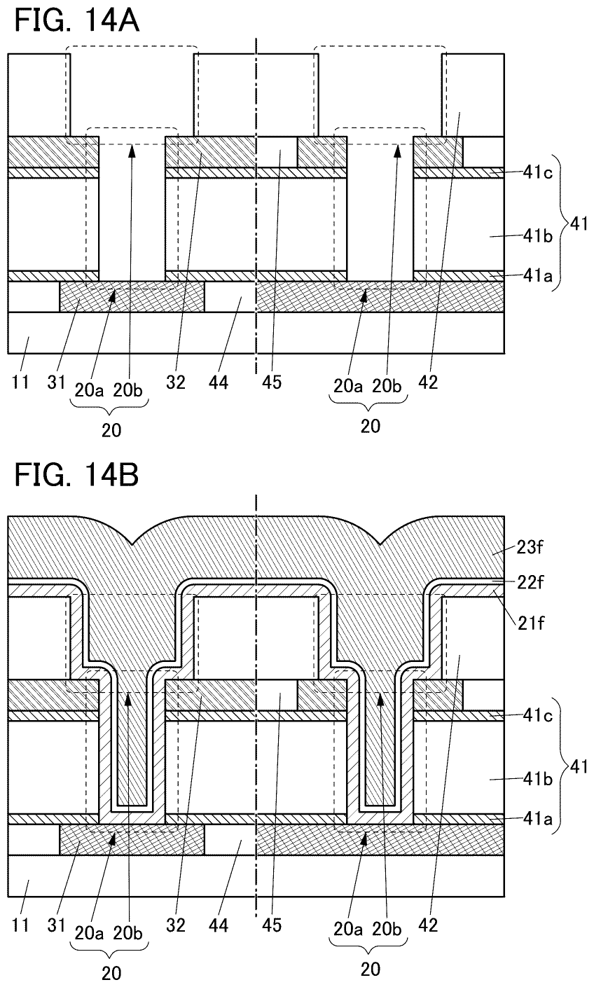

Then, part of the insulating layer 42 is processed to form the opening portion 20b reaching the conductive layer 32. After that, part of the conductive layer 32 and part of the insulating layer 41 are processed to form the opening portion 20a that includes a region overlapping with the opening portion 20b and reaches the conductive layer 31 (FIG. 14A). As described above, the opening portion 20a and the opening portion 20b can be regarded as one opening portion 20.

For example, a resist mask is formed first over the insulating layer 42 by a photolithography method, a region of the insulating layer 42 that is not covered with the resist mask is removed by etching, and then, the resist mask is removed. Thus, the opening portion 20b is formed in the insulating layer 42. After that, a resist mask is formed over the insulating layer 42 and the conductive layer 32 by a photolithography method, a region of the conductive layer 32 and the insulating layer 41 that is not covered with the resist mask is removed by etching, and then, the resist mask is removed. Thus, the opening portion 20a is formed in the conductive layer 32 and the insulating layer 41. Through the above steps, the opening portion 20 is formed in the insulating layer 41, the conductive layer 32, and the insulating layer 42. The opening portion 20 is preferably formed such that the diameter of the opening portion 20b is larger than the diameter of the opening portion 20a.

Here, the opening portion 20a may be formed in the same step as the opening portion 20b. Specifically, the opening portion 20a and the opening portion 20b may be formed under the same etching condition. Even in that case, the diameter of the opening portion 20b can be made larger than the diameter of the opening portion 20a by recession of the resist mask at the time of forming the opening portion 20a, for example. Since the insulating layer 41 can be processed using the conductive layer 32 as a hard mask and the insulating layer 42 can be processed in accordance with a resist pattern, the diameter of the opening portion 20b can be made larger than the diameter of the opening portion 20a by recession of the resist mask at the time of forming the opening portion 20a, even in the case where the opening portion 20a is formed in the same step as the opening portion 20b.

Note that the opening portion 20b may be formed in the insulating layer 42 to reach not only the conductive layer 32 but also the insulating layer 45. In that case, the insulating layer 42 is preferably etched under a condition where the etching rate of the insulating layer 42 is higher than the etching rate of the insulating layer 45, in which case the insulating layer 45 can be inhibited from being etched.

The sidewall of the opening portion 20 is preferably perpendicular to the top surface of the conductive layer 31. With such a structure, a transistor that occupies a small area can be manufactured. Alternatively, the sidewall of the opening portion 20 may have a tapered shape. The tapered shape can improve the coverage with a film formed inside the opening portion 20.

The maximum width of the opening portion 20a (the maximum diameter in the case where the opening portion 20a is circular in the plan view) is preferably as minute as possible. For example, the maximum width of the opening portion 20a is preferably less than or equal to 60 nm, less than or equal to 50 nm, less than or equal to 40 nm, less than or equal to 30 nm, or less than or equal to 20 nm and greater than or equal to 5 nm. Such a minute opening portion 20a is preferably formed by a lithography method using an electron beam or short-wavelength light such as EUV light. Note that the maximum width of the opening portion 20b can be larger than the maximum width of the opening portion 20a; like the opening portion 20a, the opening portion 20b is preferably formed by a lithography method using an electron beam or short-wavelength light such as EUV light.

Since the opening portion 20 has a high aspect ratio, anisotropic etching is preferably used for the formation of the opening portion 20. Processing by a dry etching method is particularly preferable because it is suitable for microfabrication. The condition of etching for the processing may be different between the insulating layer 42, the conductive layer 32, the insulating layer 41c, the insulating layer 41b, and the insulating layer 41a. Note that the angle of the sidewall of the opening portion 20b may be different from the angle of the sidewall of the opening portion 20a. The angle of the sidewall of the opening portion 20a may be different between the conductive layer 32, the insulating layer 41c, the insulating layer 41b, and the insulating layer 41a.

When the insulating layer 42 is etched, the upper portion of the conductive layer 32 is partly etched to reduce the thickness of the conductive layer 32 at the bottom portion of the opening portion 20b in some cases. When the insulating layer 41 is etched, the upper portion of the conductive layer 31 is partly etched to reduce the thickness of the conductive layer 31 at the bottom portion of the opening portion 20a in some cases. Alternatively, after the formation of the opening portion 20b and before the formation of the opening portion 20a, the upper portion of the conductive layer 32 may be partly etched to reduce the thickness of the conductive layer 32. The upper portion of the conductive layer 31 may be partly etched successively after the formation of the opening portion 20a to reduce the thickness of the conductive layer 31.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere. By the above-described heat treatment, impurities such as water contained in the insulating layer 41, for example, can be reduced before an oxide semiconductor film to be the semiconductor layer is deposited.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent, for example, entry of moisture into the insulating layer 41 as much as possible.

Next, a semiconductor film 21f is formed to cover the conductive layer 31, the insulating layer 41, the conductive layer 32, and the insulating layer 42 so as to include a region positioned inside the opening portion 20 (FIG. 14B). The semiconductor film 21f is a semiconductor film to be the semiconductor layer 21 later. An oxide semiconductor film can be used as the semiconductor film 21f. The semiconductor film 21f is formed by a sputtering method, a CVD method, an MBE method, a PLD method, an ALD method, or the like as appropriate. Here, the semiconductor film 21f is preferably formed in contact with the bottom portion and sidewall of the opening portion 20 with a high aspect ratio. Thus, the semiconductor film 21f is preferably formed by a deposition method with favorable coverage, and is further preferably formed by a CVD method, an ALD method, or the like. For example, an In—Ga—Zn oxide may be deposited by an ALD method as the semiconductor film 21f. In the case where the opening portion 20 has a tapered shape, the semiconductor film 21f can be deposited by a sputtering method.

During or after the deposition of the semiconductor film 21f, treatment for reducing the impurity concentration in the semiconductor film 21f, such as microwave treatment in an oxygen-containing atmosphere, is preferably performed. Note that specific examples of impurities include hydrogen and carbon. The microwave treatment can increase the crystallinity of the semiconductor film 21f in some cases. Here, the microwave treatment refers to, for example, treatment using an apparatus including a power source that generates high-density plasma with use of a microwave.

The microwave treatment in an oxygen-containing atmosphere can convert an oxygen gas into plasma using a high-frequency wave such as a microwave or RF and make the oxygen plasma act on the semiconductor film 21f for which an oxide semiconductor can be used. Oxygen that acts on the semiconductor film 21f has any of a variety of forms such as an oxygen atom, an oxygen molecule, an oxygen ion, and an oxygen radical (also referred to as O radical, which is an atom, a molecule, or an ion having an unpaired electron). Note that the oxygen that acts on the semiconductor film 21f has any one or more of the above forms, particularly suitably an oxygen radical.

The aforementioned microwave treatment in an oxygen-containing atmosphere is preferably performed while the substrate is heated, in which case the impurity concentration in the semiconductor film 21f can be further reduced. The substrate is heated at higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-containing atmosphere is performed while the substrate is heated, the carbon concentration in the semiconductor film 21f, which is measured by SIMS, can be lower than 1×10²⁰ atoms/cm³, preferably lower than 1×10¹⁹ atoms/cm³, further preferably lower than 1×10¹⁸ atoms/cm³.

The above-described example in which the microwave treatment in an oxygen-containing atmosphere is performed on the semiconductor film 21f is a non-limiting example. For example, the microwave treatment in an oxygen-containing atmosphere may be performed on an insulating film, specifically a silicon oxide film, which is positioned in the vicinity of the semiconductor film 21f. In that case, hydrogen contained in the silicon oxide film can be released as H₂O to the outside. Release of hydrogen from the silicon oxide film positioned in the vicinity of the semiconductor film 21f enables the semiconductor device to have high reliability.

In the case where the semiconductor film 21f has a stacked-layer structure, the layers may be deposited by the same method or different methods from each other. For example, in the case where the semiconductor film 21f has a stacked-layer structure of two layers, the lower layer of the semiconductor film 21f may be deposited by a sputtering method and the upper layer of the semiconductor film 21f may be deposited by an ALD method. An oxide semiconductor film deposited by a sputtering method is likely to have crystallinity. Thus, when an oxide semiconductor film having crystallinity is provided as the lower layer of the semiconductor film 21f, the crystallinity of the upper layer of the semiconductor film 21f can be increased. Even when a pin hole, disconnection, or the like is formed in the lower layer of the semiconductor film 21f deposited by a sputtering method, a region overlapping therewith can be filled with the upper layer of the semiconductor film 21f deposited by an ALD method with favorable coverage.

Here, the semiconductor film 21f is preferably formed to include a region in contact with the top surface of the conductive layer 31 in the opening portion 20a, the side surface of the insulating layer 41 in the opening portion 20a, the side surface of the conductive layer 32 in the opening portion 20a, the top surface of the conductive layer 32 in the opening portion 20b, and the side surface of the insulating layer 42 in the opening portion 20b.

Heat treatment is preferably performed after the deposition of the semiconductor film 21f. The heat treatment is performed in a temperature range where the semiconductor film 21f does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent, for example, entry of moisture into the semiconductor film 21f as much as possible.

Here, the above-described heat treatment is preferably performed in the state where the semiconductor film 21f is in contact with the insulating layer 41b containing a large amount of oxygen. In that case, oxygen is supplied from the insulating layer 41b to the region of the semiconductor film 21f that is to be the channel formation region, whereby oxygen vacancies can be reduced.

Although the example in which heat treatment is performed after the deposition of the semiconductor film 21f is described above, heat treatment may be performed in a later step.

Next, an insulating film 22f is formed over the semiconductor film 21f so as to include a region positioned inside the opening portion 20 (FIG. 14B). The insulating film 22f is an insulating film to be the insulating layer 22 later. The insulating film 22f can be formed by a sputtering method, a CVD method, an MBE method, a PLD method, an ALD method, or the like as appropriate.

The insulating film 22f is preferably provided to have a thickness as uniform as possible along the side surface of the semiconductor film 21f in the opening portion 20a. Thus, the insulating film 22f is particularly preferably formed by an ALD method, which is a deposition method with extremely excellent coverage. In the case where the sidewalls of the opening portion 20a and the opening portion 20b have a tapered shape, the insulating layer 22 can be formed by a deposition method that provides lower coverage than an ALD method, such as a sputtering method.

Next, a conductive film 23f is formed over the insulating film 22f so as to include a region positioned inside the opening portion 20 (FIG. 14B). The conductive film 23f is a conductive film to be the conductive layer 23 later. Part of the conductive film 23f is provided to fill the opening portion 20.

The conductive film 23f is preferably deposited by a deposition method with favorable coverage or embeddability, and is further preferably deposited by a CVD method, an ALD method, or the like. In the case where the opening portion 20 has a sidewall with a tapered shape, the conductive film can be deposited by a sputtering method, for example.

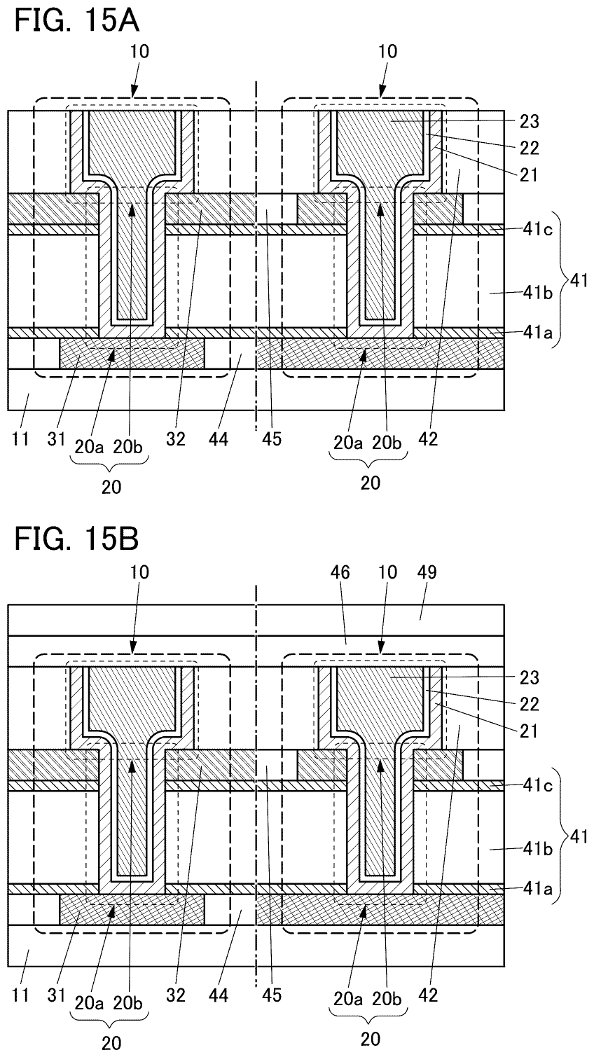

Next, planarization treatment by a CMP method, for example, is performed on the semiconductor film 21f, the insulating film 22f, and the conductive film 23f to expose the top surface of the insulating layer 42. Thus, the semiconductor layer 21 including a region in contact with the conductive layer 31 and a region in contact with the conductive layer 32, the insulating layer 22 over the semiconductor layer 21, and the conductive layer 23 over the insulating layer 22 are formed inside the opening portion 20 (FIG. 15A). Here, the conductive layer 23 can be formed to fill the opening portion 20. Note that the conductive layer 23, the insulating layer 22, and the semiconductor layer 21 may be formed by processing the upper portion of the conductive film 23f, the upper portion of the insulating film 22f, and the upper portion of the semiconductor film 21f by an etching method such as a dry etching method until the top surface of the insulating layer 42 is exposed. As described above, the top surface of the insulating layer 42, the uppermost surface of the semiconductor layer 21, the uppermost surface of the insulating layer 22, and the top surface of the conductive layer 23 can be level or substantially level with each other.

Next, the insulating layer 46 is formed over the insulating layer 42, the semiconductor layer 21, the insulating layer 22, and the conductive layer 23. After that, the insulating layer 49 is formed over the insulating layer 46 (FIG. 15B). The insulating layer 46 and the insulating layer 49 can be formed by a sputtering method, a CVD method, an MBE method, a PLD method, an ALD method, or the like as appropriate.

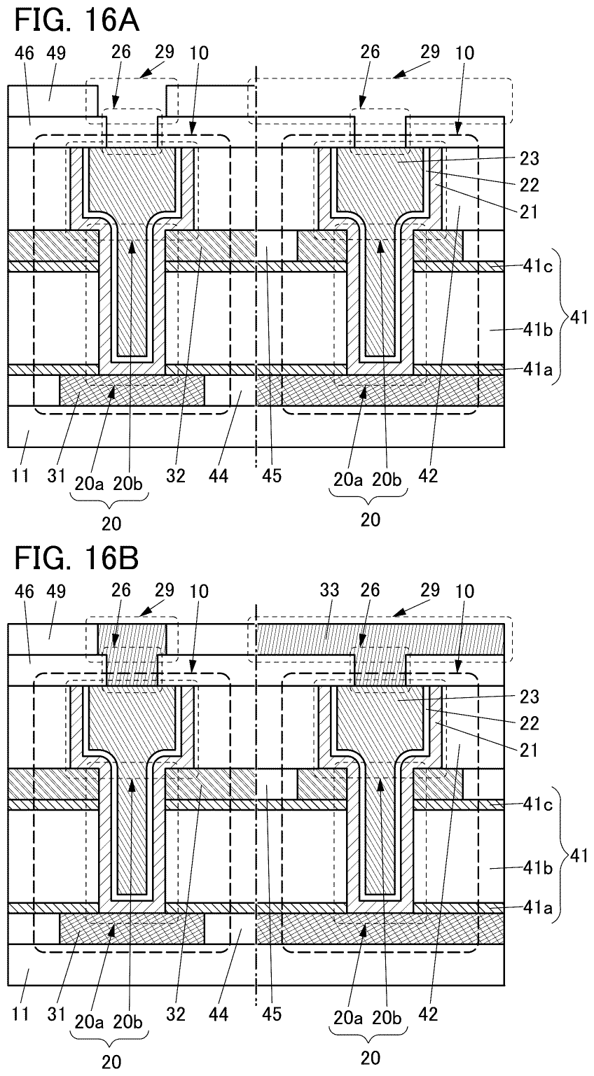

Next, part of the insulating layer 49 is processed to form the opening portion 29 reaching the insulating layer 46. After that, part of the insulating layer 46 is processed to form the opening portion 26 that includes a region overlapping with the opening portion 29 and reaches the conductive layer 23 (FIG. 16A).

For example, a resist mask is formed first over the insulating layer 49 by a photolithography method, a region of the insulating layer 49 that is not covered with the resist mask is removed by etching, and then, the resist mask is removed. Thus, the opening portion 29 is formed in the insulating layer 49. After that, a resist mask is formed over the insulating layer 49 and the insulating layer 46 by a photolithography method, a region of the insulating layer 49 and the insulating layer 46 that is not covered with the resist mask is removed by etching, and then, the resist mask is removed. Thus, the opening portion 26 is formed in the insulating layer 46.

Here, when the insulating layer 49 is etched at the time of forming the opening portion 29 under a condition where the etching rate of the insulating layer 49 is higher than the etching rate of the insulating layer 46, unintentional etching of the insulating layer 46 can be inhibited. This can prevent, for example, exposure of the top surface of the semiconductor layer 21. Note that an insulating layer functioning as an etching stopper at the time of forming the opening portion 29 in the insulating layer 49 may be formed between the insulating layer 46 and the insulating layer 49. In that case, the insulating layer 49 does not need to be etched at the time of forming the opening portion 29 under the condition where the etching rate of the insulating layer 49 is higher than the etching rate of the insulating layer 46; thus, the range of choices of etching conditions can be expanded. Note that, as described above, the insulating layer functioning as an etching stopper may be included in the insulating layer 46, for example. In that case, the uppermost portion of the insulating layer 46 can be the insulating layer functioning as an etching stopper.

Here, when the diameter of the opening portion 20b is larger than the diameter of the opening portion 20a, the area of the top surface of the conductive layer 23 can be increased while the area occupied by the transistor 10 is inhibited from being increased. This can prevent the opening portion 26 from reaching the semiconductor layer 21 and the conductive layer 33 to be formed in a later step from being in contact with the semiconductor layer 21, for example. Accordingly, a method for manufacturing a semiconductor device that includes miniaturized transistors and has a high yield can be obtained.

Next, a conductive film to be the conductive layer 33 is formed to cover the conductive layer 23, the insulating layer 46, and the insulating layer 49 so as to include a region positioned inside the opening portion 26 and a region positioned inside the opening portion 29. The conductive film can be formed to include a region in contact with the top surface of the conductive layer 23 inside the opening portion 26.

Next, planarization treatment by a CMP method, for example, is performed on the conductive film to expose the top surface of the insulating layer 49. Thus, the conductive layer 33 is formed to fill the opening portion 26 and the opening portion 29 (FIG. 16B). The conductive layer 33 is formed to include a region in contact with the conductive layer 23 inside the opening portion 26. The conductive layer 33 is formed to include a region positioned over the insulating layer 46 and include, in the region, a region overlapping with the insulating layer 42 with the insulating layer 46 therebetween, a region overlapping with the semiconductor layer 21 with the insulating layer 46 therebetween, a region overlapping with the insulating layer 22 with the insulating layer 46 therebetween, and a region overlapping with the conductive layer 23 with the insulating layer 46 therebetween. Specifically, the conductive layer 33 is formed to include a region overlapping with the top surface of the insulating layer 42 with the insulating layer 46 therebetween, a region overlapping with the uppermost surface of the semiconductor layer 21 with the insulating layer 46 therebetween, a region overlapping with the uppermost surface of the insulating layer 22 with the insulating layer 46 therebetween, and a region overlapping with the top surface of the conductive layer 23 with the insulating layer 46 therebetween. Note that the conductive layer 33 may be formed by processing the upper portion of the conductive film to be the conductive layer 33 by an etching method such as a dry etching method, for example, until the top surface of the insulating layer 49 is exposed. As described above, the top surface of the conductive layer 33 can be level or substantially level with the top surface of the insulating layer 49.

Through the above-described steps, the transistor 10 illustrated in FIG. 2B and FIG. 2C can be manufactured.

### Manufacturing Method Example 2

Next, an example of a method for manufacturing a semiconductor device that is partly different from the above manufacturing method example 1 will be described below. Specifically, an example of a method for manufacturing the transistor 10 illustrated in FIG. 3A and FIG. 3B is described. Note that the description of portions similar to those described in the above manufacturing method example 1 will be omitted as appropriate.

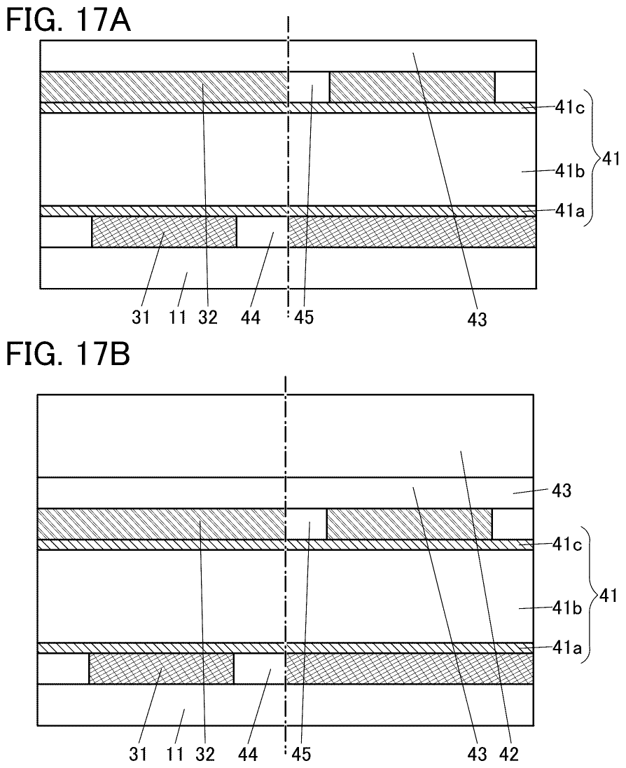

First, as in the above manufacturing method example 1, the steps up to the formation of the conductive layer 32 and the insulating layer 45 are performed. Next, the insulating layer 43 is formed over the conductive layer 32 and the insulating layer 45 (FIG. 17A). The insulating layer 43 can be formed by a method similar to that for the insulating layer 46, for example.

Next, the insulating layer 42 is formed over the insulating layer 43 (FIG. 17B). For the formation of the insulating layer 42, the above manufacturing method example 1 can be referred to.

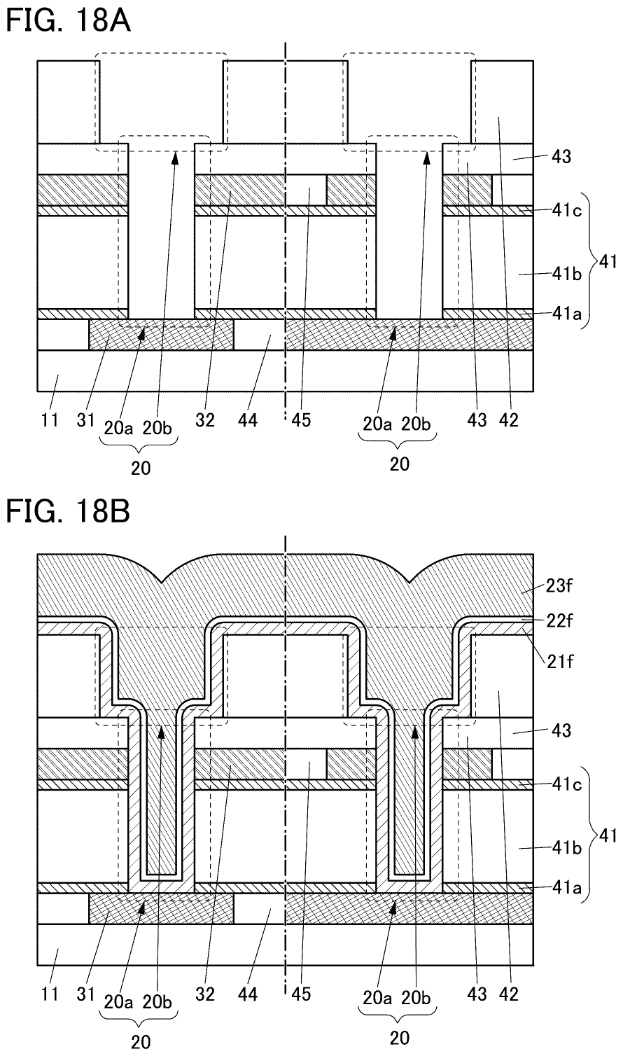

Then, part of the insulating layer 42 is processed to form the opening portion 20b reaching the insulating layer 43. After that, part of the insulating layer 43, part of the conductive layer 32, and part of the insulating layer 41 are processed to form the opening portion 20a that includes a region overlapping with the opening portion 20b and reaches the conductive layer 31 (FIG. 18A). For the formation of the opening portion 20b and the opening portion 20a, the above manufacturing method example 1 can be referred to.

Here, when the insulating layer 42 is etched at the time of forming the opening portion 20b under a condition where the etching rate of the insulating layer 42 is higher than the etching rate of the insulating layer 43, unintentional etching of the insulating layer 43 can be inhibited. This can inhibit a reduction in the thickness of the insulating layer 43 and accordingly a reduction in the distance between the top surface of the conductive layer 32 and the conductive layer 23 to be formed later, for example. Thus, parasitic capacitance in a region where the top surface of the conductive layer 32 and the conductive layer 23 overlap with each other can be inhibited from being increased. Note that an insulating layer functioning as an etching stopper at the time of forming the opening portion 20b in the insulating layer 42 may be formed between the insulating layer 43 and the insulating layer 42. In that case, the insulating layer 42 does not need to be etched at the time of forming the opening portion 20b under the condition where the etching rate of the insulating layer 42 is higher than the etching rate of the insulating layer 43; thus, the range of choices of etching conditions can be expanded. Note that, as described above, the insulating layer functioning as an etching stopper may be included in the insulating layer 43, for example. In that case, the uppermost portion of the insulating layer 43 can be the insulating layer functioning as an etching stopper.

Next, the semiconductor film 21f is formed to cover the conductive layer 31, the insulating layer 41, the conductive layer 32, the insulating layer 43, and the insulating layer 42 so as to include a region positioned inside the opening portion 20 (FIG. 18B). For the formation of the semiconductor film 21f, the above manufacturing method example 1 can be referred to. Here, the semiconductor film 21f is preferably formed to include a region in contact with the top surface of the conductive layer 31 in the opening portion 20a, the side surface of the insulating layer 41 in the opening portion 20a, the side surface of the conductive layer 32 in the opening portion 20a, the side surface of the insulating layer 43 in the opening portion 20a, the top surface of the insulating layer 43 in the opening portion 20b, and the side surface of the insulating layer 42 in the opening portion 20b.

Next, the insulating film 22f is formed over the semiconductor film 21f so as to include a region positioned inside the opening portion 20. After that, the conductive film 23f is formed over the insulating film 22f so as to include a region positioned inside the opening portion 20 (FIG. 18B). For the formation of the insulating film 22f and the conductive film 23f, the above manufacturing method example 1 can be referred to.

For the subsequent steps, the above manufacturing method example 1 can be referred to. Through the above-described steps, the transistor 10 illustrated in FIG. 3A and FIG. 3B can be manufactured.

### Manufacturing Method Example 3

Next, an example of a method for manufacturing a semiconductor device that is partly different from the above manufacturing method example 1 will be described below. Specifically, an example of a method for manufacturing the transistor 10 illustrated in FIG. 6A to FIG. 6C is described. Note that the description of portions similar to those described in the above manufacturing method example 1 will be omitted as appropriate.

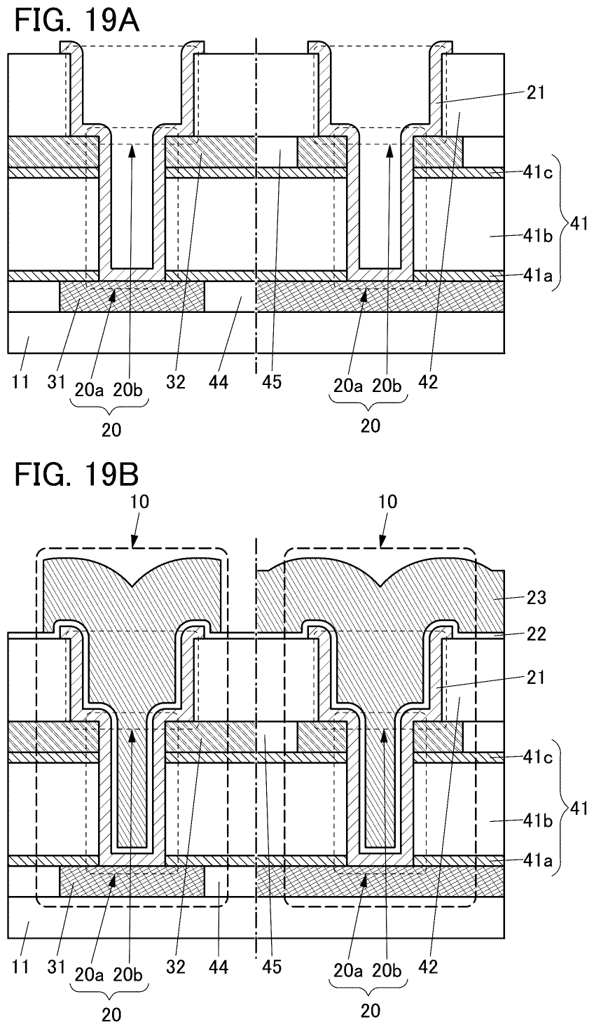

First, as in the above manufacturing method example 1, the steps up to the formation of the semiconductor film 21f are performed. After that, a resist mask is formed over the semiconductor film 21f by, for example, a photolithography method, a part of the semiconductor film 21f that is not covered with the resist mask is removed by etching, and then, the resist mask is removed. Thus, the semiconductor layer 21 can be formed (FIG. 19A).

Next, the insulating layer 22 is formed to cover the semiconductor layer 21 and the insulating layer 42 (FIG. 19B). For the formation of the insulating layer 22, the description of the formation of the insulating film 22f in the above manufacturing method example 1 can be referred to.

Next, a conductive film to be the conductive layer 23 is formed over the insulating layer 22. For the formation of the conductive film to be the conductive layer 23, the description of the formation of the conductive film 23f in the above manufacturing method example 1 can be referred to.

After that, a resist mask is formed over the conductive film to be the conductive layer 23 by, for example, a photolithography method, a part of the conductive film 23f that is not covered with the resist mask is removed by etching, and then, the resist mask is removed. Thus, the conductive layer 23 can be formed (FIG. 19B).

Through the above-described steps, the transistor 10 illustrated in FIG. 6A to FIG. 6C can be manufactured.

The above is the description of the manufacturing method examples.

### Application Example

A structure example of a memory device of one embodiment of the present invention that includes a transistor and a capacitor is described below.

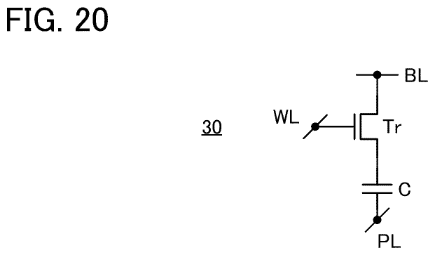

FIG. 20 illustrates a circuit structure example of a memory cell 30 included in the memory device of one embodiment of the present invention. The memory cell 30 includes one transistor Tr and one capacitor C and can also be referred to as 1Tr1C. A gate of the transistor Tr is electrically connected to a wiring WL, one of a source and a drain thereof is electrically connected to a wiring BL, and the other of the source and the drain thereof is electrically connected to one electrode of the capacitor C. The other electrode of the capacitor C is electrically connected to a wiring PL.

The memory cell 30 can store data by retaining in the capacitor C a data potential that is input from the wiring BL through the transistor Tr. The data can be retained when the transistor Tr is brought into a non-conduction state. When the transistor Tr is brought into a conduction state, a potential corresponding to the retained data is output to the wiring BL, so that the data can be read. A signal for controlling the conduction or non-conduction of the transistor Tr is supplied to the wiring WL. A predetermined potential (e.g., a fixed potential) is supplied to the wiring PL.

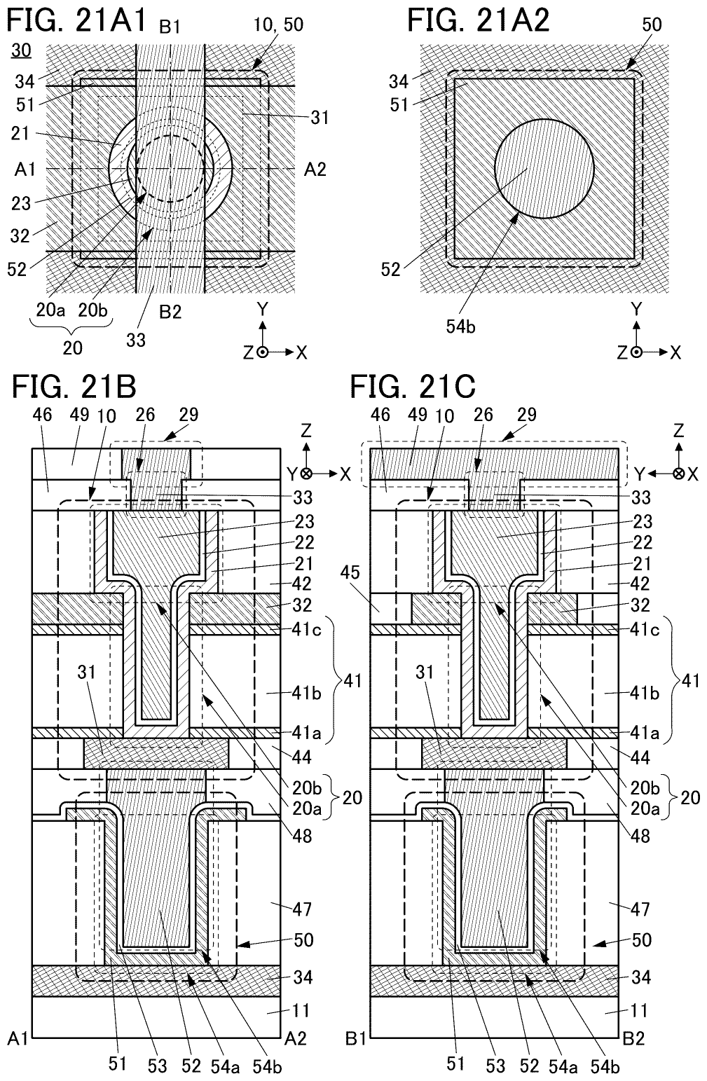

FIG. 21A1 illustrates a planar structure example of the memory device of one embodiment of the present invention, and FIG. 21B and FIG. 21C respectively illustrate cross-sectional structure examples along the cutting line A1-A2 and the cutting line B1-B2 in FIG. 21A1. Specifically, FIG. 21A1, FIG. 21B, and FIG. 21C illustrate a structure example of the memory cell 30 illustrated in FIG. 20.

As illustrated in FIG. 21B and FIG. 21C, the memory cell 30 has a structure in which the transistor 10 is stacked over a capacitor 50. The transistor 10 and the capacitor 50 correspond to the above transistor Tr and the above capacitor C, respectively. Here, FIG. 21A2 is a plan view selectively illustrating the capacitor 50 in FIG. 21A1.

The above description can be referred to for the structure of the transistor 10; thus, the description thereof is omitted. The capacitor 50 includes a conductive layer 51, a conductive layer 52, and an insulating layer 53 sandwiched therebetween. The capacitor 50 forms what is called a MIM (Metal-Insulator-Metal) capacitor.

A conductive layer 34 is provided over the insulating layer 11, and an insulating layer 47 is provided over the conductive layer 34. An opening portion 54a reaching the conductive layer 34 is provided in the insulating layer 47. Inside the opening portion 54a, the conductive layer 51 is provided to include a region in contact with the side surface of the insulating layer 47 and the top surface of the conductive layer 34. The insulating layer 53 is provided to cover the insulating layer 47 and the conductive layer 51. An insulating layer 48 is provided over the insulating layer 53, and an opening portion 54b that includes a region overlapping with the opening portion 54a and reaches the insulating layer 53 is provided in the insulating layer 48. The conductive layer 52 is provided to fill the opening portion 54b.

The top surfaces of the conductive layer 52 and the insulating layer 48 are planarized to be level or substantially level with each other. The insulating layer 44 and the conductive layer 31 are provided over the conductive layer 52 and the insulating layer 48. The conductive layer 31 is provided to include a region in contact with the top surface of the conductive layer 52.

In FIG. 21B and FIG. 21C, the conductive layer 32 corresponds to the wiring BL illustrated in FIG. 20, the conductive layer 33 corresponds to the wiring WL illustrated in FIG. 20, and the conductive layer 34 corresponds to the wiring PL illustrated in FIG. 20.

For the conductive layer 34, the conductive layer 51, and the conductive layer 52, a low-resistance conductive material can be used. For example, any of the materials that can be used for the conductive layer 23 can be used.

Since the insulating layer 53 functions as a dielectric layer of the capacitor 50, the capacitance of the capacitor 50 can be increased as the thickness of the insulating layer 53 decreases and the dielectric constant of the insulating layer 53 increases. The insulating layer 53 is preferably formed using a high-dielectric-constant (high-k) material. The insulating layer 53 is preferably formed using a stacked layer containing a high-k material, for example. The insulating layer 53 preferably has a stacked-layer structure of a high-k material and a material having a higher dielectric strength than the high-k material, for example. For example, as the insulating layer 53, an insulating film in which zirconium oxide, aluminum oxide, and zirconium oxide are stacked in this order (also referred to as ZAZ) can be used. Alternatively, an insulating film in which zirconium oxide, aluminum oxide, zirconium oxide, and aluminum oxide are stacked in this order (also referred to as ZAZA) can be used, for example. Alternatively, an insulating film in which hafnium zirconium oxide, aluminum oxide, hafnium zirconium oxide, and aluminum oxide are stacked in this order can be used, for example. Using such a stacked insulator with relatively high dielectric strength, such as aluminum oxide, can increase the dielectric strength of the insulating layer 53 and inhibit electrostatic breakdown of the capacitor 50.

Alternatively, a material that exhibits ferroelectricity may be used for the insulating layer 53. Examples of the material that exhibits ferroelectricity include metal oxides such as hafnium oxide, zirconium oxide, and HfZrO_{X} (X is a real number greater than 0).

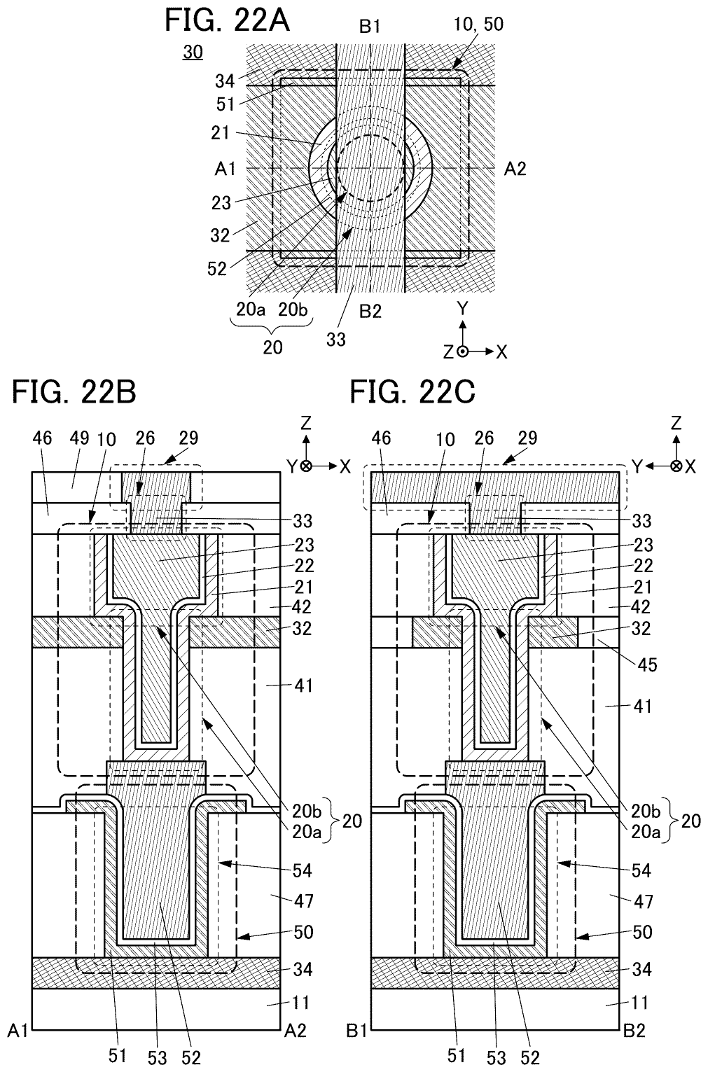

FIG. 22A, FIG. 22B, and FIG. 22C illustrate an example in which the conductive layer 31, the insulating layer 48, and the insulating layer 44 illustrated in FIG. 21A1, FIG. 21B, and FIG. 21C are not provided and the insulating layer 41 is a single layer. FIG. 22B and FIG. 22C illustrate an example in which the opening portion 20a reaches the conductive layer 52 and the bottom surface of the semiconductor layer 21 is in contact with the conductive layer 52. FIG. 22B and FIG. 22C illustrate an example in which the insulating layer 41 covers part of the top surface of the conductive layer 52 and the side surface thereof outside an opening portion 54. For example, in FIG. 22B and FIG. 22C, the insulating layer 41 can include a region in contact with the top surface of the conductive layer 52 and a region in contact with the side surface of the conductive layer 52. Note that an opening portion corresponding to the opening portion 54a in FIG. 21B and FIG. 21C is the opening portion 54 in FIG. 22B and FIG. 22C.

In the example illustrated in FIG. 22A to FIG. 22C, a structure may be employed in which the opening portion 20 reaches the insulating layer 53 and the semiconductor layer 21 covers the top surface of the conductive layer 52 and the side surface thereof outside the opening portion 54. In that case, a structure can be obtained in which the insulating layer 41 is not in contact with the conductive layer 52. Although FIG. 22B and FIG. 22C illustrate an example in which the insulating layer 41 has a single-layer structure, the insulating layer 41 may have a stacked-layer structure of two or more layers. For example, the insulating layer 41 can have a three-layer stacked structure as illustrated in FIG. 21B, FIG. 21C, and the like.

In the example illustrated in FIG. 22A to FIG. 22C, the conductive layer 52 functions as the one of the source electrode and the drain electrode of the transistor 10. In this case, the conductive layer 52 is preferably formed using a material similar to the material that can be used for the conductive layer 31 illustrated in FIG. 21A1, FIG. 21B, FIG. 21C, and the like.

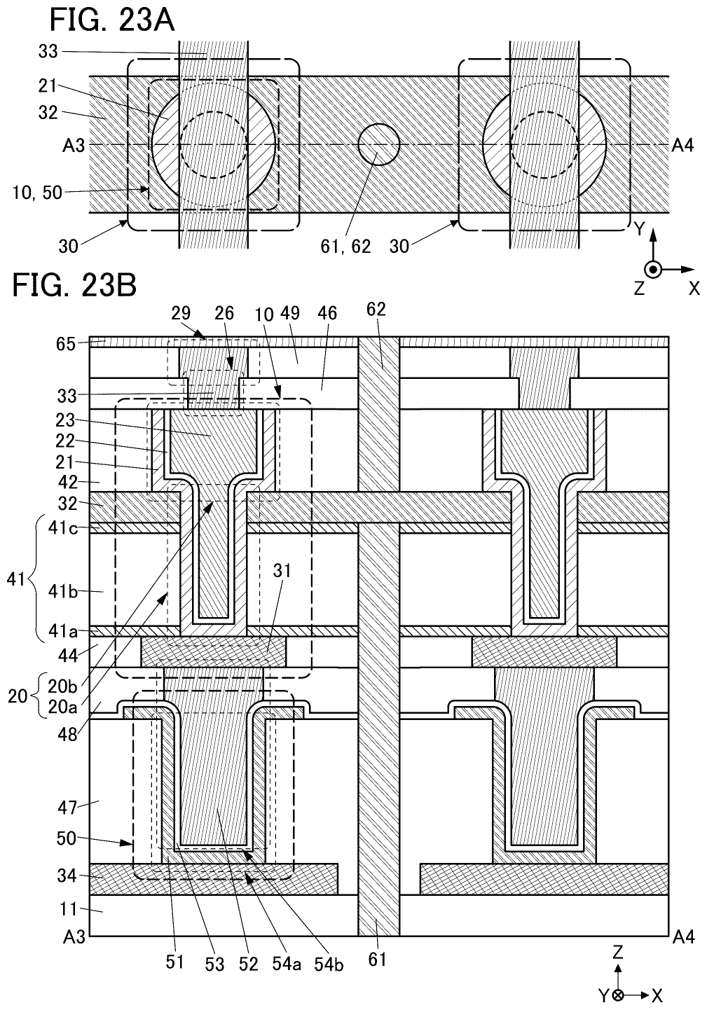

FIG. 23A and FIG. 23B illustrate an example of a memory device in which two memory cells 30 are connected to a common wiring. FIG. 23A is a planar structure example of the memory device, and FIG. 23B is a cross-sectional structure example along the cutting line A3-A4 in FIG. 23A.

The conductive layer 33 functioning as the wiring WL illustrated in FIG. 20 is provided separately in each of the two memory cells 30. The conductive layer 32 functioning as the wiring BL illustrated in FIG. 20 is provided to be shared by the two memory cells 30.

The conductive layer 32 functioning as the wiring BL illustrated in FIG. 20 is electrically connected to a conductive layer 61 and a conductive layer 62 that are embedded in interlayer insulating layers and function as plugs (also referred to as connection electrodes). A structure may be employed in which the conductive layer 61 is electrically connected to a sense amplifier (not illustrated) provided below the insulating layer 11.

An insulating layer 65 functions as a barrier layer and has a function of preventing diffusion of impurities such as water and hydrogen into the memory device from the outside.

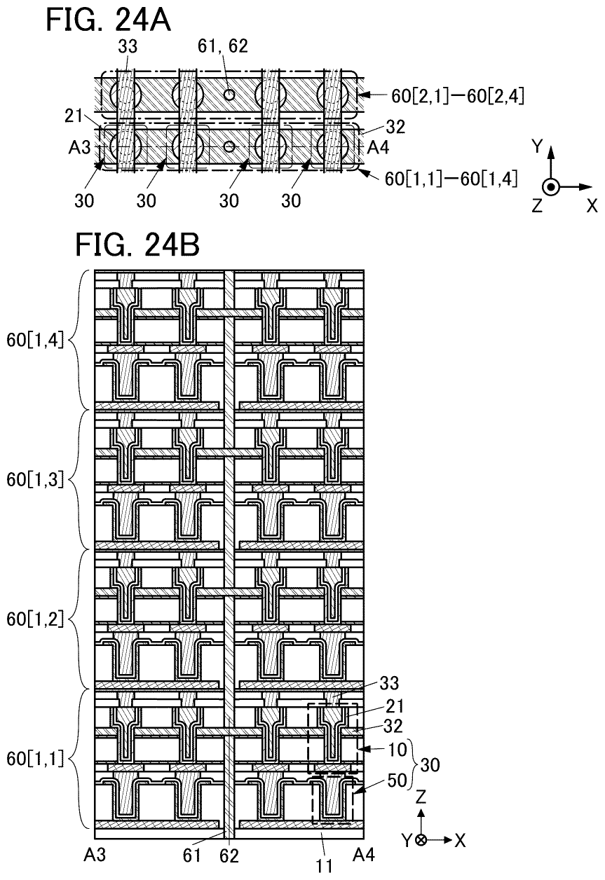

The memory cells 30 can be three-dimensionally arranged in a matrix to form a memory cell array. As an example of the memory cell array, FIG. 24A illustrates a planar structure example of a memory device in which 4×2×4 memory cells 30 are arranged in the X direction, the Y direction, and the Z direction. FIG. 24B illustrates a cross-sectional structure example along the cutting line A3-A4 in FIG. 24A.

In the example illustrated in FIG. 24A and FIG. 24B, a group of four memory cells 30 is referred to as a memory unit 60. FIG. 24A illustrates eight memory units 60 (a memory unit 60[1,1] to a memory unit 60[2,4]). FIG. 24B illustrates four memory units 60 (the memory unit 60[1,1] to a memory unit 60[1,4]). In the memory unit 60[a,b] (a and b are each a positive integer), a represents an address in the Y direction and b represents an address in the Z direction.

In the memory unit 60, pairs of the memory cells 30 are arranged symmetrically with respect to the conductive layer 61 or the conductive layer 62. The conductive layer 62 electrically connects the conductive layers 32 of the memory units 60 stacked in the Z direction. When a plurality of memory units 60 are stacked in this manner, the memory capacity per unit area can be increased. Accordingly, a miniaturized or highly integrated memory device can be obtained.

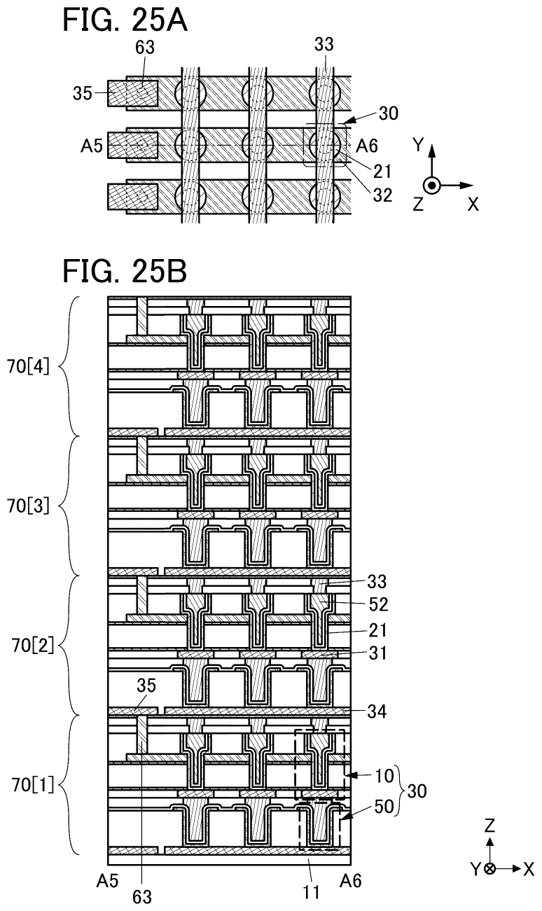

FIG. 25A illustrates a planar structure example of a memory device in which a connection portion is positioned at an end of a memory unit. FIG. 25B illustrates a cross-sectional structure example along the cutting line A5-A6 in FIG. 25A. As an example of the memory cell array, FIG. 25A and FIG. 25B illustrate an example of a memory device in which 3×3×4 memory cells 30 are arranged. The first layer to the fourth layer each including the memory cells 30 are referred to as a layer 70[1] to a layer 70[4], respectively.

A conductive layer 63 is provided outside the memory unit. The conductive layer 63 may be electrically connected to the conductive layer 35 of the layer 70 above the layer 70 that includes the conductive layer 63. For example, the conductive layer 63 provided in the layer 70[1] is electrically connected to the conductive layer 35 provided in the layer 70[2]. Note that the conductive layer 63 may be electrically connected to the conductive layer 35 of the layer 70 that includes the conductive layer 63 or may be electrically connected to the conductive layer 35 of the layer 70 positioned below the layer 70 that includes the conductive layer 63. Although FIG. 25B illustrates an example in which the conductive layer 35 is provided in the same layer as the conductive layer 34, i.e., the conductive layer 35 and the conductive layer 34 are formed in the same step and contain the same material, one embodiment of the present invention is not limited thereto. For example, the conductive layer 35 may be provided in the same layer as the conductive layer 33, may be provided in the same layer as the conductive layer 52, or may be provided in the same layer as the conductive layer 31.

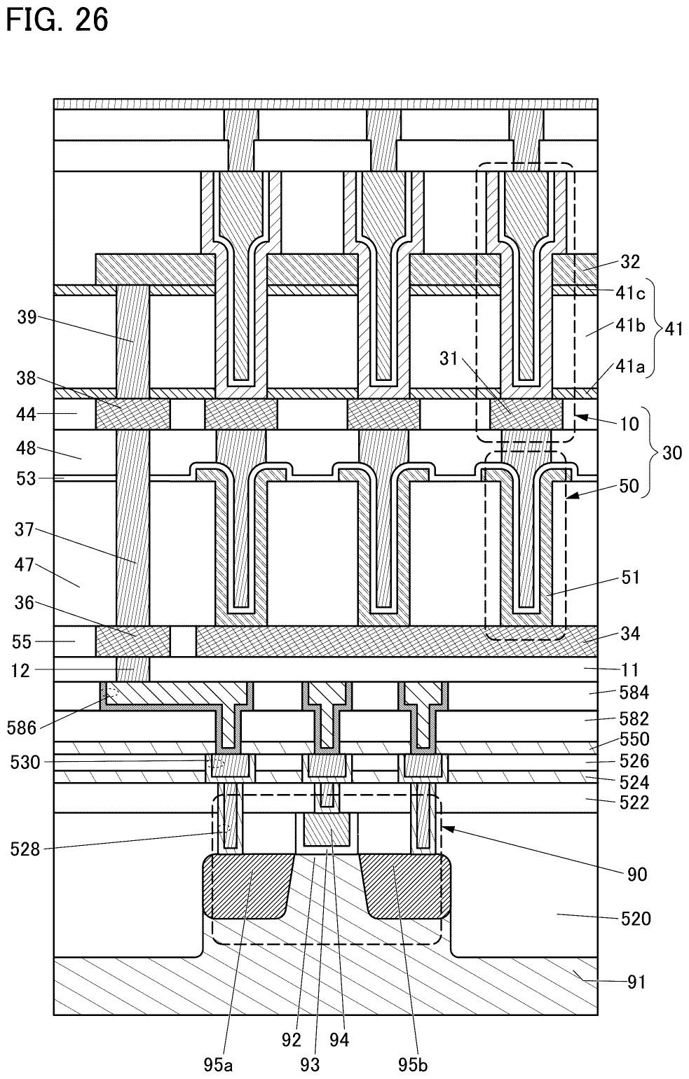

FIG. 26 illustrates a cross-sectional structure example of a memory device in which a layer including the memory cell 30 is stacked over a layer provided with a driver circuit including a sense amplifier.

FIG. 26 illustrates an example in which the capacitor 50 is provided above a transistor 90 and the transistor 10 is provided over the capacitor 50. The transistor 90 can be one of the transistors included in the sense amplifier.

When the sense amplifier is provided to include a region overlapping with the memory cell 30, the bit line can be shortened. This reduces the load on the bit line, so that the read sensitivity of the sense amplifier can be improved. Thus, the storage capacitance of the memory cell 30 can be reduced.

The transistor 90 is provided on a substrate 91 and includes a conductive layer 94 functioning as a gate electrode, an insulating layer 93 functioning as a gate insulating layer, a semiconductor region 92 formed of part of the substrate 91, a low-resistance region 95a functioning as one of a source region and a drain region, and a low-resistance region 95b functioning as the other of the source region and the drain region. The transistor 90 may be a p-channel transistor or an n-channel transistor.

Here, in the transistor 90 illustrated in FIG. 26, the semiconductor region 92 (part of the substrate 91) where a channel is formed has a protruding shape. Such a transistor 90 is also referred to as a FIN-type transistor because it utilizes the protruding portion of the semiconductor substrate.

In the memory device illustrated in FIG. 26, an insulating layer 520 is provided over the substrate 91 to cover the region having the protruding shape described above. An opening portion reaching the semiconductor region 92 is provided in the insulating layer 520, and the insulating layer 93 is provided along the top surface of the semiconductor region 92 and the side surface of the insulating layer 520 in the opening portion. A conductive layer 94 is provided over the insulating layer 93 to fill the opening portion. The top surface of the insulating layer 520, the uppermost surface of the insulating layer 93, and the top surface of the conductive layer 94 can be level or substantially level with each other.

In the example illustrated in FIG. 26, an insulating layer 522, an insulating layer 524, and an insulating layer 526 are stacked in this order over the insulating layer 520. A conductive layer 528 electrically connected to the low-resistance region 95a or the low-resistance region 95b is embedded in the insulating layer 520 and the insulating layer 522. A conductive layer 530 electrically connected to the conductive layer 528 is embedded in the insulating layer 524 and the insulating layer 526.

A wiring layer may be provided over the insulating layer 526 and the conductive layer 530. In the example illustrated in FIG. 26, an insulating layer 550, an insulating layer 582, and an insulating layer 584 are stacked in this order over the insulating layer 526 and the conductive layer 530. A conductive layer 586 electrically connected to the conductive layer 530 is embedded in the insulating layer 550, the insulating layer 582, and the insulating layer 584.

The insulating layer 520, the insulating layer 522, the insulating layer 524, the insulating layer 526, the insulating layer 550, the insulating layer 582, and the insulating layer 584 function as interlayer insulating layers. The conductive layer 528, the conductive layer 530, and the conductive layer 586 function as plugs or wirings.

The insulating layer 11 is provided over the insulating layer 584 and the conductive layer 586. A conductive layer 12 electrically connected to the conductive layer 586 is embedded in the insulating layer 11. An insulating layer 55 is provided over the insulating layer 11. The insulating layer 55 functions as an interlayer insulating layer. The conductive layer 34 electrically connected to the conductive layer 51 included in the capacitor 50 and a conductive layer 36 electrically connected to the conductive layer 12 are embedded in the insulating layer 55.

The insulating layer 47, the insulating layer 53, and the insulating layer 48 are stacked in this order over the insulating layer 55, the conductive layer 34, and the conductive layer 36. A conductive layer 37 electrically connected to the conductive layer 36 is embedded in the insulating layer 47, the insulating layer 53, and the insulating layer 48.

The insulating layer 44 is provided over the insulating layer 48. In addition to the conductive layer 31 included in the transistor 10, a conductive layer 38 electrically connected to the conductive layer 37 is embedded in the insulating layer 44.

The insulating layer 41a, the insulating layer 41b, and the insulating layer 41c are stacked in this order as the insulating layer 41 over the insulating layer 44, the conductive layer 31, and the conductive layer 38. A conductive layer 39 electrically connected to the conductive layer 38 is embedded in the insulating layer 41. The conductive layer 32 is provided over the insulating layer 41 and the conductive layer 39, and the conductive layer 39 and the conductive layer 32 are electrically connected to each other.

Accordingly, the low-resistance region 95a or the low-resistance region 95b and the conductive layer 32 are electrically connected to each other through the conductive layer 528, the conductive layer 530, the conductive layer 586, the conductive layer 12, the conductive layer 36, the conductive layer 37, the conductive layer 38, and the conductive layer 39. FIG. 26 illustrates an example in which the low-resistance region 95a and the conductive layer 32 are electrically connected to each other.

At least part of this embodiment can be implemented in appropriate combination with the other embodiments described in this specification.

### Embodiment 2

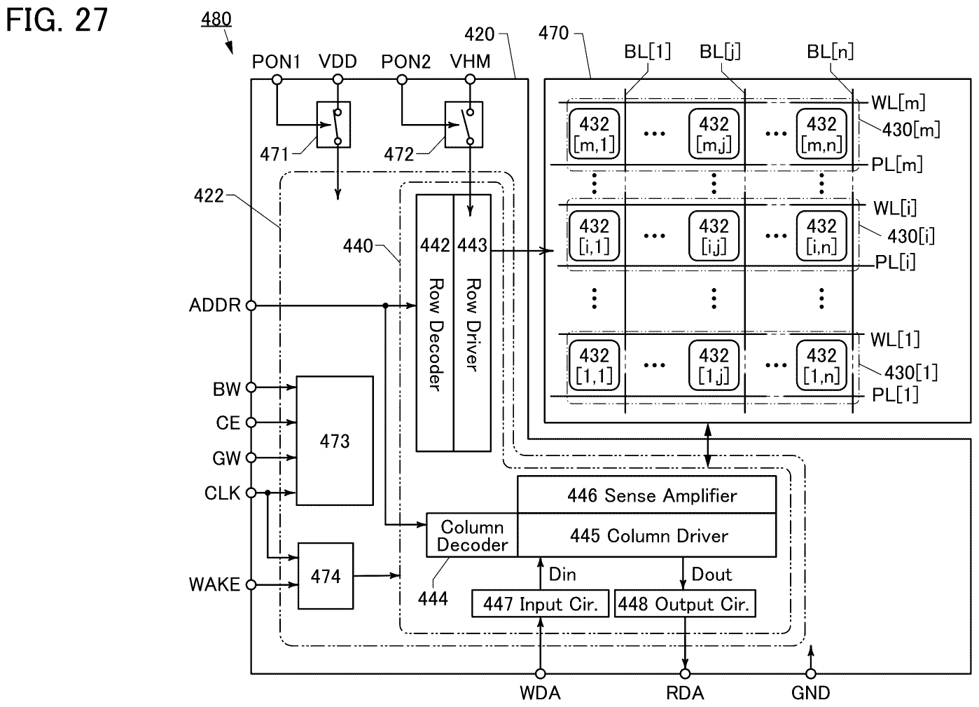

In this embodiment, a memory device of one embodiment of the present invention is described with reference to FIG. 27 to FIG. 30. A structure example of a memory device in which a layer including a memory cell is stacked over a layer provided with a driver circuit including a sense amplifier will be described in this embodiment.

### <Structure Example of Memory Device>

FIG. 27 is a block diagram illustrating a structure example of a memory device 480 of one embodiment of the present invention. The memory device 480 illustrated in FIG. 27 includes a layer 420 and a layer 470 stacked thereover.

The layer 420 is a layer including a Si transistor. The layer 470 is provided with element layers 430[1] to 430[m] (m is an integer greater than or equal to 2) as stacked layers. The element layers 430[1] to 430[m] each include an OS transistor. The layer 470 provided with the stacked layers each including the OS transistor can be stacked over the layer 420.

Elements such as OS transistors and capacitors included in the element layers 430[1] to 430[m] form memory cells. FIG. 27 illustrates an example in which the element layers 430[1] to 430[m] include a plurality of memory cells 432 arranged in a matrix of m rows and n columns (n is an integer greater than or equal to 2).

In FIG. 27, the memory cell 432 in the first row and the first column is denoted as a memory cell 432[1,1], and the memory cell 432 in the m-th row and the n-th column is denoted as a memory cell 432[m,n]. In this embodiment, for example, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment, for example, the memory cell 432 in the i-th row and the j-th column is denoted as a memory cell 432[i,j]. Note that in this embodiment, for example, “i+α” (α is a positive or negative integer) is not below 1 and does not exceed m. Similarly, “j+α” is not below 1 and does not exceed n.

FIG. 27 illustrates, as an example, m wirings WL extending in the row direction, m wirings PL extending in the row direction, and n wirings BL extending in the column direction. In this embodiment, for example, the first (first row) wiring WL is denoted as a wiring WL[1] and the m-th (m-th row) wiring WL is denoted as a wiring WL[m]. Similarly, the first (first row) wiring PL is denoted as a wiring PL[1] and the m-th (m-th row) wiring PL is denoted as a wiring PL[m]. Similarly, the first (first column) wiring BL is denoted as a wiring BL[1] and the n-th (n-th column) wiring BL is denoted as a wiring BL[n]. Note that the number of the element layers 430[1] to 430[m] is not necessarily the same as the number of the wirings WL (and the wirings PL).

The plurality of memory cells 432 provided in the i-th row are electrically connected to the wiring WL in the i-th row (wiring WL[i]) and the wiring PL in the i-th row (wiring PL[i]). The plurality of memory cells 432 provided in the j-th column are electrically connected to the wiring BL in the j-th column (wiring BL[j]).

The wiring BL functions as a bit line for writing and reading data. The wiring WL functions as a word line for controlling on and off states (conduction and non-conduction states) of an access transistor functioning as a switch. The wiring PL has a function of a constant potential line connected to a capacitor. Note that a wiring for transmitting a back gate potential can be additionally provided.

The memory cells 432 included in each of the element layers 430[1] to 430[m] are connected to a sense amplifier 446 through the wiring BL. The wiring BL can be provided horizontally and perpendicularly to the surface of the substrate where the layer 420 is provided. When the wiring BL extending from the memory cells 432 included in the element layers 430[1] to 430[m] is formed using a wiring provided perpendicularly to the substrate surface as well as a wiring provided horizontally to the substrate surface, the length of the wiring between the element layers 430 and the sense amplifier 446 can be shortened. The signal transmission distance between the memory cell and the sense amplifier can be shortened and the resistance and parasitic capacitance of the bit line can be significantly reduced, so that power consumption and signal delay can be reduced. Thus, power consumption and signal delay of the memory device 480 can be reduced. Moreover, operation is possible even when the capacitance of the capacitors included in the memory cells 432 is reduced. Thus, the memory device 480 can be downsized.

The layer 420 includes a PSW 471 (power switch), a PSW 472, and a peripheral circuit 422. The peripheral circuit 422 includes a driver circuit 440, a control circuit 473, and a voltage generation circuit 474. Note that each circuit included in the layer 420 is a circuit including a Si transistor.

In the memory device 480, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 473.

The control circuit 473 is a logic circuit having a function of controlling the entire operation of the memory device 480. For example, the control circuit performs a logical operation on the signal CE, the signal GW, and the signal BW to determine an operation mode (e.g., a writing operation or a reading operation) of the memory device 480. Alternatively, the control circuit 473 generates a control signal for the driver circuit 440 so that the operation mode is executed.

The voltage generation circuit 474 has a function of generating a negative voltage. The signal WAKE has a function of controlling the input of the signal CLK to the voltage generation circuit 474. For example, when an H-level signal is supplied as the signal WAKE, the signal CLK is input to the voltage generation circuit 474, and the voltage generation circuit 474 generates a negative voltage.

The driver circuit 440 is a circuit for writing and reading data to/from the memory cells 432. The driver circuit 440 includes the above-described sense amplifier 446 in addition to a row decoder 442, a column decoder 444, a row driver 443, a column driver 445, an input circuit 447 (Input Cir.), and an output circuit 448 (Output Cir.).

The row decoder 442 and the column decoder 444 have a function of decoding the signal ADDR. The row decoder 442 is a circuit for specifying a row to be accessed, and the column decoder 444 is a circuit for specifying a column to be accessed. The row driver 443 has a function of selecting the wiring WL specified by the row decoder 442. The column driver 445 has a function of writing data to the memory cells 432, a function of reading data from the memory cells 432, a function of retaining the read data, and the like.

The input circuit 447 has a function of retaining the signal WDA. Data retained by the input circuit 447 is output to the column driver 445. Data output from the input circuit 447 is data (Din) to be written to the memory cells 432. Data (Dout) read from the memory cells 432 by the column driver 445 is output to the output circuit 448. The output circuit 448 has a function of retaining Dout. In addition, the output circuit 448 has a function of outputting Dout to the outside of the memory device 480. Data output from the output circuit 448 is the signal RDA.

The PSW 471 has a function of controlling the supply of VDD to the peripheral circuit 422. The PSW 472 has a function of controlling the supply of VHM to the row driver 443. Here, in the memory device 480, a high power supply voltage is VDD and a low power supply voltage is GND (a ground potential). In addition, VHM is a high power supply voltage used to set the word line at high level and is higher than VDD. The on/off state of the PSW 471 is controlled by the signal PON1, and the on/off state of the PSW 472 is controlled by the signal PON2. The number of power domains to which VDD is supplied is one in the peripheral circuit 422 in FIG. 27 but can be more than one. In such a case, a power switch is provided for each power domain.

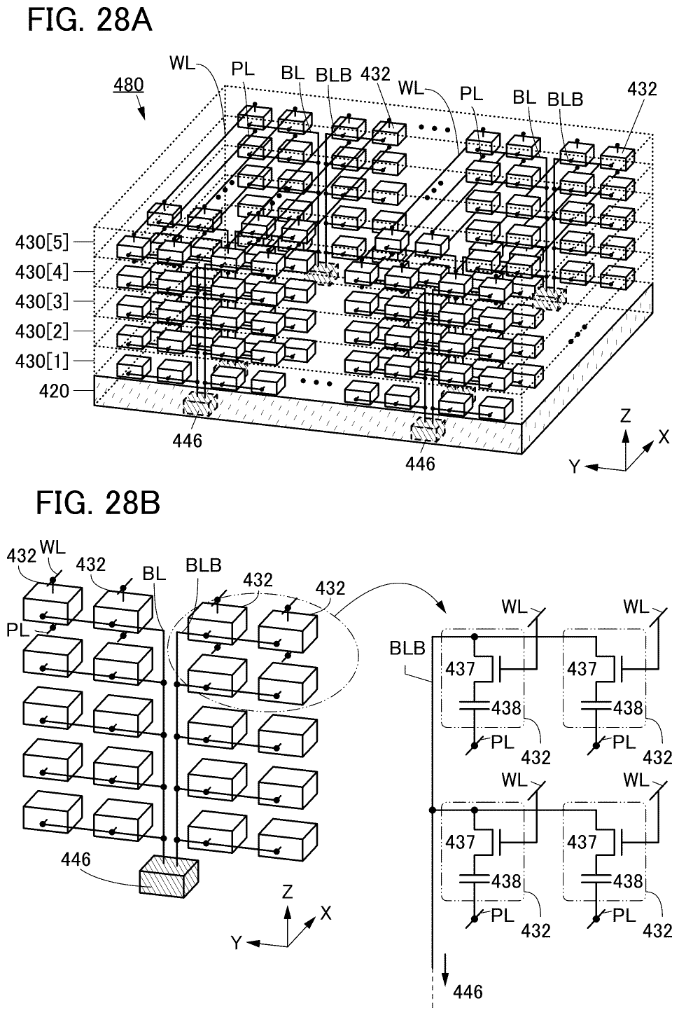

The element layers 430[1] to 430[m] can be provided over the layer 420 to overlap therewith. FIG. 28A illustrates a perspective view of the memory device 480 in which five (m=5) element layers 430[1] to 430[5] are provided over the layer 420 to overlap therewith.

In FIG. 28A, the element layer 430 provided in the first layer is denoted as the element layer 430[1], the element layer 430 provided in the second layer is denoted as the element layer 430[2], and the element layer 430 provided in the fifth layer is denoted as the element layer 430[5]. FIG. 28A also illustrates the wiring WL and the wiring PL extending in the X direction and the wiring BL and a wiring BLB extending in the Y direction and the Z direction (the direction perpendicular to the surface of the substrate where the driver circuit is provided). The wiring BLB is an inverted bit line. For easy viewing of the drawing, some of the wirings WL and the wirings PL included in the element layers 430 are not illustrated.

FIG. 28B illustrates a schematic view illustrating a structure example of the sense amplifier 446, which is connected to the wiring BL and the wiring BLB, and the memory cells 432 included in the element layers 430[1] to 430[5], which are connected to the wiring BL and the wiring BLB, illustrated in FIG. 28A. Note that a structure in which a plurality of memory cells (memory cells 432) are electrically connected to one wiring BL and one wiring BLB is also referred to as “memory string”.

FIG. 28B illustrates an example of a circuit structure of the memory cell 432 connected to the wiring BLB. The memory cell 432 includes a transistor 437 and a capacitor 438. As for the transistor 437, the capacitor 438, and the wirings (e.g., BL and WL), for example, the wiring BL[1] and the wiring WL[1] are referred to as the wiring BL and the wiring WL in some cases. The memory cell 30 described as an example in the above embodiment can be used as the memory cell 432, for example. In other words, the transistor 10 can be used as the transistor 437, and the capacitor 50 can be used as the capacitor 438. As the transistor included in the sense amplifier 446, the transistor 90 (see FIG. 26) can be used.

In the memory cell 432, one of a source and a drain of the transistor 437 is connected to the wiring BL. The other of the source and the drain of the transistor 437 is connected to one electrode of the capacitor 438. The other electrode of the capacitor 438 is connected to the wiring PL. A gate of the transistor 437 is connected to the wiring WL.

The wiring PL is a wiring for supplying a fixed potential for retaining the potential of the capacitor 438. When a plurality of wirings PL are connected to each other and used as one wiring, the number of wirings can be reduced.

In one embodiment of the present invention, OS transistors are provided in stacked layers and a wiring functioning as a bit line is provided in the direction perpendicular to the surface of the substrate where the layer 420 is provided. In addition, the transistors 437 and the capacitors 438 included in the memory cells 432 are arranged in the direction perpendicular to the surface of the substrate where the layer 420 is provided. When the elements and the wirings are provided in the direction perpendicular to the substrate surface, the length of the wiring between the element layers can be shortened and the density of the elements per unit area can be increased. Thus, the memory device can have excellent memory capacity and be excellent in reducing power consumption.

### [Structure Examples of Memory Cell 432 and Sense Amplifier 446]

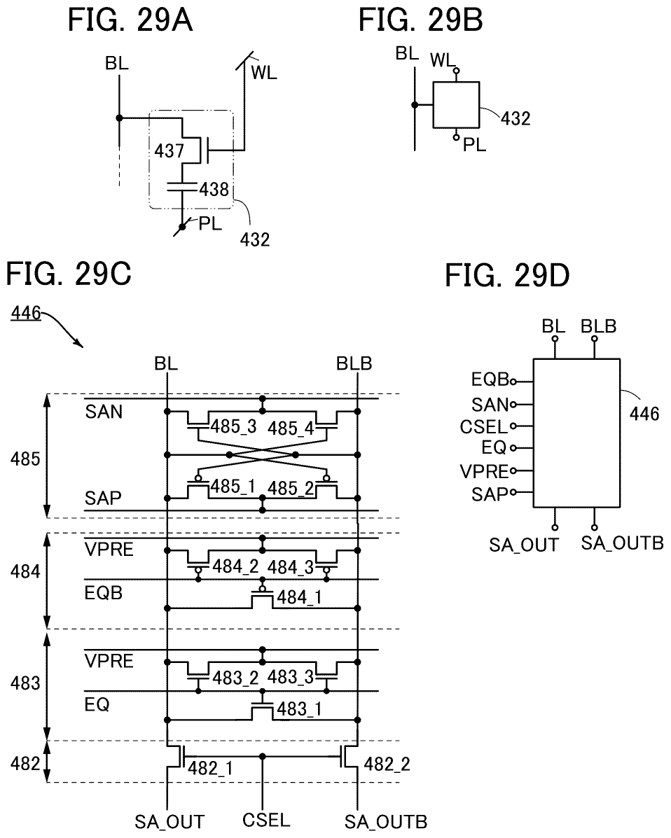

FIG. 29A and FIG. 29B illustrate a circuit diagram corresponding to the above-described memory cell 432 and a circuit block diagram corresponding to the circuit diagram. As illustrated in FIG. 29A and FIG. 29B, the memory cell 432 is illustrated as a block in the drawing and the like in some cases. Note that the same can be applied to the case where the wiring BL illustrated in FIG. 29A and FIG. 29B is replaced with the wiring BLB.

FIG. 29C and FIG. 29D illustrate a circuit diagram corresponding to the above-described sense amplifier 446 and a circuit block diagram corresponding to the circuit diagram. The sense amplifier 446 includes a switch circuit 482, a precharge circuit 483, a precharge circuit 484, and an amplifier circuit 485. In addition to the wiring BL and the wiring BLB, a wiring SA_OUT and a wiring SA_OUTB that output a read signal are illustrated.

The switch circuit 482 includes, for example, n-channel transistors 482_1 and 482_2, as illustrated in FIG. 29C. The transistor 482_1 and the transistor 482_2 switch electrical continuity between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 483 includes n-channel transistors 483_1, 483_2, and 483_3, as illustrated in FIG. 29C. The precharge circuit 483 is a circuit for precharging the wiring BL and the wiring BLB with an intermediate potential VPRE corresponding to a potential VDD/2 in accordance with a signal EQ.

The precharge circuit 484 includes p-channel transistors 484_1, 484_2, and 484_3, as illustrated in FIG. 29C. The precharge circuit 484 is a circuit for precharging the wiring BL and the wiring BLB with the intermediate potential VPRE corresponding to the potential VDD/2 in accordance with a signal EQB.

The amplifier circuit 485 includes p-channel transistors 485_1 and 485_2 and n-channel transistors 485_3 and 485_4 that are connected to a wiring SAP or a wiring SAN, as illustrated in FIG. 29C. The wiring SAP or the wiring SAN is a wiring having a function of supplying VDD or VSS. The transistor 485_1 to the transistor 485_4 are transistors that form an inverter loop.

FIG. 29D illustrates a circuit block diagram corresponding to the sense amplifier 446 described with reference to FIG. 29C, for example. As illustrated in FIG. 29D, the sense amplifier 446 is illustrated as a block in the drawing in some cases.

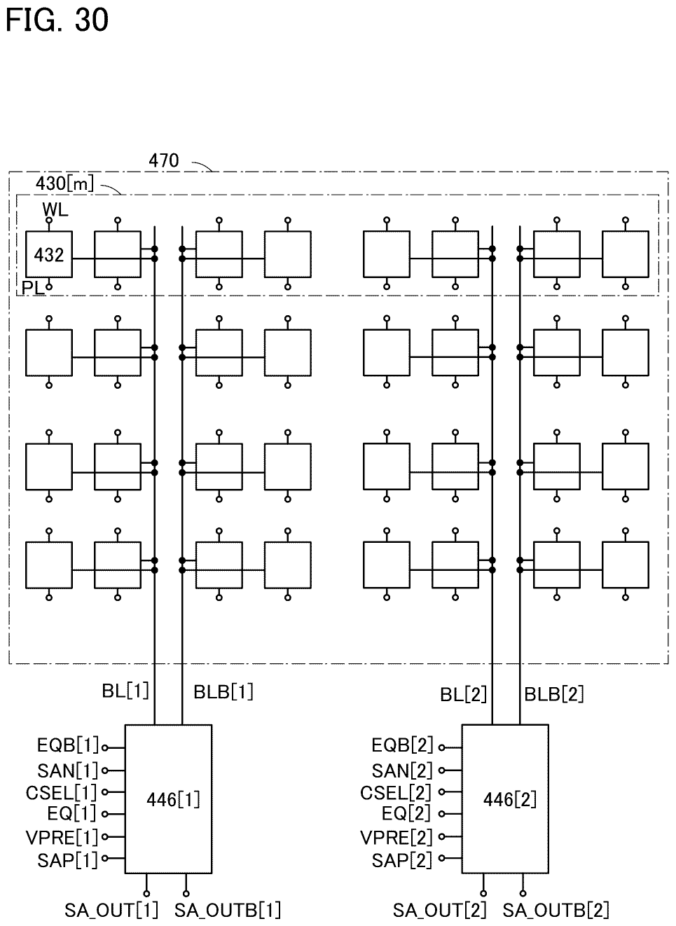

FIG. 30 is a block diagram of the memory device 480 in FIG. 27. In the illustration in FIG. 30, the circuit blocks illustrated in FIG. 29B and FIG. 29D are used.

As illustrated in FIG. 30, the layer 470 including the element layer 430[m] includes the memory cells 432. The memory cells 432 illustrated in FIG. 30 are connected to a pair of wirings BL[1] and BLB[1] or a pair of wirings BL[2] and BLB[2], for example. The memory cells 432 connected to the wiring BL are memory cells to/from which data is written or read.

The wiring BL[1] and the wiring BLB[1] are connected to a sense amplifier 446[1], and the wiring BL[2] and the wiring BLB[2] are connected to a sense amplifier 446[2]. The sense amplifier 446[1] and the sense amplifier 446[2] can perform data reading in accordance with the various signals described with reference to FIG. 29D.

At least part of this embodiment can be implemented in appropriate combination with the other embodiments described in this specification.

### Embodiment 3

In this embodiment, a structure example of a display device that can use the transistor of one embodiment of the present invention will be described.

Since the transistor of one embodiment of the present invention can be extremely minute, a display device using the transistor of one embodiment of the present invention can have an extremely high resolution. For example, the display device of one embodiment of the present invention can be used for display portions of information terminal devices (wearable devices) such as watch-type and bracelet-type information terminal devices and display portions of devices capable of being worn on the head, such as VR devices like head-mounted displays (HMDs) and glasses-type AR devices.

### [Display Module]

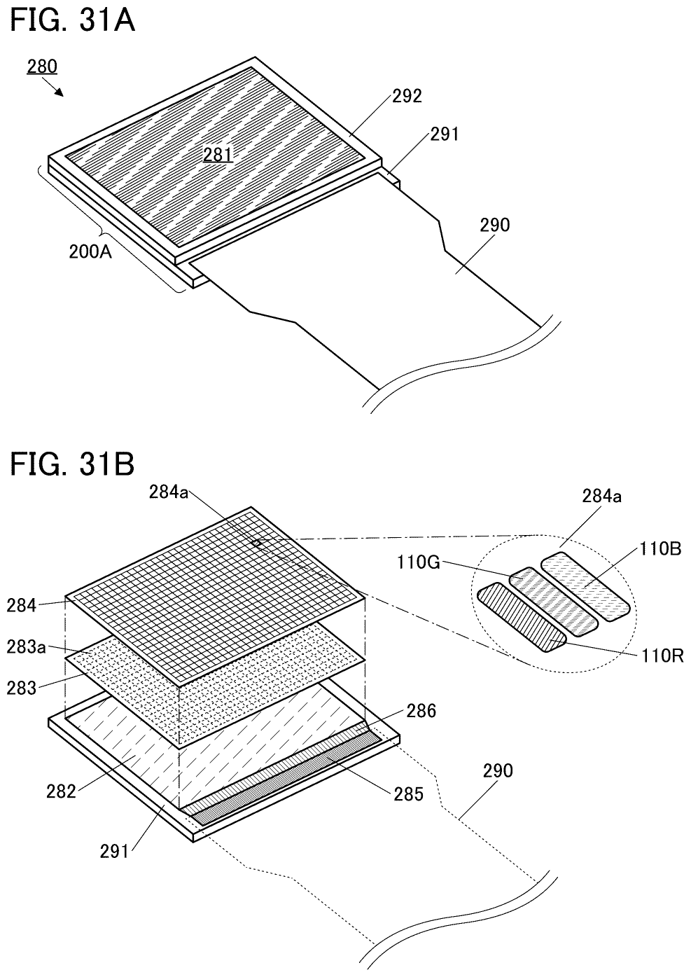

FIG. 31A illustrates a perspective view of a display module 280. The display module 280 includes a display device 200A and an FPC 290. Note that a display panel included in the display module 280 is not limited to the display device 200A and may be a display device 200B or a display device 200C described later.

The display module 280 includes a substrate 291 and a substrate 292. The display module 280 includes a display portion 281. The display portion 281 is a region where an image is displayed.

FIG. 31B illustrates a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a region over the substrate 291 that does not overlap with the pixel portion 284. The terminal portion 285 and the circuit portion 282 are electrically connected to each other with a wiring portion 286 formed of a plurality of wirings.

The pixel portion 284 includes a plurality of pixels 284a arranged periodically. An enlarged view of one pixel 284a is illustrated on the right side of FIG. 31B. The pixel 284a includes a light-emitting element 110R that emits red light, a light-emitting element 110G that emits green light, and a light-emitting element 110B that emits blue light.

The pixel circuit portion 283 includes a plurality of pixel circuits 283a arranged periodically. One pixel circuit 283a is a circuit that controls light emission of three light-emitting devices included in one pixel 284a. A structure may be employed in which one pixel circuit 283a is provided with three circuits each controlling light emission of one light-emitting device. For example, a structure can be employed in which the pixel circuit 283a includes at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is obtained.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even in the case of a structure in which the display portion of the display module 280 is seen through a lens, pixels of the extremely-high-resolution display portion 281 included in the display module 280 are not seen when the display portion is enlarged by the lens, so that display providing a high sense of immersion can be performed. Without being limited thereto, the display module 280 can also be suitably used for an electronic appliance having a relatively small display portion. For example, the display module 280 can be suitably used for a display portion of a wearable electronic appliance, such as a wrist watch.

### [Display Device 200A]

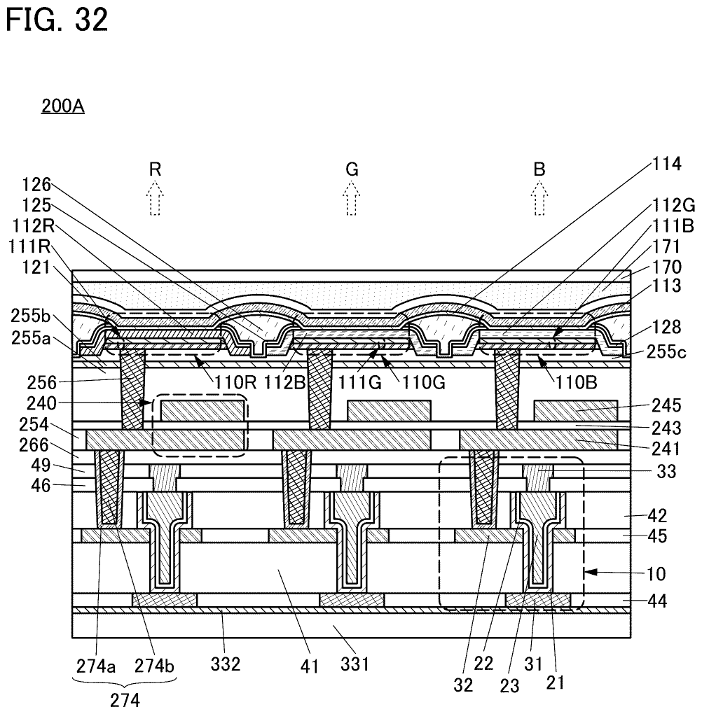

The display device 200A illustrated in FIG. 32 includes a substrate 331, the light-emitting element 110R, the light-emitting element 110G, the light-emitting element 110B, a capacitor 240, and the transistor 10.

The substrate 331 corresponds to the substrate 291 in FIG. 31A. Embodiment 1 can be referred to for the structure of the transistor 10; thus, the description thereof is omitted.

An insulating layer 332 is provided over the substrate 331, and the transistor 10 is provided over the insulating layer 332. The insulating layer 332 functions as a barrier layer that prevents diffusion of an impurity such as water or hydrogen from the substrate 331 into the transistor 10 and release of oxygen from the semiconductor layer 21 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The insulating layer 42, the insulating layer 46, the insulating layer 49, and an insulating layer 266 function as interlayer insulating layers. A barrier layer that prevents diffusion of an impurity such as water or hydrogen from, for example, the insulating layer 266 into the transistor 10 may be provided between the insulating layer 266 and the insulating layer 49. As the barrier layer, an insulating film similar to the insulating layer 332 can be used.

A plug 274 electrically connected to one of the conductive layers 32 is provided to be embedded in the insulating layer 266, the insulating layer 49, the insulating layer 46, and the insulating layer 42. Here, the plug 274 preferably includes a conductive layer 274a covering the side surface of an opening portion formed in the insulating layer 266, the insulating layer 49, the insulating layer 46, and the insulating layer 42 and part of the top surface of the conductive layer 32, and a conductive layer 274b positioned inward from the conductive layer 274a and filling the opening portion. In that case, for the conductive layer 274a, a conductive material in which hydrogen and oxygen are less likely to diffuse is preferably used.

The capacitor 240 is provided over the insulating layer 266. The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the plug 274 and the insulating layer 266 and is embedded in an insulating layer 254. The conductive layer 241 is electrically connected to the conductive layer 32 in the transistor 10 through the plug 274. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layer 255a, the insulating layer 255b, and the insulating layer 255c. For example, it is preferable that a silicon oxide film be used as each of the insulating layer 255a and the insulating layer 255c and that a silicon nitride film be used as the insulating layer 255b. This enables the insulating layer 255b to function as an etching protective film. Although this embodiment shows an example where the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Details of the light-emitting element 110R, the light-emitting element 110G, and the light-emitting element 110B will be described in Embodiment 3.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

In the display device 200A, since the light-emitting devices of different colors are separately formed, a change in chromaticity between light emission at low luminance and light emission at high luminance is small. Furthermore, since the organic layer 112R, the organic layer 112G, and the organic layer 112B are separated from each other, crosstalk generated between adjacent subpixels can be inhibited while the display panel has high resolution. Accordingly, the display panel can have high resolution and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductive layer 32 in the transistor 10 through a plug 256 that is embedded in the insulating layer 255a, the insulating layer 255b, and the insulating layer 255c, the conductive layer 241 that is embedded in the insulating layer 254, and the plug 274. The top surface of the insulating layer 255c and the top surface of the plug 256 are level or substantially level with each other. A variety of conductive materials can be used for the plugs.

A protective layer 121 is provided over the light-emitting element 110R, the light-emitting element 110G, and the light-emitting element 110B. A substrate 170 is attached onto the protective layer 121 with an adhesive layer 171.

An insulating layer covering an end portion of the top surface of the pixel electrode 111 is not provided between two adjacent pixel electrodes 111. Thus, the interval between adjacent light-emitting elements can be extremely shortened. Accordingly, the display device can have a high resolution or a high definition.

### [Display Device 200B]

A display device whose structure is partly different from the above-described structure will be described below. Note that the above description is referred to for portions common to those described above, and the description is omitted in some cases.

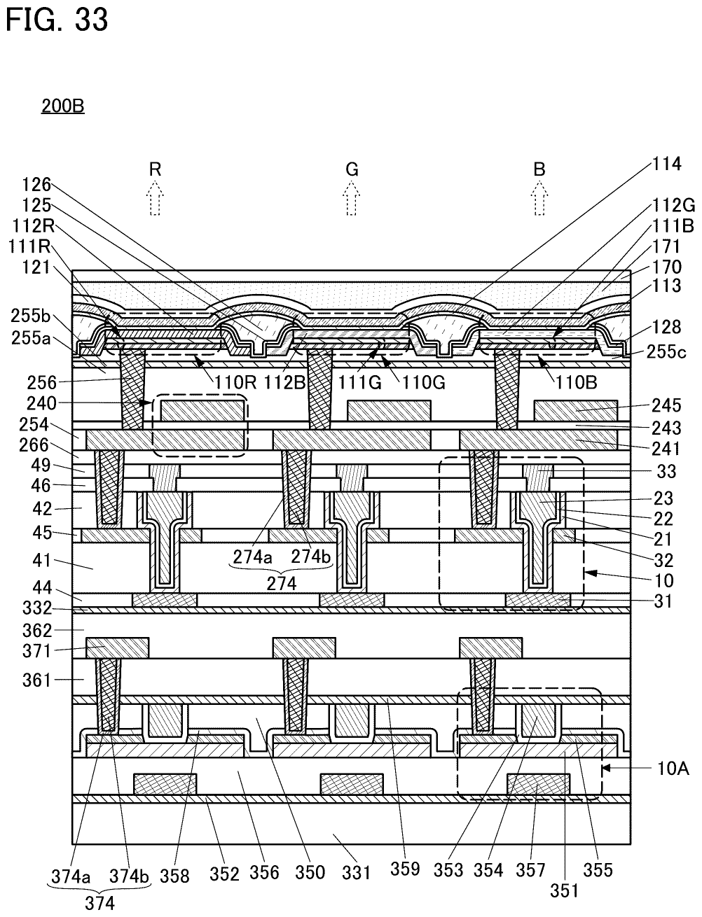

The display device 200B illustrated in FIG. 33 shows an example in which a transistor 10A that is a planar transistor whose semiconductor layer is formed on a plane and the transistor 10 that is a vertical-channel transistor are stacked.

The transistor 10A includes a semiconductor layer 351, an insulating layer 353, a conductive layer 354, a pair of conductive layers 355, an insulating layer 356, and a conductive layer 357.

An insulating layer 352 is provided over a substrate 331. The insulating layer 352 functions as a barrier layer that prevents diffusion of an impurity such as water or hydrogen from the substrate 331 into the transistor 10 and release of oxygen from the semiconductor layer 351 to the insulating layer 352 side. As the insulating layer 352, it is possible to use, for example, a film in which hydrogen or oxygen is less likely to diffuse than in a silicon oxide film, such as an aluminum oxide film, a hafnium oxide film, or a silicon nitride film.

The conductive layer 357 is provided over the insulating layer 352, and the insulating layer 356 is provided over the insulating layer 352 to cover the conductive layer 357. The conductive layer 357 functions as a first gate electrode of the transistor 10A, and part of the insulating layer 356 functions as a first gate insulating layer. An oxide insulating film such as a silicon oxide film is preferably used for at least a region of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as oxide semiconductor) film exhibiting semiconductor characteristics. The pair of conductive layers 355 is provided over and in contact with the semiconductor layer 351, and functions as a source electrode and a drain electrode.

An insulating layer 358 and an insulating layer 350 are provided to cover the top surfaces and the side surfaces of the pair of conductive layers 355, the side surface of the semiconductor layer 351, and the like. The insulating layer 358 functions as a barrier layer that prevents diffusion of an impurity such as water or hydrogen into the semiconductor layer 351 and release of oxygen from the semiconductor layer 351. As the insulating layer 358, an insulating film similar to the insulating layer 352 can be used.

An opening portion reaching the semiconductor layer 351 is provided in the insulating layer 358 and the insulating layer 350. The conductive layer 354 and the insulating layer 353 that is in contact with the top surface of the semiconductor layer 351 fill the inside of the opening portion. The conductive layer 354 functions as a second gate electrode, and the insulating layer 353 functions as a second gate insulating layer.

The top surface of the conductive layer 354, the top surface of the insulating layer 353, and the top surface of the insulating layer 350 are subjected to planarization treatment so as to be level or substantially level with each other, and an insulating layer 359 is provided to cover these layers. The insulating layer 359 functions as a barrier layer that prevents diffusion of an impurity such as water or hydrogen into the transistor 10. As the insulating layer 359, an insulating film similar to the insulating layer 352 can be used.

The structure in which the semiconductor layer where a channel is formed is sandwiched between two gates is used for the transistor 10. The two gates may be connected to each other and supplied with the same signal to drive the transistor. Alternatively, the threshold voltage of the transistor may be controlled by supplying a potential for controlling the threshold voltage to one of the two gates and a potential for driving to the other.

An insulating layer 361 is provided over the insulating layer 359, and a plug 374 is provided to be embedded in the insulating layer 361, the insulating layer 359, the insulating layer 350, and the insulating layer 358. Here, the plug 374 preferably includes a conductive layer 374a covering the side surface of an opening portion formed in the insulating layer 361, the insulating layer 359, the insulating layer 350, and the insulating layer 358 and part of the top surface of the conductive layer 355, and a conductive layer 374b positioned inward from the conductive layer 374a and filling the opening portion. For the conductive layer 374a, a material similar to the material that can be used for the conductive layer 274a can be used, and for the conductive layer 374b, a material similar to the material that can be used for the conductive layer 274b can be used.

A conductive layer 371 is provided over the plug 374 and the insulating layer 361. The conductive layer 371 is electrically connected to the conductive layer 355 in the transistor 10A through the plug 374. An insulating layer 362 is provided over the insulating layer 361 to cover the conductive layer 371. Moreover, the insulating layer 332 is provided over the insulating layer 362.

### [Display Device 200C]

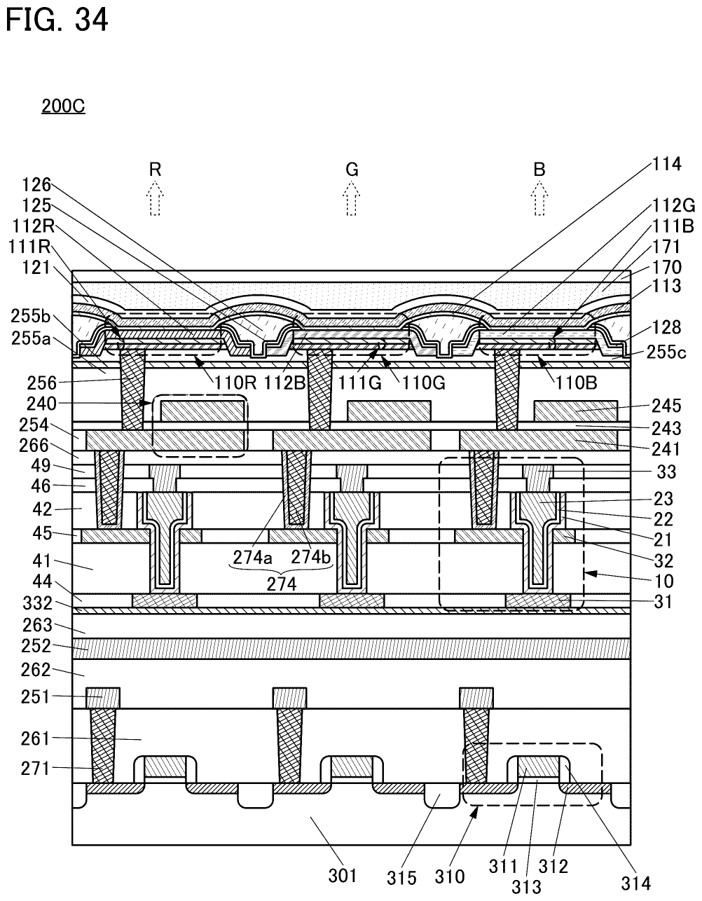

The display device 200C illustrated in FIG. 34 has a structure in which a transistor 310 whose channel is formed in a semiconductor substrate and the transistor 10 that is a vertical-channel transistor are stacked.

The transistor 310 is a transistor including a channel formation region in a substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 so as to be embedded in the substrate 301.

An insulating layer 261 is provided to cover the transistor 310, and a plug 271 is provided to be embedded in the insulating layer 261. A conductive layer 251 is provided over the plug 271 and the insulating layer 261. The conductive layer 251 is electrically connected to the low-resistance region 312 of the transistor 310 through the plug 271. An insulating layer 262 is provided over the insulating layer 261 to cover the conductive layer 251. Moreover, a conductive layer 252 is provided over the insulating layer 262, an insulating layer 263 is provided over the conductive layer 252, and the insulating layer 332 is provided over the insulating layer 263.

At least part of this embodiment can be implemented in appropriate combination with the other embodiments described in this specification.

### Embodiment 4

In this embodiment, structure examples of display devices that can be used as a display device manufactured using the transistor of one embodiment of the present invention will be described. The display devices described below as examples can be used for the pixel portion 284 described above in Embodiment 3, for example.

One embodiment of the present invention is a display device including a light-emitting element. The display device includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers containing different light-emitting materials. For example, three kinds of light-emitting elements emitting red (R), green (G), and blue (B) light are included, whereby a full-color display device can be obtained.

In the case of manufacturing a display device including a plurality of light-emitting elements of different emission colors, at least layers (light-emitting layers) containing light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various effects such as the accuracy of the metal mask, the positional deviation between the metal mask and a substrate, a warp of the metal mask, and expansion of the outline of a deposited film due to vapor scattering, for example; accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement, for example.

Note that in this specification and the like, an island shape refers to a state where two or more layers formed using the same material in the same step are physically separated from each other. For example, an island-shaped light-emitting layer refers to a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to obtain a display device with high resolution and a high aperture ratio, which has been difficult to obtain. Moreover, since the EL layers can be formed separately, it is possible to obtain a display device that performs extremely clear display with high contrast and high display quality. Note that fine patterning of the EL layers may be performed using both a metal mask and photolithography, for example.

In addition, part or the whole of an EL layer can be physically divided. This can inhibit leakage current flowing between adjacent light-emitting elements through a layer (also referred to as a common layer) shared by the light-emitting elements. This can prevent crosstalk due to unintended light emission, so that a display device with extremely high contrast can be obtained. In particular, a display device having high current efficiency at low luminance can be obtained.

In one embodiment of the present invention, the display device can also be obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of each EL layer may be divided by photolithography. Thus, leakage current through the common layer is suppressed; accordingly, a high-contrast display device can be obtained. In particular, when an element has a tandem structure in which a plurality of light-emitting layers are stacked with a highly conductive intermediate layer therebetween, leakage current through the intermediate layer can be effectively prevented, so that a display device with high luminance, high resolution, and high contrast can be obtained.

In the case where the EL layer is processed by a photolithography method, part of the light-emitting layer is sometimes exposed to cause deterioration. Thus, an insulating layer covering at least the side surface of the island-shaped light-emitting layer is preferably provided. The insulating layer may cover part of the top surface of an island-shaped EL layer. For the insulating layer, a material having a barrier property against water and oxygen is preferably used. For example, an inorganic insulating film in which water or oxygen is less likely to diffuse can be used. This can inhibit deterioration of the EL layer, so that a highly reliable display device can be obtained.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a structure is preferably employed in which a local gap positioned between two adjacent light-emitting elements is filled with a resin layer functioning as a planarization film (also referred to as LFP: Local Filling Planarization). The resin layer has a function of the planarization film. This structure can inhibit disconnection of the common layer or the common electrode, so that a highly reliable display device can be obtained.

More specific structure examples of the display device of one embodiment of the present invention will be described below with reference to drawings.

### Structure Example 1

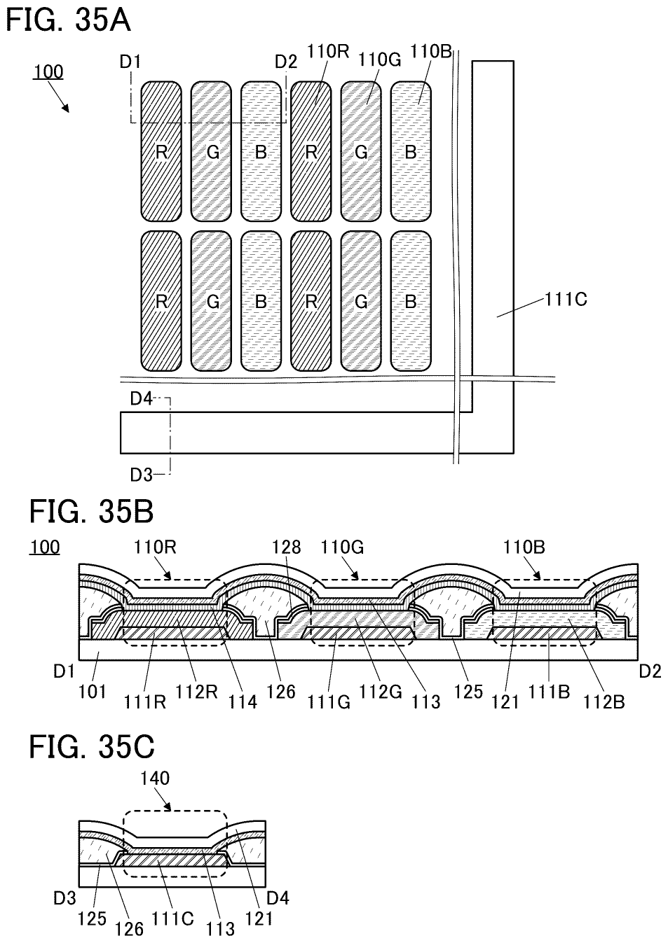

FIG. 35A illustrates a plan view of a display device 100 of one embodiment of the present invention. The display device 100 includes, over a substrate 101, a plurality of light-emitting elements 110R exhibiting red, a plurality of light-emitting elements 110G exhibiting green, and a plurality of light-emitting elements 110B exhibiting blue. In FIG. 35A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 35A illustrates what is called a stripe arrangement, in which light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. Examples of light-emitting substances contained in EL elements include a substance that emits fluorescent light (a fluorescent material), a substance that emits phosphorescent light (a phosphorescent material), and a substance that exhibits thermally activated delayed fluorescence (a thermally activated delayed fluorescence (TADF) material). As the light-emitting substance contained in the EL element, not only an organic compound but also an inorganic compound (e.g., a quantum dot material) can be used.

FIG. 35A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R are arranged, for example.

The connection electrode 111C can be provided along the outer periphery of the display region. For example, the connection electrode 111C may be provided along one side of the outer periphery of the display region or may be provided along two or more sides of the outer periphery of the display region. That is, in the case where the display region has a rectangular top surface shape, a top surface shape of the connection electrode 111C can have a band shape (a rectangle), an L-like shape, a U-like shape (a square bracket shape), a quadrangular shape, or the like.

FIG. 35B and FIG. 35C are cross sections respectively corresponding to the cutting line D1-D2 and the cutting line D3-D4 in FIG. 35A. FIG. 35B illustrates a cross section of the light-emitting element 110R, the light-emitting element 110G, and the light-emitting element 110B, and FIG. 35C illustrates a cross section of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using letters of the alphabet, such as the organic layer 112R, the organic layer 112G, and the organic layer 112B, reference numerals without the letters of the alphabet are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the pixel electrode 111 has an end portion with a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a foreign substance (for example, also referred to as dust or particles) in a manufacturing step is easily removed by processing such as cleaning, which is preferable.

Note that in this specification and the like, the tapered shape refers to a shape such that at least part of a side surface of a component is inclined to a substrate surface. For example, the tapered shape preferably includes a region where the angle formed between the inclined side surface and the substrate surface (the angle is also referred to as a taper angle) is less than 90°.

The organic layer 112 is processed into an island shape by a photolithography method. Thus, an angle formed between a top surface and a side surface of an end portion of the organic layer 112 is approximately 90°. By contrast, an organic film formed using an FMM (Fine Metal Mask), for example, has a thickness that tends to gradually decrease with decreasing distance to the end portion, and the top surface has a slope shape in the range of greater than or equal to 1 μm and less than or equal to 10 μm to the end portion, for example; thus, such an organic film has a shape whose top surface and side surface cannot be easily distinguished from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to bury end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode 113 over the organic layer 112 from being insulated. The resin layer 126 can also be referred to as an LFP (Local Filling Planarization) layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided to include a region in contact with the side surfaces of the organic layers 112. In addition, the insulating layer 125 is provided to cover an upper end portion of the organic layer 112. Furthermore, part of the insulating layer 125 is provided in contact with a top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent used at the time of forming the resin layer 126, for example. Therefore, a structure can be employed in which the insulating layer 125 is provided between the organic layer 112 and the resin layer 126 to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material in which the oxygen content is higher than the nitrogen content in its composition, and nitride oxide refers to a material in which the nitrogen content is higher than the oxygen content in its composition. For example, silicon oxynitride refers to a material in which the oxygen content is higher than the nitrogen content in its composition, and silicon nitride oxide refers to a material in which the nitrogen content is higher than the oxygen content in its composition.

The insulating layer 125 can be formed by a sputtering method, a CVD method, a PLD method, an ALD method, or the like. The insulating layer 125 is preferably formed by an ALD method with excellent coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus for processing, for example, can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked-layer film of an inorganic insulating film and an organic insulating film can also be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat; therefore, when a component (e.g., a color filter, an electrode of a touch sensor, a lens array, or the like) is provided above the protective layer 121, the component can be less affected by an uneven shape caused by a lower structure.

FIG. 35C illustrates the connection portion 140 in which the connection electrode 111C is electrically connected to the common electrode 113. In the connection portion 140, an opening portion portion is provided in the insulating layer 125 and the resin layer 126 over the connection electrode 111C. The connection electrode 111C and the common electrode 113 are electrically connected to each other in the opening portion portion.

Note that although FIG. 35C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display device whose structure is partly different from that in the above-described structure example 1 is described below. Note that the above description is referred to for portions common to those in the above-described structure example 1, and the description is omitted in some cases.

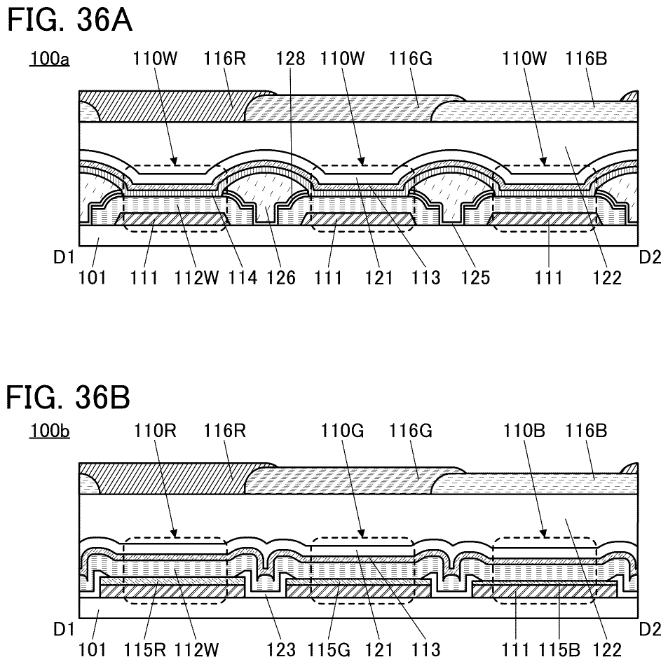

FIG. 36A illustrates a cross section of a display device 100a. The display device 100a is different from the above-described display device 100 mainly in the structure of the light-emitting element and including a coloring layer.

The display device 100a includes a light-emitting element 110W emitting white light. The light-emitting element 110W includes the pixel electrode 111, an organic layer 112W, the common layer 114, and the common electrode 113. The organic layer 112W emits white light. For example, the organic layer 112W can have a structure containing two or more kinds of light-emitting materials whose emission colors have a relationship of complementary colors. For example, the organic layer 112W can have a structure containing a light-emitting organic compound that emits red light, a light-emitting organic compound that emits green light, and a light-emitting organic compound that emits blue light. Alternatively, the organic layer 112W may have a structure containing a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed. Thus, with a flat top surface of the insulating layer 122, the thicknesses of the coloring layer 116R, the coloring layer 116G, the coloring layer 116B, and the like can be uniform and color purity can be increased. Note that when the thicknesses of the coloring layer 116R, the coloring layer 116G, the coloring layer 116B, and the like are non-uniform, the amount of light absorption varies depending on a place in the coloring layer 116R, the coloring layer 116G, and the coloring layer 116B, which might decrease the color purity.

### Structure Example 3

FIG. 36B illustrates a cross section of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having both properties of reflecting and transmitting visible light is used for the common electrode 113, so that a micro resonator (microcavity) structure can be obtained. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used.

Furthermore, the coloring layer 116R, the coloring layer 116G, and the coloring layer 116B are provided on the optical paths of the light-emitting element 110R, the light-emitting element 110G, and the light-emitting element 110B, respectively, whereby light with high color purity can be obtained.

In addition, an insulating layer 123 that covers an end portion of the pixel electrode 111 and an end portion of the conductive layer 115 is provided. An end portion of the insulating layer 123 preferably has a tapered shape. When the insulating layer 123 is provided, coverage with the organic layer 112W, the common electrode 113, the protective layer 121, and the like formed over the insulating layer 123 can be increased.

The organic layer 112W and the common electrode 113 are each provided as one continuous film shared by the light-emitting elements. Such a structure is preferable because the manufacturing process of the display device can be greatly simplified.

Here, the end portion of the pixel electrode 111 preferably has a substantially vertical shape. Accordingly, a steep region can be formed on the surface of the insulating layer 123, and thus a thin region can be formed in part of the organic layer 112W that covers the steep region or part of the organic layer 112W can be divided. Accordingly, a leakage current generated between adjacent light-emitting elements through the organic layer 112W can be inhibited without processing the organic layer 112W by a photolithography method, for example.

The above is the description of the structure examples of the display devices.

At least part of this embodiment can be implemented in appropriate combination with the other embodiments described in this specification.

### Embodiment 5

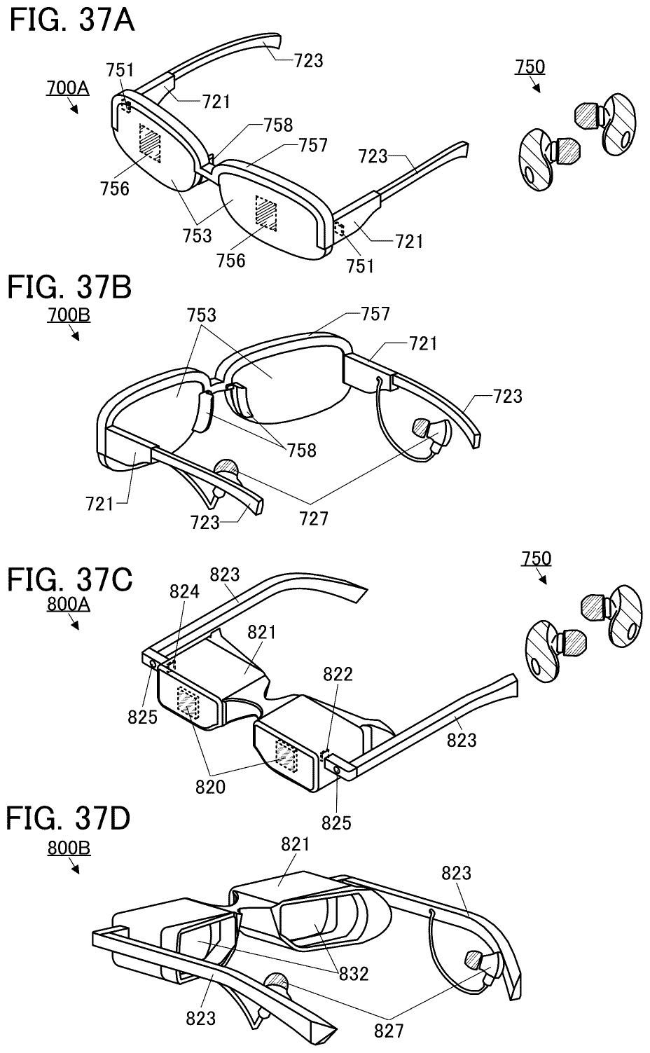

In this embodiment, electronic appliances of embodiments of the present invention will be described with reference to FIG. 37 to FIG. 39.

Electronic appliances in this embodiment each include a display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic appliances.

Examples of electronic appliances include a digital camera, a digital video camera, a digital photo frame, a mobile phone, a portable game console, a portable information terminal, and an audio reproducing device, in addition to electronic appliances with a relatively large screen, such as a television device, desktop and laptop personal computers, a monitor of a computer and the like, digital signage, and a large game machine such as a pachinko machine.

In particular, the display panel of one embodiment of the present invention can have a high resolution, and thus can be suitably used for an electronic appliance having a relatively small display portion. Examples of such an electronic appliance include watch-type and bracelet-type information terminal devices (wearable devices) and wearable devices worn on the head, such as a VR device like a head-mounted display, a glasses-type AR device, and an MR device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display panel having one or both of high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (square), 4:3, 16:9, and 16:10.

The electronic appliance of this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, a gradient, oscillation, odor, or infrared rays).

The electronic appliance in this embodiment can have a variety of functions. For example, the electronic appliance can have a function of displaying a variety of information (e.g., a still image, a moving image, and a text image) on the display portion, a touch panel function, a function of displaying a calendar, date, time, or the like, a function of executing a variety of software (programs), a wireless communication function, or a function of reading out a program or data stored in a recording medium.

Examples of a wearable device that can be worn on the head are described with reference to FIG. 37A to FIG. 37D. These wearable devices have one or both of a function of displaying AR content and a function of displaying VR content. Note that these wearable devices may have a function of displaying SR or MR content, in addition to AR and VR content. The electronic appliance having a function of displaying content of at least one of AR, VR, SR, MR, and the like enables the user to feel a higher sense of immersion.

An electronic appliance 700A illustrated in FIG. 37A and an electronic appliance 700B illustrated in FIG. 37B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic appliances are capable of performing ultrahigh-resolution display.

The electronic appliance 700A and the electronic appliance 700B can each project an image displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic appliance 700A and the electronic appliance 700B are electronic appliances capable of AR display.

In the electronic appliance 700A and the electronic appliance 700B, a camera capable of capturing images of the front side may be provided as the image capturing portion. Furthermore, when the electronic appliance 700A and the electronic appliance 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of or in addition to the wireless communication device, a connector to which a cable for supplying a video signal and a power supply potential can be connected may be provided.

The electronic appliance 700A and the electronic appliance 700B are provided with a battery so that they can be charged wirelessly and/or by wire.

A touch sensor module may be provided in the housing 721. The touch sensor module has a function of detecting a touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

Any of various touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic appliance 800A illustrated in FIG. 37C and an electronic appliance 800B illustrated in FIG. 37D each include a pair of display portions 820, a housing 821, a communication portion 822, a pair of wearing portions 823, a control portion 824, a pair of image capturing portions 825, and a pair of lenses 832.

The display panel of one embodiment of the present invention can be used for the display portions 820. Thus, the electronic appliance is capable of performing ultrahigh-resolution display. This enables a user to feel a high sense of immersion.

The display portions 820 are positioned inside the housing 821 so as to be seen through the lenses 832. When the pair of display portions 820 display different images, three-dimensional display using parallax can be performed.

The electronic appliance 800A and the electronic appliance 800B can be regarded as electronic appliances for VR. The user who wears the electronic appliance 800A or the electronic appliance 800B can see images displayed on the display portions 820 through the lenses 832.

The electronic appliance 800A and the electronic appliance 800B each preferably include a mechanism for adjusting the lateral positions of the lenses 832 and the display portions 820 so that the lenses 832 and the display portions 820 are positioned optimally in accordance with the positions of the user's eyes. Moreover, the electronic appliance 800A and the electronic appliance 800B each preferably include a mechanism for adjusting focus by changing the distance between the lenses 832 and the display portions 820.

The electronic appliance 800A or the electronic appliance 800B can be worn on the user's head with the wearing portions 823. Note that FIG. 37C illustrates an example in which the wearing portion 823 has a shape like a temple (also referred to as a joint, for example) of glasses, for example; however, one embodiment of the present invention is not limited thereto. The wearing portion 823 can have any shape with which the user can wear the electronic appliance, for example, a shape of a helmet or a band.

The image capturing portions 825 has a function of obtaining information on the external environment. Data obtained by the image capturing portions 825 can be output to the display portions 820. An image sensor can be used for the image capturing portions 825. Moreover, a plurality of cameras may be provided so as to support a plurality of fields of view, such as a telescope field of view and a wide field of view.

Although an example where the image capturing portions 825 are provided is described here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic appliance 800A.

The electronic appliance 800A and the electronic appliance 800B may each include an input terminal. To the input terminal, a cable for supplying, for example, a video signal from a video output device, electric power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A illustrated in FIG. 37A has a function of transmitting information to the earphones 750 with the wireless communication function. As another example, the electronic appliance 800A illustrated in FIG. 37C has a function of transmitting information to the earphones 750 with the wireless communication function.

The electronic appliance may include an earphone portion. The electronic appliance 700B illustrated in FIG. 37B includes earphone portions 727. For example, the earphone portions 727 and the control portion can be connected to each other by wire. Part of a wiring that connects the earphone portions 727 and the control portion may be positioned inside the housing 721 or the wearing portion 723.

Similarly, the electronic appliance 800B illustrated in FIG. 37D includes earphone portions 827. For example, a structure can be employed in which the earphone portions 827 and the control portion 824 are connected to each other by wire. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

As described above, both the glasses-type device (e.g., the electronic appliance 700A and the electronic appliance 700B) and the goggles-type device (e.g., the electronic appliance 800A and the electronic appliance 800B) are suitable for the electronic appliance of one embodiment of the present invention.

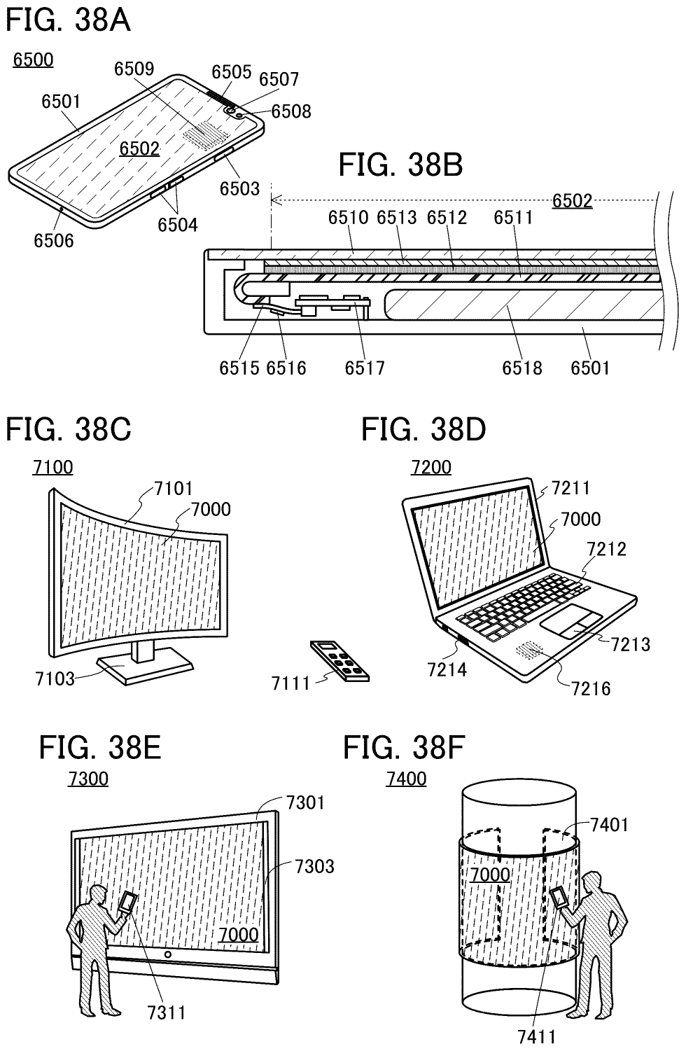

An electronic appliance 6500 illustrated in FIG. 38A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like. The display portion 6502 has a touch panel function. Note that as the control device 6509, for example, one or more selected from a CPU, a GPU, and a memory device are included. The semiconductor device of one embodiment of the present invention can be used for the display portion 6502, the control device 6509, and the like. The semiconductor device of one embodiment of the present invention is preferably used for the control device 6509, in which case power consumption can be reduced.

The display panel of one embodiment of the present invention can be used in the display portion 6502.

FIG. 38B is a cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back such that a connection portion with the FPC 6515 is provided on the back side of a pixel portion, whereby an electronic appliance with a narrow bezel can be obtained.

FIG. 38C illustrates an example of a television device. In a television device 7100, a display portion 7000 is incorporated in a housing 7101. Here, a structure in which the housing 7101 is supported by a stand 7103 is illustrated.

Operation of the television device 7100 illustrated in FIG. 38C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 38D illustrates an example of a laptop personal computer. A laptop personal computer 7200 includes a housing 7211, a keyboard 7212, a pointing device 7213, an external connection port 7214, a control device 7216, and the like. In the housing 7211, the display portion 7000 is incorporated. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the control device 7216, in which case power consumption can be reduced.

FIG. 38E and FIG. 38F illustrate examples of digital signage.

Digital signage 7300 illustrated in FIG. 38E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 38F is digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 38E and FIG. 38F, it is preferable that the digital signage 7300 or the digital signage 7400 be capable of working with an information terminal device 7311 or an information terminal device 7411, such as a smartphone a user has, through wireless communication. For example, information of an advertisement displayed on the display portion 7000 can be displayed on a screen of the information terminal device 7311 or the information terminal device 7411. By operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

In FIG. 38C to FIG. 38F, the display panel of one embodiment of the present invention can be used in the display portion 7000.

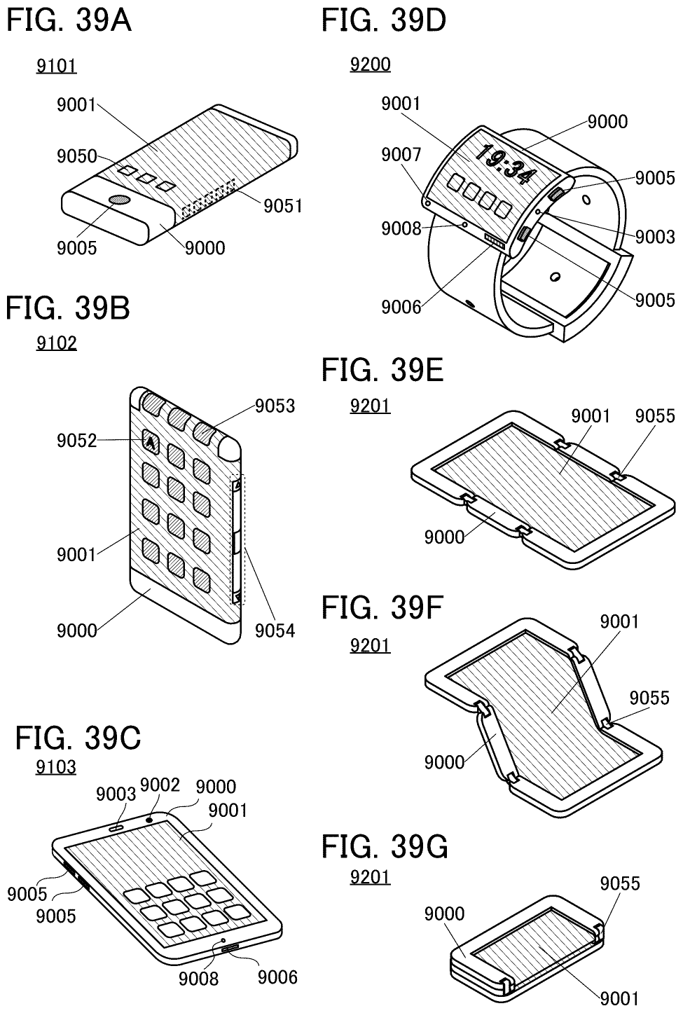

Electronic appliances illustrated in FIG. 39A to FIG. 39G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic appliances illustrated in FIG. 39A to FIG. 39G have a variety of functions. For example, the electronic appliances can have a function of displaying a variety of information (e.g., a still image, a moving image, and a text image) on the display portion, a touch panel function, a function of displaying a calendar, date, time, or the like, a function of controlling processing with the use of a variety of software (programs), a wireless communication function, or a function of reading out and processing a program or data stored in a recording medium. Note that the functions of the electronic appliances are not limited thereto, and the electronic appliances can have a variety of functions. The electronic appliances may include a plurality of display portions. The electronic appliances may each include, for example, a camera and have a function of taking a still image or a moving image and storing the taken image in a recording medium (an external recording medium or a recording medium incorporated in the camera), a function of displaying the taken image on the display portion, and the like.

The electronic appliances illustrated in FIG. 39A to FIG. 39G are described in detail below.

FIG. 39A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display text and image information on its plurality of surfaces. FIG. 39A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 39B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 39C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 39D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 39E to FIG. 39G are perspective views illustrating a foldable portable information terminal 9201. FIG. 39E is a perspective view of an opened state of the portable information terminal 9201, FIG. 39G is a perspective view of a folded state thereof, and FIG. 39F is a perspective view of a state in the middle of change from one of FIG. 39E and FIG. 39G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in appropriate combination with the other embodiments described in this specification.

### Embodiment 6

In this embodiment, application examples of the semiconductor device of one embodiment of the present invention are described. The semiconductor device of one embodiment of the present invention can be used for an electronic component, an electronic appliance, a large computer, a device for space, and a data center (DC), for example. An electronic component, an electronic appliance, a large computer, a device for space, and a data center each employing the semiconductor device of one embodiment of the present invention are effective in improving performance, for example, reducing power consumption.

For example, the electronic component using the semiconductor device of one embodiment of the present invention can be used for the electronic appliances described in Embodiment 5.

### [Electronic Component]

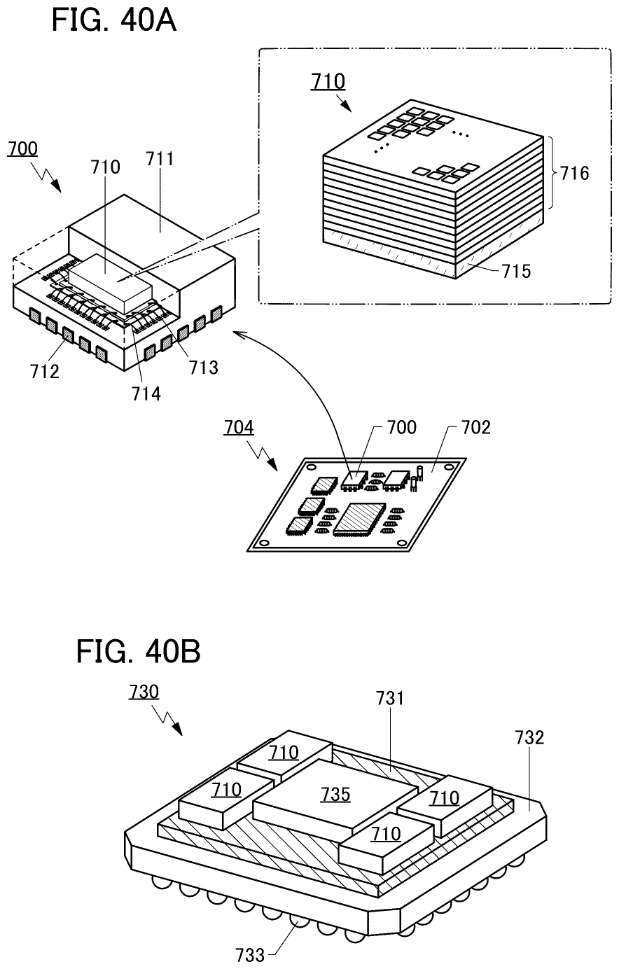

FIG. 40A illustrates a perspective view of a substrate (a mounting board 704) on which an electronic component 700 is mounted. The electronic component 700 illustrated in FIG. 40A includes a semiconductor device 710 in a mold 711. FIG. 40A omits illustrations of some parts to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected to each other on the printed circuit board 702, whereby the mounting board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the size of, for example, a connection wiring can be smaller than that in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer volume per unit time, and the access latency refers to a period of time from data access to the start of data transmission. Note that in the case where the memory layer 716 is formed using Si transistors, the monolithic stacked-layer structure is difficult to form compared with the case where the memory layer 716 is formed using OS transistors. Thus, the OS transistor is superior to the Si transistor in the monolithic stacked-layer structure.

The semiconductor device 710 may be referred to as a die. In this specification and the like, a die refers to each of chip pieces obtained by dividing a circuit pattern formed on, for example, a circular substrate (also referred to as a wafer) into dice in the manufacturing process of a semiconductor chip. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 40B illustrates a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the semiconductor device 710 and the semiconductor device 735 are preferably equal to each other, for example.

An electrode 733 may be provided on the bottom portion of the package substrate 732 to mount the electronic component 730 on another substrate. FIG. 40B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

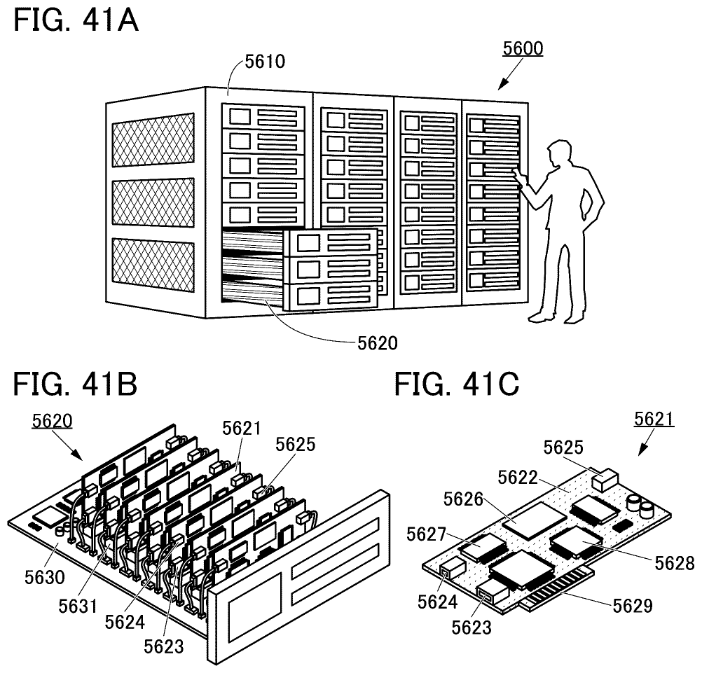

FIG. 41A illustrates a perspective view of a large computer 5600. In the large computer 5600, a plurality of rack mount computers 5620 are stored in a rack 5610. Note that the large computer 5600 may be referred to as a supercomputer.

FIG. 41B illustrates a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 41C illustrates an example of the PC card 5621. The PC card 5621 is, for example, a processing board provided with a CPU, a GPU, a memory device, and the like. The PC card 5621 includes a board 5622 and the connection terminal 5623, the connection terminal 5624, the connection terminal 5625, an electronic component 5626, an electronic component 5627, an electronic component 5628, a connection terminal 5629, and the like which are mounted on the board 5622. Note that FIG. 41C illustrates components other than the electronic component 5626, the electronic component 5627, and the electronic component 5628.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The electronic component 5626 includes a terminal (not illustrated) for inputting and outputting signals, and when the terminal is inserted in a socket (not illustrated) of the board 5622, the electronic component 5626 and the board 5622 can be electrically connected to each other.

The electronic component 5627 and the electronic component 5628 include a plurality of terminals, and can be mounted when the terminals are reflow-soldered, for example, to wirings of the board 5622. Examples of the electronic component 5627 include an FPGA, a GPU, and a CPU. As the electronic component 5627, the electronic component 730 can be used, for example. An example of the electronic component 5628 is a memory device. As the electronic component 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used for a device for space.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of thermosphere, mesosphere, and stratosphere.

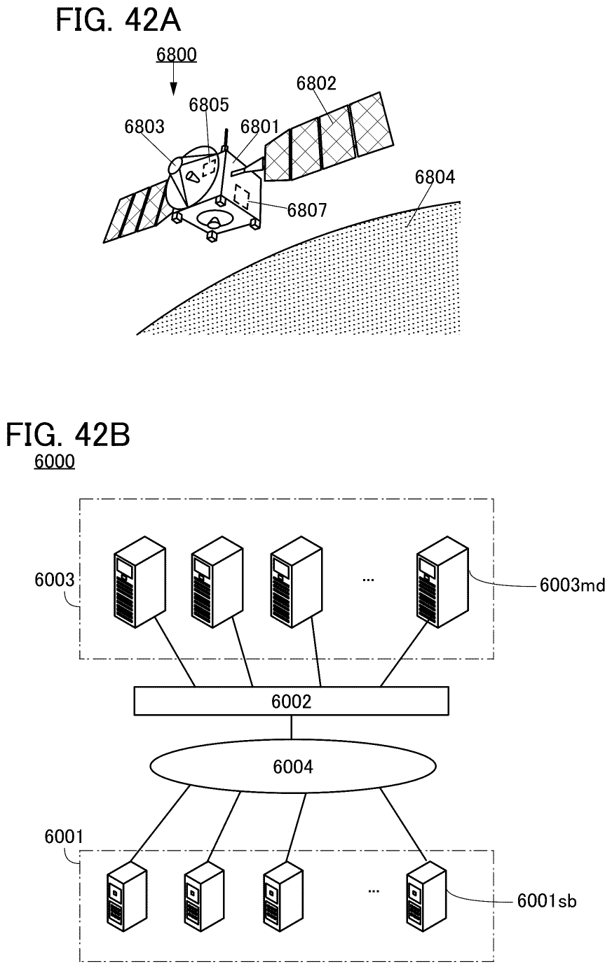

FIG. 42A illustrates an artificial satellite 6800 as an example of a device for space. The artificial satellite 6800 includes a body 6801, a solar panel 6802, an antenna 6803, a secondary battery 6805, and a control device 6807. Note that FIG. 42A illustrates a planet 6804 in outer space, for example.

Although not illustrated in FIG. 42A, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to exposure to radiation is smaller in the OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the semiconductor device of one embodiment of the present invention for a storage system in a data center, electric power required for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 42B illustrates a storage system that can be used in a data center. A storage system 6000 illustrated in FIG. 42B includes a plurality of servers 6001sb as a host 6001. The storage system 6000 includes a plurality of memory devices 6003md as a storage 6003. In the illustrated example, the host 6001 and the storage 6003 are connected to each other through a storage area network 6004 and a storage control circuit 6002.

The host 6001 corresponds to a computer which accesses data stored in the storage 6003. The host 6001 may be connected to another host 6001 through a network.

The data access speed, i.e., the time taken for storing and outputting data, of the storage 6003 is shortened by using a flash memory, but is still considerably longer than the time required for a DRAM that can be used as a cache memory in the storage. In the storage system, in order to solve the problem of low access speed of the storage 6003, a cache memory is normally provided in the storage to shorten the time taken for data storage and output.

The above-described cache memory is used in the storage control circuit 6002 and the storage 6003. The data transmitted between the host 6001 and the storage 6003 is stored in the cache memories in the storage control circuit 6002 and the storage 6003 and then output to the host 6001 or the storage 6003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic appliance, a large computer, a device for space, and a data center can be expected to produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

At least part of this embodiment can be implemented in appropriate combination with the other embodiments described in this specification.

### REFERENCE NUMERALS

10A: transistor, 10: transistor, 11: insulating layer, 12: conductive layer, 20a: opening portion, 20b: opening portion, 20: opening portion, 21f: semiconductor film, 21i: channel formation region, 21n: low-resistance region, 21: semiconductor layer, 22f: insulating film, 22: insulating layer, 23f: conductive film, 23: conductive layer, 26: opening portion, 27: conductive layer, 28: insulating layer, 29: opening portion, 30: memory cell, 31: conductive layer, 32: conductive layer, 33: conductive layer, 34: conductive layer, 35: conductive layer, 36: conductive layer, 37: conductive layer, 38: conductive layer, 39: conductive layer, 41a: insulating layer, 41b: insulating layer, 41c: insulating layer, 41: insulating layer, 42: insulating layer, 43: insulating layer, 44: insulating layer, 45: insulating layer, 46: insulating layer, 47: insulating layer, 48: insulating layer, 49: insulating layer, 50: capacitor, 51: conductive layer, 52: conductive layer, 53: insulating layer, 54a: opening portion, 54b: opening portion, 54: opening portion, 55: insulating layer, 60: memory unit, 61: conductive layer, 62: conductive layer, 63: conductive layer, 65: insulating layer, 70: layer, 90: transistor, 91: substrate, 92: semiconductor region, 93: insulating layer, 94: conductive layer, 95a: low-resistance region, 95b: low-resistance region, 100a: display device, 100b: display device, 100: display device, 101: substrate, 110: light-emitting element, 111: pixel electrode, 112: organic layer, 113: common electrode, 114: common layer, 115: conductive layer, 116B: coloring layer, 116G: coloring layer, 116R: coloring layer, 121: protective layer, 122: insulating layer, 123: insulating layer, 125: insulating layer, 126: resin layer, 128: layer, 140: connection portion, 170: substrate, 171: adhesive layer, 200A: display device, 200B: display device, 200C: display device, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 266: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 331: substrate, 332: insulating layer, 350: insulating layer, 351: semiconductor layer, 352: insulating layer, 353: insulating layer, 354: conductive layer, 355: conductive layer, 356: insulating layer, 357: conductive layer, 358: insulating layer, 359: insulating layer, 361: insulating layer, 362: insulating layer, 371: conductive layer, 374a: conductive layer, 374b: conductive layer, 374: plug, 420: layer, 422: peripheral circuit, 430: element layer, 432: memory cell, 437: transistor, 438: capacitor, 440: driver circuit, 442: row decoder, 443: row driver, 444: column decoder, 445: column driver, 446: sense amplifier, 447: input circuit, 448: output circuit, 470: layer, 471: PSW, 472: PSW, 473: control circuit, 474: voltage generation circuit, 480: memory device, 482_1: transistor, 482_2: transistor, 482: switch circuit, 483_1: transistor, 483_2: transistor, 483_3: transistor, 483: precharge circuit, 484_1: transistor, 484_2: transistor, 484_3: transistor, 484: precharge circuit, 485_1: transistor, 485_2: transistor, 485_3: transistor, 485_4: transistor, 485: amplifier circuit, 520: insulating layer, 522: insulating layer, 524: insulating layer, 526: insulating layer, 528: conductive layer, 530: conductive layer, 550: insulating layer, 582: insulating layer, 584: insulating layer, 586: conductive layer, 700A: electronic appliance, 700B: electronic appliance, 700: electronic component, 702: printed circuit board, 704: mounting board, 710: semiconductor device, 711: mold, 712: land, 713: electrode pad, 714: wire, 715: driver circuit layer, 716: memory layer, 721: housing, 723: wearing portion, 727: earphone portion, 730: electronic component, 731: interposer, 732: package substrate, 733: electrode, 735: semiconductor device, 750: earphone, 751: display panel, 753: optical member, 756: display region, 757: frame, 758: nose pad, 800A: electronic appliance, 800B: electronic appliance, 820: display portion, 821: housing, 822: communication portion, 823: wearing portion, 824: control portion, 825: image capturing portion, 827: earphone portion, 832: lens, 5600: large computer, 5610: rack, 5620: computer, 5621: PC card, 5622: board, 5623: connection terminal, 5624: connection terminal, 5625: connection terminal, 5626: electronic component, 5627: electronic component, 5628: electronic component, 5629: connection terminal, 5630: motherboard, 5631: slot, 6000: storage system, 6001sb: server, 6001: host, 6002: storage control circuit, 6003md: memory device, 6003: storage, 6500: electronic appliance, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6800: artificial satellite, 6801: body, 6802: solar panel, 6803: antenna, 6804: planet, 6805: secondary battery, 6807: control device, 7000: display portion, 7100: television device, 7101: housing, 7103: stand, 7111: remote controller, 7200: laptop personal computer, 7211: housing, 7212: keyboard, 7213: pointing device, 7214: external connection port, 7216: control device, 7300: digital signage, 7301: housing, 7303: speaker, 7311: information terminal device, 7400: digital signage, 7401: pillar, 7411: information terminal device, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor;
a first insulating layer;
a second insulating layer;
a third insulating layer; and
a wiring,
the transistor comprising:
a first conductive layer;
a second conductive layer;
a third conductive layer;
a semiconductor layer; and
a fourth insulating layer,
wherein the first insulating layer is over the first conductive layer,
wherein the second conductive layer is over the first insulating layer,
wherein the second insulating layer is over the second conductive layer,
wherein the first insulating layer, the second conductive layer, and the second insulating layer comprise a first opening portion reaching the first conductive layer,
wherein the semiconductor layer is positioned inside the first opening portion and comprises a region in contact with the first conductive layer and a region in contact with the second conductive layer,
wherein the fourth insulating layer is between the semiconductor layer and the third conductive layer inside the first opening portion,
wherein the third conductive layer is provided to fill the first opening portion,
wherein the third insulating layer is over the second insulating layer, the semiconductor layer, the fourth insulating layer, and the third conductive layer and comprises a second opening portion reaching the third conductive layer, and
wherein the wiring comprises a region in contact with the third conductive layer inside the second opening portion and comprises a region overlapping with the semiconductor layer with the third insulating layer therebetween.

2. A semiconductor device comprising:
a transistor;
a first insulating layer;
a second insulating layer;
a third insulating layer; and
a wiring,
the transistor comprising:
a first conductive layer;
a second conductive layer;
a third conductive layer;
a semiconductor layer; and
a fourth insulating layer,
wherein the first insulating layer is over the first conductive layer,
wherein the second conductive layer is over the first insulating layer,
wherein the first insulating layer and the second conductive layer comprise a first opening portion reaching the first conductive layer,
wherein the second insulating layer is over the second conductive layer,
wherein the second insulating layer comprises a second opening portion reaching the second conductive layer and comprising a region overlapping with the first opening portion,
wherein the semiconductor layer is positioned inside the first opening portion and inside the second opening portion and comprises a region in contact with the first conductive layer and a region in contact with the second conductive layer,
wherein the fourth insulating layer is between the semiconductor layer and the third conductive layer inside the first opening portion and inside the second opening portion,
wherein the third conductive layer is provided to fill the first opening portion and the second opening portion,
wherein the third insulating layer is over the second insulating layer, the semiconductor layer, the fourth insulating layer, and the third conductive layer and comprises a third opening portion reaching the third conductive layer, and
wherein the wiring comprises a region in contact with the third conductive layer inside the third opening portion and comprises a region overlapping with the semiconductor layer with the third insulating layer therebetween.

3. The semiconductor device according to claim 2, wherein the semiconductor layer comprises a region in contact with a top surface of the second conductive layer.

4. The semiconductor device according to claim 1, wherein a top surface of the second insulating layer, a top surface of the semiconductor layer, a top surface of the fourth insulating layer, and a top surface of the third conductive layer are level or substantially level with each other.

5. The semiconductor device according to claim 1, wherein the semiconductor layer comprises a metal oxide.

6. The semiconductor device according to claim 5,
wherein the metal oxide comprises two or three selected from In, an element M, and Zn, and
wherein the element Mis one or more kinds selected from Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb.

7. A method for manufacturing a semiconductor device, comprising:
forming a first insulating layer;
forming a first conductive layer over the first insulating layer;
forming a second insulating layer over the first conductive layer;
forming a first opening portion in the second insulating layer, the first conductive layer, and the first insulating layer;
forming a semiconductor layer, a third insulating layer over the semiconductor layer, and a second conductive layer over the third insulating layer, inside the first opening portion, the semiconductor layer comprising a region in contact with the first conductive layer;
forming a fourth insulating layer over the second insulating layer, the semiconductor layer, the third insulating layer, and the second conductive layer;
forming a second opening portion reaching the second conductive layer in the fourth insulating layer; and
forming a wiring to comprise a region in contact with the second conductive layer inside the second opening portion and to comprise a region overlapping with the semiconductor layer with the fourth insulating layer therebetween.

8. The method for manufacturing a semiconductor device, according to claim 7,
wherein the semiconductor layer, the third insulating layer, and the second conductive layer are formed by:
forming a semiconductor film, an insulating film over the semiconductor film, and a conductive film over the insulating film to comprise a region positioned inside the first opening portion and a region overlapping with the second insulating layer, after forming the first opening portion; and
performing planarization treatment on the conductive film, the insulating film, and the semiconductor film to expose a top surface of the second insulating layer.

9. The semiconductor device according to claim 2, wherein a top surface of the second insulating layer, a top surface of the semiconductor layer, a top surface of the fourth insulating layer, and a top surface of the third conductive layer are level or substantially level with each other.

10. The semiconductor device according to claim 2, wherein the semiconductor layer comprises a metal oxide.
